(19) United States
(12) Patent Application Publication
(10) Pub. No.: US 2025/0138516 A1
(43) Pub. Date: May 1, 2025

(54) PLASMA PROCESSING APPARATUS AND COMMUNICATION SYSTEM FOR CONTROL OF PLASMA PROCESSING APPARATUS

(71) Applicant: Hitachi High-Tech Corporation, Minato-ku, Tokyo (JP)

(72) Inventors: Tatsuya MARUYAMA, Tokyo (JP); Junichi KITAMURA, Tokyo (JP); Koichi YAMAMOTO, Tokyo (JP); Yuji SUGAYA, Tokyo (JP)

(21) Appl. No.: 18/692,102

(22) PCT Filed: Dec. 23, 2022
(86) PCT No.: PCT/JP2022/047771

§ 371 Date: Mar. 14, 2024

(51) Int. Cl. G05B 19/418; H01J 37/32

(52) U.S. Cl. CPC G05B 19/4185; H01J 37/32174; H01J 37/32449

(57) ABSTRACT

A control communication system and a plasma processing apparatus for efficient utilization of a computer resource and a communication resource such as a storage area. A control communication system includes a control communication apparatus that includes a communication unit configured to transmit a packet including control data and in which the communication unit includes a plurality of ports, and a plurality of device groups that are communicably connected to the plurality of communication ports and are operated according to the received packet. The control data is generated toward a target communication port among the plurality of communication ports, the target communication port being determined based on information of a communication port that transmits the packet. The packet includes a packet data area in which the control data is arranged, and is transmitted from the target communication port to the device group connected to the target communication port.

### TECHNICAL FIELD

The present invention relates to a technique of a control communication apparatus, a control communication system, a control data processing method, a control data processing program, and a semiconductor manufacturing apparatus.

### BACKGROUND ART

A control system that supports social infrastructure includes a sensor, a controller, and an actuator, and has a configuration in which the sensor acquires a state of a physical object and inputs the state to the controller, the controller calculates a control command value for instructing the actuator, and the actuator acts on the physical object based on the command value. For example, desired control is executed by periodically repeating such a series of processing.

Examples of such a control system include factory automation (FA) in a factory or the like, process automation (PA) in a chemical plant or the like, a semiconductor manufacturing device, a semiconductor inspection device, a medical machine, a distributed control system, a control system of an electric power system, a power plant, a water and sewage treatment system, and a steel control system.

Particularly, in a large-scale control system or a complicated control system, a plurality of sensors, controllers, and actuators are connected via a network. In such a network, a technique of a control network is developed in order to satisfy a time constraint (for example, a worst delay), cost, reliability, and a requirement specific to the field, which are requirements of a control system. In particular, driven by an increase in a scale and an increase in a level of a control system, or by recent progress of industrial IoT, a control network constituting a control system is required to speed up communication, shorten a control communication cycle, increase a communication capacity, and the like.

As a method for meeting such needs, there is a technique of transmitting communication packets in parallel using a plurality of communication ports. That is, a communication delay is reduced by distributing a group of target communication apparatuses and performing communication in parallel, which will lead to speeding up in communication, shortening in a control communication cycle, and an increase in a communication capacity.

From the viewpoint of developing a control application, an application model specific to a control field is provided because a basic operation of a control system includes inputting data to and outputting data from an actuator or a sensor, and a large-scale control system is implemented by distributing a plurality of actuators and sensors. Under such circumstances, for example, the following system is known as a data input and output system of an actuator or a sensor.

### (Transfer Memory System)

In a system called a transfer memory system as disclosed in PTL 1 and NPL 1, data areas of all nodes constituting a network are allocated in an equal size on an address space. An allocated data area is referred to as a transfer memory, and data on transfer memories of all nodes is exchanged and shared by periodic communication among all nodes. A physical input and a physical output of an actuator or a sensor are associated in a transfer memory, and an input and an output of the actuator or the sensor are performed by reading data from the transfer memory and writing data to the transfer memory.

### (Logical Address Space System)

As another system of allocating an input and an output of an actuator or a sensor to a predetermined address space, there is a logical address space system. In the logical address space system, any one data area (that is, a physical input and a physical output) of each slave is allocated to a single virtual logical address space. A size and an allocation method of the area can be freely set. As a network using such a system, there is EtherCAT (registered trademark) (Communication Profile Family 12 of IEC 61784 part 2).

### CITATION LIST

### Patent Literature

PTL1: JP2000-76163A

### Non Patent Literature

NPL1: ISO 15745-4 Industrial Automation Systems and Integration Open Systems Application, Integration Frameworks Part 4 Reference Description for Ethernet-based Control Systems

### SUMMARY OF INVENTION

### Technical Problem

However, in a case where a plurality of communication ports are used to speed up communication, shorten a control communication cycle, and increase a communication capacity, a problem arises when there is nonuniformity in correspondence between data on a control application and a control target device serving as a transmission target, or in communication characteristics of control target devices. For example, in a transfer memory system, since it is required to exchange and share data among all nodes, even when a plurality of communication ports are provided, data for all nodes needs to be transmitted from the communication ports. Therefore, it is not possible to divide a communication amount using a plurality of communication ports, and there is a constraint in speeding up communication.

In addition, since data areas of a fixed size are allocated to a shared address space by the number of all nodes, utilization efficiency of the data areas on the address space is low, and the number of nodes connectable to a network is likely to be constrained. The utilization efficiency of data areas indicates that, for example, when there are a control target device having a small number of input and output points and a control target device having a large number of input and output points, a size of an individual data area needs to be adjusted to the control target device having a large number of input and output points, and most data areas of the control target device having a small number of input and output points become invalid.

On the other hand, in a logical address space system, a data area of a control target can be freely arranged as compared with the transfer memory system. Therefore, utilization efficiency of an address space is high, and a constraint on the number of connectable nodes is relaxed. Accordingly, a network employing the logical address space system tends to have a larger maximum allowable number of connectable nodes than a network employing the transfer memory system.

However, since utilization of a plurality of communication ports is not considered in the logical address space system, it is unclear from which communication port a communication packet for accessing a logical address space is transmitted. When communication packets for accessing all areas of an allocated logical address space are transmitted from all communication ports, a control target device may receive an invalid communication packet for accessing a logical address space to which the control target device is not allocated, which leads to a problem such as an increase in delay and a reduction in effective communication capacity. Since an input and an output of a control target device on a logical address space may be allocated to a plurality of areas or discontinuous areas, such an invalid communication packet may be transmitted.

When the number of input and output points, a size of a data area, and a communication cycle of a group of control target devices are not uniform, implementation of efficient communication may be constrained. For example, when a control target device having a short communication cycle and a control target device having a relatively long communication cycle are connected to the same communication port, a communication delay caused by the control target device having a long communication cycle may be a factor that inhibits shortening of a cycle of the control target device having a short communication cycle.

In order to solve the above problems, a main object of the invention is to provide a control communication system and a plasma processing apparatus that have excellent communication performance and utilization efficiency of a computer resource and a communication resource such as a storage area.

The above and other objects and novel features of the invention will become apparent from description of the present specification and accompanying drawings.

### Solution to Problem

A control communication system according to a representative embodiment includes a control communication apparatus that includes a communication unit configured to transmit a packet including control data and in which the communication unit includes a plurality of ports, and a plurality of device groups that are communicably connected to the plurality of communication ports and are operated according to the received packet. The control data is generated toward a target communication port among the plurality of communication ports, the target communication port being determined based on information of a communication port that transmits the packet. The packet includes a packet data area in which the control data is arranged, and is transmitted from the target communication port to the device group connected to the target communication port.

### Advantageous Effects of Invention

To briefly describe effects obtained by a representative embodiment of the invention disclosed in the present application, it is possible to provide a control communication system that has excellent control performance, communication performance, and utilization efficiency of a computer resource and a communication resource.

### BRIEF DESCRIPTION OF DRAWINGS

FIG. 1 is a schematic view showing a configuration example of a control communication system according to a first embodiment.

FIG. 2 is a circuit block diagram showing a hardware configuration example of a control apparatus 120 shown in FIG. 1.

FIG. 3 is a functional block diagram showing a functional configuration example of the control apparatus 120 shown in FIG. 1.

FIG. 4 is a circuit block diagram showing a hardware configuration example of a control target device 121 shown in FIG. 1.

FIG. 5 is a functional block diagram showing a functional configuration example of a control target device communication control IC 130 shown in FIG. 4.

FIG. 6 is a diagram showing a configuration example of an EtherCAT frame.

FIG. 7 is a circuit block diagram showing a hardware configuration example of a control system management apparatus 124 shown in FIG. 1.

FIG. 8 is a functional block diagram showing a functional configuration example of the control system management apparatus 124 shown in FIG. 1.

FIG. 9A is a diagram showing a specific example of a control recipe 190 shown in FIG. 8.

FIG. 9B is a diagram showing a specific example of the control recipe 190 shown in FIG. 8.

FIG. 9C is a diagram showing a specific example of the control recipe 190 shown in FIG. 8.

FIG. 9D is a diagram showing a specific example of the control recipe 190 shown in FIG. 8.

FIG. 10A is a diagram showing an example of a quantity relationship among an overall process, a process, the control target device 121, and a control processing content.

FIG. 10B is a diagram showing an example of a quantity relationship among the process, the control target device 121, and the control processing content.

FIG. 10C is a diagram showing an example of a quantity relationship among the process, the control target device 121, and the control processing content.

FIG. 11 is a flowchart showing an example of overall operation steps of the control communication system shown in FIG. 1.

FIG. 12 is a flowchart showing an example of operation steps of a configuration shown in FIG. 11.

FIG. 13 is a flowchart showing an example of a development step of a control program shown in FIG. 11.

FIG. 14 is a flowchart showing an example of execution steps of control software executed by the control apparatus 120 when a control system 123 is operated in step S003 shown in FIG. 11.

FIG. 15 is a flowchart showing an example of execution steps of transmission processing executed by the control apparatus 120 when the control system 123 is operated in step S003 shown in FIG. 11.

FIG. 16 is a diagram showing an example of a relationship between an execution start timing in step S040 and a periodic execution timing in step S048 shown in FIG. 15.

FIG. 17 is a flowchart showing an example of execution steps of reception processing executed by the control apparatus 120 when the control system 123 is operated in step S003 shown in FIG. 11.

FIG. 18A is a diagram showing an example of specific components and required specifications of the control system 123 shown in FIG. 1.

FIG. 18B is a schematic diagram showing a specific configuration example of the control system 123 shown in FIG. 18A.

FIG. 19A is a diagram showing an example of a specific connection relationship of the control system 123 represented by control target device arrangement information 194 shown in FIG. 8.

FIG. 19B is a diagram showing an example of a logical address space allocated to the control target device 121 shown in FIG. 19A.

FIG. 19C is a diagram showing an example of a logical address space serving as a comparative example of FIG. 19B.

FIG. 20A is a flowchart showing an example of steps for allocating the logical address space shown in FIG. 19B.

FIG. 20B is a diagram showing a specific example of each step shown in FIG. 20A.

FIG. 20C is a diagram showing a specific example of each step shown in FIG. 20A.

FIG. 20D is a diagram showing a specific example of each step shown in FIG. 20A.

FIG. 21 is a diagram showing a modification of FIGS. 19B and 20D.

FIG. 22 is a diagram showing another modification of FIGS. 19B and 20D.

FIG. 23A is a diagram showing an example of a correspondence relationship between the logical address space shown in FIG. 19B and an access datagram (a command) in EtherCAT.

FIG. 23B is a diagram showing an example of a correspondence relationship different from that shown in FIG. 23A.

FIG. 24A is a diagram showing an example of a case where determination of the control target device arrangement information 194 and determination of datagram configuration information 196 shown in FIG. 8 are performed together.

FIG. 24B is a diagram showing a comparative example of FIG. 24A.

FIG. 25 is a diagram showing a specific example of datagram generation information stored in a datagram generation information storage unit 151 shown in FIG. 3.

FIG. 26A is a diagram showing an example of data storage positions in a data storage unit 152 shown in FIGS. 3 and 25.

FIG. 26B is a diagram showing an example of data storage positions in the data storage unit 152 shown in FIGS. 3 and 25.

FIG. 27 is a diagram showing an example of API definition information provided by a data access management unit 160.

FIG. 28 is a flowchart showing an example of steps for determining a time offset of transmission timings shown in FIG. 25.

FIG. 29 is a diagram showing datagrams generated by a datagram generating unit 150 based on the datagram generation information shown in FIG. 25 and timings of the datagrams.

FIG. 30 is a diagram showing a configuration example of a communication frame received by a receiving unit shown in FIG. 3.

FIG. 31 is a diagram showing an operation example when a time synchronization protocol is applied in a control communication system according to a second embodiment.

FIG. 32 is a functional block diagram showing a functional configuration example of the control apparatus 120 shown in FIG. 1 in a control communication system according to a third embodiment.

FIG. 33A is a diagram showing an operation example of the control system 123 including the control apparatus 120 shown in FIG. 32.

FIG. 33B is a diagram showing an operation example of the control system 123 including the control apparatus 120 shown in FIG. 32.

FIG. 34A is a diagram showing an operation example different from that in FIG. 33A.

FIG. 34B is a diagram showing an operation example different from that in FIG. 33B.

FIG. 35 is a schematic diagram showing a configuration example of the control communication system according to the first embodiment different from that in FIG. 1.

FIG. 36 is a functional block diagram showing a functional configuration example of the control apparatus 120 shown in FIG. 1 different from that in FIG. 3.

### DESCRIPTION OF EMBODIMENTS

Hereinafter, embodiments of the invention will be described in detail with reference to the drawings. In all drawings illustrating the embodiments, the same members are denoted by the same reference numerals in principle, and repeated description thereof will be omitted.

### First Embodiment

### (Overview of Control Communication System)

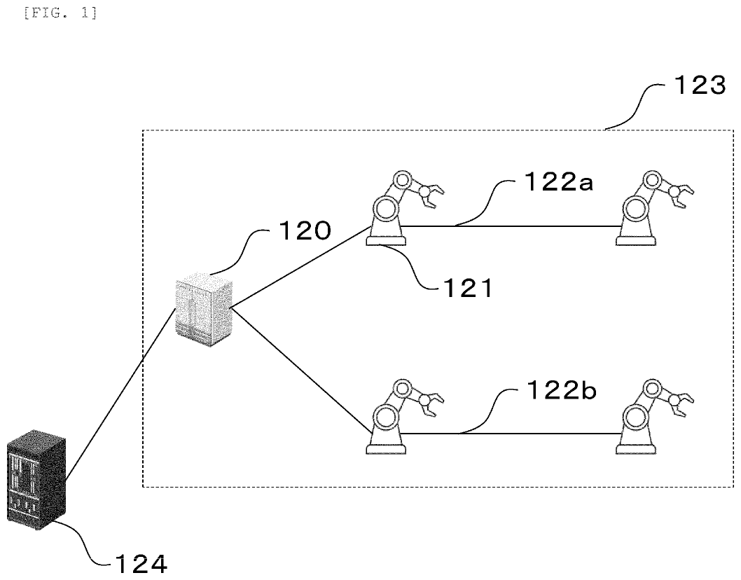

FIG. 1 is a schematic diagram showing a configuration example of a control communication system according to a first embodiment. In FIG. 1, a control apparatus 120 is a control communication apparatus to which the invention is applied. The control apparatus 120 communicates with a control target device 121 via control networks 122a and 122b to control the control target device 121. In the specification, the control networks 122a and 122b are collectively referred to as a control network 122. The control apparatus 120 transmits a communication packet to and receives a communication packet from the control target device 121, thereby transmitting a control command value for controlling the control target device 121 such as a sensor and an actuator, receiving a measured value or sensor information the control target device 121, and performing various settings or the like for the control target device 121.

The control apparatus 120 exchanges sampling data, a control command, a state signal, and the like in a control system such as a controller in a semiconductor manufacturing apparatus or a semiconductor inspection apparatus, a central control apparatus of a distributed control system (DCS), and a protection control apparatus of a power system. In this case, a plurality of pieces of data in the same control system may be stored in a packet. The control apparatus 120 may support a software virtualization technique or a software container technique, and may manage an application or an operating system (OS) as a container by virtualization.

Examples of the control apparatus 120 include a dedicated controller, an industrial personal computer, a control computer, a DCS controller, a multi-access edge computing (MEC) apparatus, a computer cloud, a server, a supervisory control and data acquisition (SCADA) server, a programmable logic controller (PLC), an intelligent electronic device (IED), a protection control apparatus, a cloud, and a server.

The control target device 121 is a device such as a sensor and an actuator, and is operated according to a control command received from the control apparatus 120 via the control network 122. The control target device 121 acquires a state and information of a device and transmits the state and the information to the control apparatus 120 via the control network 122. The control target device 121 may only have a function of inputting information such as a sensor, may only have a function of outputting information such as an actuator, or may have both functions of inputting and outputting.

Examples of the control target device 121 include an industrial robot such as a mobile robot, a humanoid robot, and a robot arm, an automated guided vehicle (AGV), an autonomous mobile robot (AMR), and an autonomous mobile object or a remote-controlled mobile object. Examples of the control target device 121 further include a chip mounter, a machine tool table, a processing device, a machine tool, a semiconductor manufacturing device, a semiconductor inspection device, and a medical device such as a clinical test device, an electric power device such as a motor, an inverter, a servo amplifier, and a servo motor in a manufacturing device, a circuit breaker, and a disconnector, and various sensors (an encoder, a temperature sensor, a pressure sensor, and the like).

Examples of the control target device 121 further include a dedicated controller, an industrial personal computer, a control computer, a DCS controller, a SCADA device, a PLC, a smartphone or a communication device including a wireless communication interface, an intelligent electronic device (IED), a merging unit (MU), and a protection control device.

The control network 122 is a network that connects the control apparatus 120 and the control target device 121. Examples of the control network 122 include a network based on IEEE 802.3 (Ethernet) including a control network such as EtherCAT (registered trademark), IEC 61784, and time sensitive networking (TSN). Examples of the control network 122 further include a core network in a wireless network such as 5G, 6G, and 4G, a wired network such as a controller area network (CAN, registered trademark), RS-232C, and a universal serial bus (USB, registered trademark), and various wireless networks such as Bluetooth (registered trademark).

Examples of an upper protocol in a protocol stack include an OPC unified architecture (UA), a data distribution service (DDS), a communication protocol based on a service based interface (SBI), REST API, HTTP/2, open API, JavaScript object notation (JSON) data, and IEC 61850. These protocols may be hierarchized. For example, a content of a data area on TSN applies an OPC UA standard.

In the first embodiment, a case where the control network 122 is EtherCAT will be described as an example. The EtherCAT network has the following features.
The control apparatus 120 and the control target device 121 are connected, and a control packet sent from the control apparatus 120 sequentially passes through one or more control target devices 121 and returns to the control apparatus 120. For example, a topology includes a line topology, a ring topology, and a star topology. A relay device adapted to the EtherCAT is used as needed.
One control packet may include control data for each of a plurality of control target devices 121. Accordingly, the control apparatus 120 only needs to transmit and receive a smaller number of packets than a case where the control apparatus 120 individually transmits packets to and receiving packets from each of a plurality of control target devices 121.
When a control packet including a control command to each of a plurality of control target devices 121 is sent from the control apparatus 120, the control packet is sequentially transferred to the control target devices 121 according to a connection order with a network, and then returns to the control apparatus 120 which is a transmission source. At this time, each control target device 121 is operated based on control data (a datagram) corresponding to the control target device 121 included in a data area of the received control packet.

In FIG. 1, a control system 123 includes the control apparatus 120, the control target device 121, and the control network 122. Examples of the control system 123 include a control system of a semiconductor manufacturing apparatus, a semiconductor inspection apparatus, and a medical apparatus such as a clinical test apparatus, a control system such as DCS for factory automation (FA) and process automation (PA), a remote control system via a wireless network, a monitoring control and protection control system in the field of power systems, a control system in an in-vehicle system, an industrial apparatus, a construction machine, and a railway vehicle, and a control system in a railway ground signal system and an aircraft.

Alternatively, the control system 123 may be a part of components of the entire system. For example, the control system 123 may be a part of components of a chamber of a plasma processing apparatus that is a semiconductor manufacturing apparatus, a manufacturing line of an FA system, an apparatus constituting DCS, an in-vehicle system, and an aircraft control system. The plasma processing apparatus is, for example, an etching apparatus or a sputtering apparatus.

A control system management apparatus 124 is connected to the control apparatus 120 to control and manage the control apparatus 120. For example, the control system management apparatus 124 sets and acquires a control parameter, a control policy, and the like for the control apparatus 120 to perform control. In this case, the control system management apparatus 124 may perform functional division on the control apparatus 120 from the viewpoint of time resolution. That is, the control system management apparatus 124 can control a control parameter, a target value, and the like of the control apparatus 120 in a relatively long control cycle for a control cycle executed by the control apparatus 120. In another aspect, while the control apparatus 120 performs automatic control, the control system management apparatus 124 can enable a system operator to perform manual control.

The control system management apparatus 124 may set a configuration of the control system 123. For example, the control system management apparatus 124 sets a parameter and an operation mode of the control apparatus 120 and the control target device 121. Alternatively, the control system management apparatus 124 allocates an address when mapping the control target device 121 to a logical address, and sets the control target device 121 related to such an allocation of a logical address. In this case, the control system management apparatus 124 may determine a datagram for setting, transfer the determined information to the control apparatus 120, and the control apparatus 120 may transmit the information to the control target device 121. The setting may be performed by generating, editing, and managing EtherCAT slave information (ESI) and EtherCAT network information (ENI) in EtherCAT.

In this manner, when the control system management apparatus 124 sets the control system 123, not only a setting in an online state in which the control system 123 is operated, but also a setting in an offline state before the control system 123 is operated may be used. In such a case, a connection between the control system management apparatus 124 and the control apparatus 120 or a connection between the control system management apparatus 124 and the control target device 121 may be performed during setting. The control system management apparatus 124 may be directly connected to the control target device 121 without passing through the control apparatus 120. The connection here includes not only a physical connection using a network cable but also a logical connection such as a communication protocol and software for setting.

The control system management apparatus 124 may be implemented in a similar manner to the control apparatus 120. The control system management apparatus 124 may be connected to the control apparatus 120 via the control network 122 or may be connected to the control apparatus 120 via a network independent of the control network 122.

As one aspect of the control communication system shown in FIG. 1, in addition to a system exemplified as the control system 123, there is an IoT system or the like in which an analysis is performed by artificial intelligence on a cloud or a computer based on information collected via the control network 122 and performance of the control system is improved. This aspect may include local 5G, private 5G, and public 5G.

(Hardware Configuration of Control Apparatus (Control Communication Apparatus) 120)

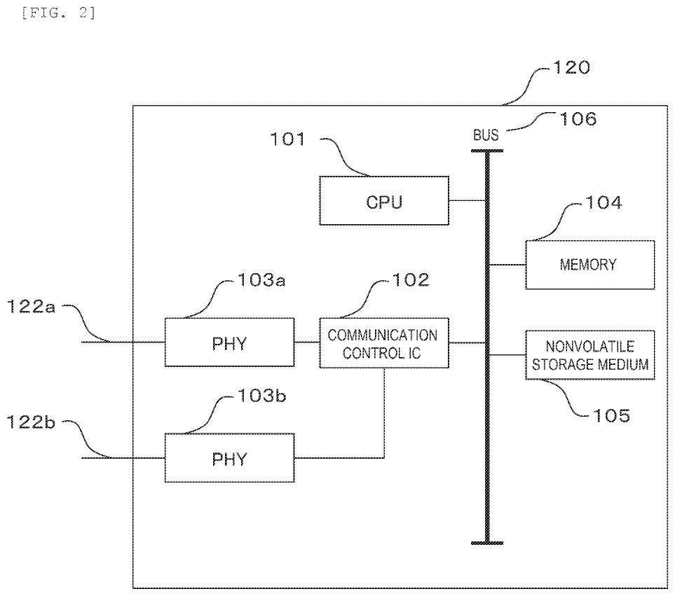

FIG. 2 is a circuit block diagram showing a hardware configuration example of the control apparatus 120 shown in FIG. 1. In FIG. 2, a CPU 101 that is an example of a processor transfers a program stored in a nonvolatile storage medium 105 to a memory 104 and executes the program. Examples of an execution processing program include an operating system (hereinafter referred to as an OS) and an application program operating on an OS. Based on a program operating on the CPU 101, an operation setting in a communication control IC 102, acquisition of state information, and the like are performed.

The communication control IC 102 receives a transmission request and transmission data from software operating on the CPU 101, and transmits the transmission request and the transmission data to the control network 122 using PHYs 103a and 130b. In the specification, the PHY 103a and the PHY 130b are collectively referred to as a PHY 103. Data received from the control network 122 is transferred to the CPU 101, the memory 104, and the nonvolatile storage medium 105 via a bus 106.

Implementation examples of the communication control IC 102 include an IC such as a field programmable gate array (FPGA), a complex programmable logic device (CPLD), an application specific integrated circuit (ASIC), and a gate array. Alternatively, the communication control IC 102 may be integrated with the CPU 101.

The communication control IC 102 may be implemented as an IEEE 802.3 communication device including a MAC layer and a PHY layer, or the communication control IC 102 may include a PHY function. In this case, implementation examples of the communication control IC 102 include a media access control (MAC) chip of IEEE 802.3 standard, a physical layer (PHY) chip, and a composite chip of MAC and PHY. The communication control IC 102 may be included in the CPU 101 or a chipset that controls an information path inside a computer. Although one communication control IC 102 is shown in the configuration example in FIG. 2, the number of the communication control ICs 102 may be plural.

The PHY 103 is a transceiver IC having a function of communicating with the control network 122. Examples of a communication standard provided by the PHY 103 include a physical layer (PHY) chip of IEEE 802.3. In the configuration example shown in FIG. 2, since the PHY 103 and the communication control IC 102 are connected, processing of a media access control (MAC) layer of IEEE 802.3 is performed by the communication control IC 102. However, an effect of the invention is not lost even in a configuration in which an IC that provides a MAC function is arranged between the communication control IC 102 and the PHY 103 or a configuration in which a communication IC in which an IC that provides a MAC function and the PHY 103 are combined is connected to the communication control IC 102.

The PHY 103 may be included in the communication control IC 102. In the configuration example shown in FIG. 2, a plurality of PHYs 103 are shown. A quantity relationship between the communication control IC 102 and the PHY 103 may be a relationship in which one or more PHYs 103 are provided for one communication control IC 102.

The memory 104 is a temporary storage area for operating the CPU 101, and stores an OS, an application program, and the like transferred from the nonvolatile storage medium 105. The nonvolatile storage medium 105 is a storage medium for information, and is used to store a program for operating the CPU 101 such as an OS, an application, and a device driver, and to store an execution result of the program. Examples of the nonvolatile storage medium 105 include a hard disk drive (HDD), a solid state drive (SSD), and a flash memory. Examples of an external storage medium that can be easily removed include a floppy disk (FD), a CD, a DVD, a Blu-ray (registered trademark), a USB memory, and a compact flash.

The bus 106 connects the CPU 101, the communication control IC 102, the memory 104, and the nonvolatile storage medium 105. Examples of the bus 106 include a PCI bus, an ISA bus, a PCI Express bus, an on-chip bus, a system bus, and a memory bus.

### (Functional Configuration of Control Apparatus (Control Communication Apparatus) 120)

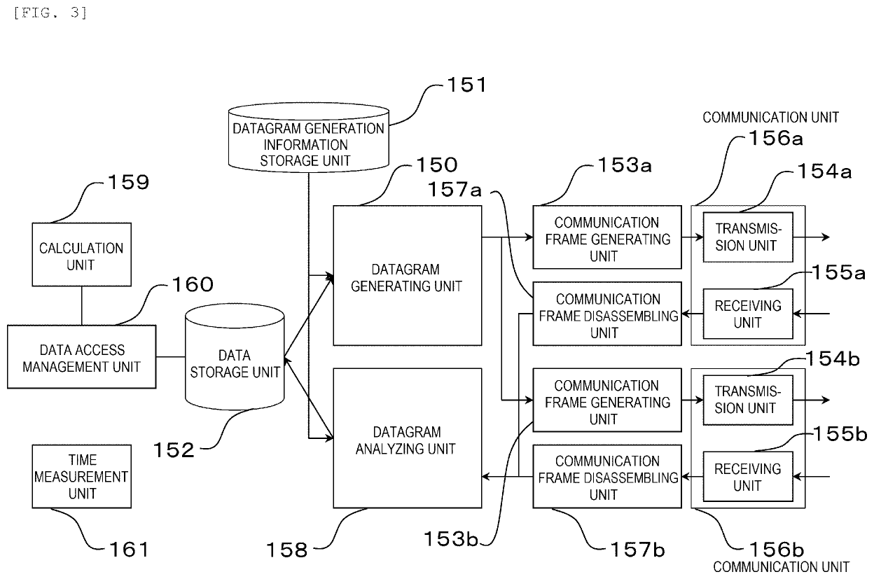

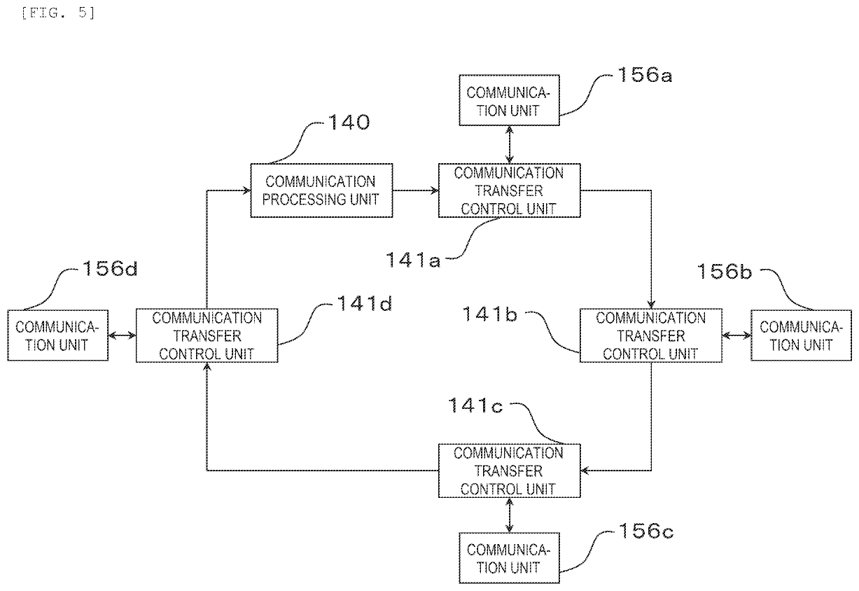

FIG. 3 is a functional block diagram showing a functional configuration example of the control apparatus 120 shown in FIG. 1. FIG. 6 is a diagram showing a configuration example of an EtherCAT frame. In the specification, the EtherCAT frame is also referred to as a communication frame, a packet, or a communication packet.

The control apparatus 120 shown in FIG. 3 includes a datagram generating unit 150, a datagram generation information storage unit 151, a data storage unit 152, communication frame generating units 153a and 153b, communication units 156a and 156b, communication frame disassembling units 157a and 157b, and a datagram analyzing unit 158. The control apparatus 120 further includes a calculation unit 159, a data access management unit 160, and a time measurement unit 161. The communication unit 156a includes a transmission unit 154a and a receiving unit 155a, and the communication unit 156b includes a transmission unit 154b and a receiving unit 155b.

In the specification, the communication frame generating units 153a and 153b are collectively referred to as a communication frame generating unit 153, and the communication frame disassembling units 157a and 157b are collectively referred to as a communication frame disassembling unit 157. The communication units 156a and 156b are collectively referred to as a communication unit 156, the transmission units 154a and 154b are collectively referred to as a transmission unit 154, and the receiving units 155a and 155b are collectively referred to as a receiving unit 155. Each of the communication units 156a and 156b includes a communication port. Therefore, in the example shown in FIG. 3, the communication unit 156 includes two communication ports.

In FIG. 3, the datagram generating unit 150 extracts information required for generating a datagram (control data) from the datagram generation information storage unit 151. The extracted datagram generation information includes a data position on the data storage unit 152, and the datagram generating unit 150 extracts data from the data storage unit 152 based on the data position.

The datagram generating unit 150 generates a datagram (control data) based on the extracted data and datagram generation information, and transfers the datagram to the communication frame generating unit 153 specified by the datagram generation information and to a communication port specified by the datagram generation information. For example, the datagram generating unit 150 is implemented by one or more of the CPU 101 or an application operating on the CPU 101, and the communication control IC 102.

The datagram generation information storage unit 151 stores datagram generation information required for generating a datagram by the datagram generating unit 150. For example, the datagram generation information is mainly generated based on information of the control target device 121, and includes one or more pieces of the following information.
[1] Information constituting a header of a datagram: in the case of an EtherCAT frame shown in FIG. 6, for example, the information includes a command 179, an index 180, an address 181, a size 182, a CIRCLE 184, and a MORE 185. Since an IRQ 186 is mainly an event notification from the control target device 121 side, whether the IRQ 186 is included in the datagram generation information is freely set.
[2] Information of the communication frame generating unit 153 that is a transfer destination of the generated datagram: information of the transfer destination, and the number of communication ports for transmitting a packet may be plural.
[3] Communication cycle [4] Start time: the start time may be either a relative time or an absolute time.
[5] Expected value of verification code: in the case of the EtherCAT frame shown in FIG. 6, for example, the expected value includes a WKC 178. It is possible to verify whether a datagram is processed as expected by comparing a value with the expected value at the time of reception. The expected value is mainly used at the time of reception and may be unnecessary at the time of transmission.
[6] Transmission target status in a predetermined state machine: the transmission target status is information for controlling whether a datagram is a transmission target for the purpose of switching a set of datagrams serving as transmission targets. The transmission target status may be a truth value simply indicating whether a datagram is a transmission target.
[7] Transmission pattern information: the transmission pattern information is information indicating whether to transmit a datagram in each communication cycle in [3].
[8] Valid and invalid information of datagram generation information: for example, in a case where certain devices are disabled for a reason of maintenance, cleaning, or the like, there is no need to generate and transmit a datagram to the devices, and thus corresponding datagram generation information is invalidated.

For example, the datagram generation information storage unit 151 is implemented by one or more of the CPU 101, the memory 104, and the nonvolatile storage medium 105 in FIG. 3. The data storage unit 152 stores a data portion of a datagram (control data) generated by the datagram generating unit 150. The data portion corresponds to, for example, a data area 177 in an area (a packet data area) of a datagram 175 shown in FIG. 6. When a plurality of datagrams are generated, the data storage unit 152 aggregates and stores a plurality of data portions of the datagram group.

Contents stored in the data storage unit 152 are updated by the calculation unit 159 via the data access management unit 160 or the datagram analyzing unit 158. The datagram generating unit 150 extracts data from the data storage unit 152 to generate a datagram. The calculation unit 159 extracts data from the data storage unit 152 to acquire sensor information and the like.

The communication frame generating unit 153 shapes the datagram generated by the datagram generating unit 150 into a communication frame or a packet (for example, an EtherCAT frame in the case of an EtherCAT standard). The communication frame generating unit 153 may use a plurality of datagrams (control data) to construct a communication frame. The communication frame generating unit 153 stores or calculates and adds, for example, header information and tail information required for constructing a communication frame. The header information and the tail information are an Ethernet header 171 and a frame check sequence (FCS) 173 in the case of the EtherCAT standard shown in FIG. 6.

The communication frame generating unit 153 transfers the constructed communication frame to the transmission unit 154. The communication frame generating unit 153 may be provided for each communication unit 156. Alternatively, a communication frame may be transferred from one communication frame generating unit 153 to each communication unit 156. In this case, for example, when a datagram is transferred from the datagram generating unit 150 to the communication frame generating unit 153, information indicating to which communication unit 156 a communication frame including the datagram is to be transferred may be transferred. Alternatively, the communication frame generating unit 153 may check the datagram generation information in the datagram generation information storage unit 151. For example, the communication frame generating unit 153 is implemented by one or more of the CPU 101 or an application operating on the CPU 101, the communication control IC 102, and the PHY 103.

The transmission unit 154 is a transmission function unit in the communication unit 156, and transmits a packet from the control apparatus 120 to the control network 122. For example, the transmission unit 154 is implemented by one or more of the communication control IC 102 and the PHY 103. The receiving unit 155 is a receiving function unit in the communication unit 156, and receives a packet from the control network 122. For example, the receiving unit 155 is implemented by any one or more of the communication control IC 102 and the PHY 103.

The communication unit 156 is a function unit that is connected to the control network 122 and performs communication according to a communication protocol of the control network 122. In the configuration example shown in FIG. 2, since the PHY 103 is outside the communication control IC 102, the communication unit 156 corresponds to a processing unit of a MAC layer. Alternatively, the communication control IC 102 may be an Ethernet communication device including a MAC layer and a PHY layer, or the communication control IC 102 may include a PHY function. For example, the communication unit 156 is implemented by one or more of the communication control IC 102 and the PHY 103.

The communication frame disassembling unit 157 receives a frame transferred from the receiving unit 155, removes header and tail information, and disassembles the received frame into datagrams. The communication frame disassembling unit 157 transfers the disassembled datagrams to the datagram analyzing unit 158. For example, the communication frame disassembling unit 157 is implemented by one or more of the CPU 101 or an application operating on the CPU 101, the communication control IC 102, and the PHY 103.

The datagram analyzing unit 158 analyzes the datagrams transferred from the communication frame disassembling unit 157 and updates the data storage unit 152 according to received contents. For example, the datagram analyzing unit 158 is implemented by one or more of the CPU 101 or an application operating on the CPU 101, the communication control IC 102, and the PHY 103.

The calculation unit 159 performs a control calculation, an information processing calculation, and the like. Examples of such a calculation include a calculation of a control command for processing sensor information received from the control target device 121 and driving the control target device 121 based on a predetermined control rule. Alternatively, examples of such a calculation include filter processing and statistical processing applied to sensor values, and statistical processing for a set of sensor values in a predetermined past period.

Examples of the predetermined control rule include a control engineering theory such as feedback control and feedforward control, and control processing based on AI. Examples of the predetermined control rule include a control method that can change a state depending on past information, such as integral (I) control and control by a state machine. Alternatively, examples of the predetermined control rule include statistical processing such as AI and machine learning processing for the purpose of state management (detection of a failure or dangerous state) of the control target device 121, device management or asset management (version management, update, or the like of software), preventive maintenance, condition based maintenance (CBM), and remaining life prediction.

When the control target device 121 is a mobile object, examples of the predetermined control rule include determination of a moving direction and a target moving position, speed control, acceleration control, stop, and deceleration. When the control target device 121 is an industrial robot arm, examples of the predetermined control rule include a control command to a motor of each articulated joint, control of a front end position of the robot arm, and trajectory control of the robot arm. Since the control target devices 121 may be of various types, may be not only an actuator but also a sensor simply, the calculation unit 159 performs various kinds of control according to the types of the control target device 121. For example, the calculation unit 159 is implemented by the CPU 101 or an application operating on the CPU 101.

The data access management unit 160 manages access between the calculation unit 159 and the data storage unit 152. That is, the data access management unit 160 converts an access to a software model such as a sensor and an actuator of the control target device 121 implemented on software into an access to data in the data storage unit 152 in processing executed by the calculation unit 159. For example, the data access management unit 160 is implemented by the CPU 101 or an application operating on the CPU 101.

The time measurement unit 161 is a function unit that manages time. The time measurement unit 161 measures an elapsed time of events in each function unit or between function units shown in FIG. 3, and measures an occurrence time of a specific event. A Time in this case may be an absolute time based on a global positioning system (GPS) or the like, a time of the control apparatus 120, or a time based on a reference time in the control system 123. For example, in EtherCAT, a configuration is shown in which, among the control target devices 121, the control target device 121 that supports a distributed clock protocol and is closest to the control apparatus 120 is set as a reference time.

An event to be measured by the time measurement unit 161 is a transmission time, a reception time, and a transfer time between function units of a predetermined communication frame or a datagram. The time measurement unit 161 may generate an interrupt when a specified time elapses and notify other function units of the interrupt, or may periodically generate and notify other function units of the interrupt. An implementation example of the time measurement unit 161 includes a time measurement device (a crystal oscillator or a timer device) of the CPU 101 or the communication control IC 102, and the memory 104 or the nonvolatile storage medium 105 may be used as a storage unit of a measured time.

### (Hardware Configuration of Control Target Device 121)

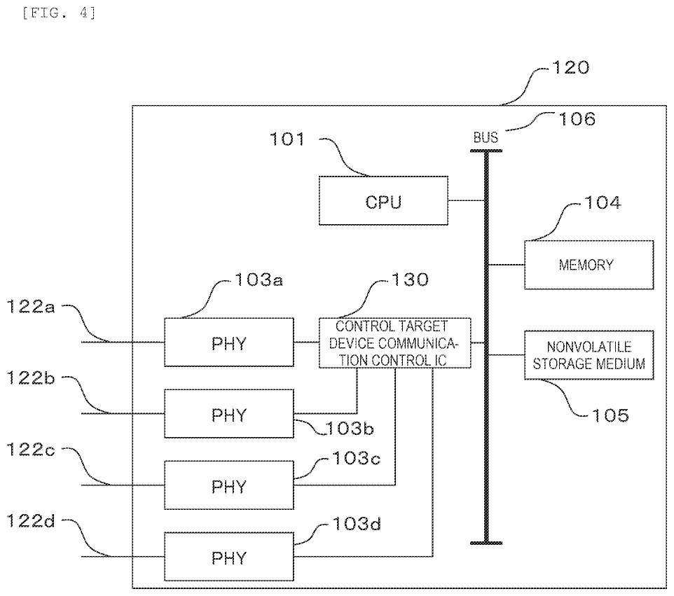

FIG. 4 is a circuit block diagram showing a hardware configuration example of the control target device 121 shown in FIG. 1. Here, the control target device 121 conforming to a EtherCAT specification defined by a communication profile family 12 of IEC 61158 and IEC 61784 Part 2 will be described as an example. An effect of the invention is not limited to the EtherCAT specification.

In FIG. 4, the CPU 101 controls the control target device communication control IC 130 via the bus 106 by executing a program stored in the memory 104. Although not shown, a peripheral device may be connected to the CPU 101, and the CPU 101 may control a sensor and an actuator via the peripheral device.

The control target device communication control IC 130 communicates with the control network 122 via a plurality of PHYS 103. The control target device communication control IC 130 is a dedicated IC conforming to an EtherCAT specification defined by a Communication Profile Family 12 of IEC 61158 and IEC 61784 Part 2. The control target device communication control IC 130 may use the nonvolatile storage medium 105 when storing and referring to information required for communication.

Although the control target device communication control IC 130 is connected to the CPU 101 via the bus 106, the control target device communication control IC 130 may be directly connected to the CPU 101 using a dedicated bus. One or both of the memory 104 and the nonvolatile storage medium 105 dedicated to the control target device communication control IC 130 may be separately provided to store information required for processing of the control target device communication control IC 130.

### (Functional Configuration of Control Target Device Communication Control IC 130)

FIG. 5 is a functional block diagram showing a functional configuration example of the control target device communication control IC 130 shown in FIG. 4. The control target device communication control IC 130 shown in FIG. 5 includes four sets of communication ports formed by a combination of a communication transfer control unit 141 and the communication unit 156. In the specification, communication transfer control units 141a to 141d are collectively referred to as the communication transfer control unit 141.

A communication processing unit 140 is connected between the communication transfer control unit 141a and the communication transfer control unit 141d related to two communication ports. For example, the communication processing unit 140 is an IC that executes communication processing conforming to the EtherCAT specification, and is implemented by an EtherCAT processor unit (EPU). The communication processing unit 140 may be connected to other calculation functions and input and output functions (not shown).

The communication transfer control unit 141 is a function unit that transfers a received packet to the adjacent communication transfer control unit 141 or the communication unit 156. A transfer direction between the communication transfer control unit 141 is constant in the control target device communication control IC 130, and here, a packet is transferred in order of the communication transfer control units 141a, 141b, 141c, and 141d. At this time, each communication transfer control unit 141 transfers a packet to the corresponding communication unit 156 or transfers a packet to the adjacent communication transfer control unit 141 based on a setting from the communication processing unit 140 and a connection state of a communication path to which the communication unit 156 is connected.

### (Hardware Configuration of Control System Management Apparatus 124)

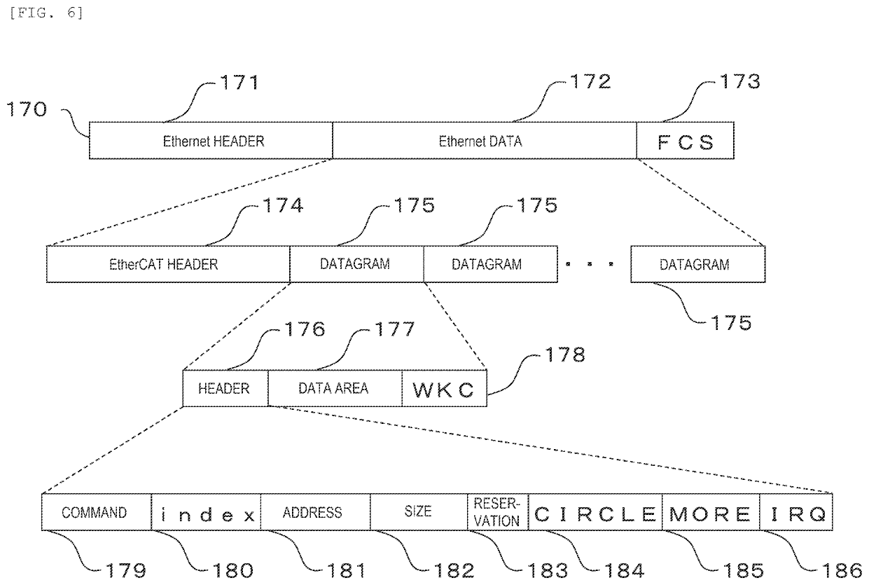

FIG. 7 is a circuit block diagram showing a hardware configuration example of the control system management apparatus 124 shown in FIG. 1. In FIG. 7, a MAC 107 receives a transmission request and transmission data based on software on the CPU 101 and transmits the transmission request and the transmission data to the control network 122 using the PHY 103. Data received from the control network 122 is transferred to the CPU 101, the memory 104, and the nonvolatile storage medium 105 via the bus 106.

Implementation examples of the MAC 107 include an IC such as a field programmable gate array (FPGA), a complex programmable logic device (CPLD), an application specific integrated circuit (ASIC), and a gate array. Alternatively, the MAC 107 may be integrated with the CPU 101.

For example, the MAC 107 is implemented as a media access control (MAC) chip of the IEEE 802.3 standard. The MAC 107 may be included in the CPU 101 or a chipset that controls an information path inside a computer. Although one MAC 107 is shown in the configuration example in FIG. 7, the number of the MAC 107 may be plural. The same applies to the PHY 103 in this regard.

### (Functional Configuration of Control System Management Apparatus 124)

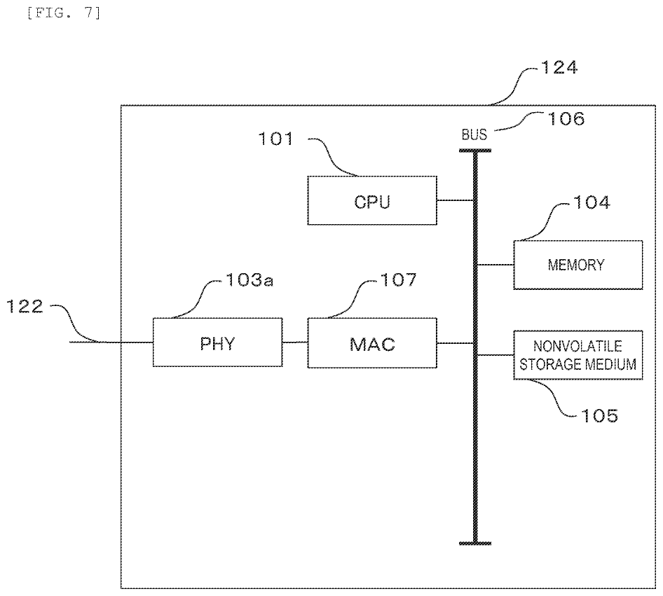

FIG. 8 is a functional block diagram showing a functional configuration example of the control system management apparatus 124 shown in FIG. 1. In FIG. 8, a control recipe 190 includes information such as a step or a process for operating the control system 123, a control content of a machine or an apparatus, a control step, an operation setting, and an operation time. The control recipe 190 may have a format that can be electronically processed, and format examples of the control recipe 190 include XML and Javascript object notation (JSON). The control recipe 190 may be defined by a unique schema. For example, the control recipe 190 is held and stored in the memory 104 or the nonvolatile storage medium 105.

A control communication requirement determining unit 191 receives the control recipe 190 as an input and extracts a control communication requirement 192. For example, the control communication requirement determining unit 191 is implemented by the CPU 101 or an application operating on the CPU 101. A system operator or the like may generate and set the control communication requirement 192 without providing the control recipe 190.

Examples of the control communication requirement 192 include a communication data amount and a communication cycle for the control target device 121, specification of a time of a communication timing (a time offset of transmission timings) for a plurality of control target devices 121, a physical relationship and constraint, a logical relationship and constraint, and the like among a plurality of control target devices 121. The communication data amount may include a size of information (a header or a trailer) required by a communication protocol.

### (Offset Requirement for Communication Requirement)

A time offset of transmission timings is a requirement related to a time difference between communication with a certain control target device 121 and communication with a different control target device 121, and indicates, for example, transmission at intervals of ten milliseconds or more, transmission at intervals of 100 microseconds or less, and transmission at intervals of one millisecond. The time offset of transmission timings may include, for example, information of an allowable time error of plus or minus 10 microseconds.

Examples of the physical relationship and the constraint among the plurality of control target devices 121 include a constraint in which, when a certain control target device 121 is a sensor and is sensing a different control target device 121, the control target devices 121 need to be installed within a predetermined distance due to a constraint such as a sensible range of the sensor. Similarly, examples of the physical relationship and the constraint include a constraint in which a plurality of the control target devices 121 are set apart from one another by a predetermined distance or more due to a constraint such as keeping a distance for safety and implementing the control target devices 121 so as not to affect one another. That is, there is a constraint that installation positions are physically close or far.

In addition, examples of the physical relationship and the constraint include a constraint related to a height direction in which a certain control target device 121 needs to be installed above or below a different control target device 121. Alternatively, examples of the physical relationship and the constraint include a constraint in which a certain control target device 121 needs to be fixed at a specific position. This may include a fixing measure for preventing vibration. Alternatively, there may be a constraint in which the control target device 121 is a mobile object or a movable control target.

Examples of the logical relationship and the constraint among a plurality of control target devices 121 include a constraint occurring in a communication order depending on features of a device. For example, communication with the control target device 121 which is a sensor is performed prior to communication with the control target device 121 which is an actuator. This is because, for example, the control target device 121 which is an actuator can execute control processing, and sensed sensor information is transferred to the control target device 121 which is an actuator with a delay reduced as much as possible.

Alternatively, when the control target device 121 which is an actuator cannot calculate a control command value, for example, there is a configuration in which the control apparatus 120 calculates a control command value via the control apparatus 120. In such a case, communication with the control target device 121 which is an actuator is performed prior to communication with the control target device 121 which is a sensor.

Alternatively, the control communication requirement 192 may indicate whether there is a causal relationship among the control target devices 121 that share such kind of data. It can be said that the control target devices 121 that sense sensor information required for calculating a control command value of the control target device 121 which is an actuator have a causal relationship with one another. On the other hand, since a sensor which is not necessary for calculating a control command value may be a component of the control system 123, it can be said that there is no causal relationship between the control target device 121 which is an actuator and the control target device 121 which is a sensor in such a case.

The control communication requirement 192 may be expressed in a format that can be electronically processed, and format examples of the control communication requirement 192 include XML and JSON. The control communication requirement 192 may be defined by a unique schema. For example, the control communication requirement 192 is held and stored in the memory 104 or the nonvolatile storage medium 105.

A control target device arrangement determining unit 193 determines the control target devices 121 to be connected to a plurality of communication units 156 of the control apparatus 120 and a connection order of the control target devices 121 based on the control communication requirement 192, and outputs control target device arrangement information 194. A method for determining the connection order will be described later.

The control target device arrangement information 194 includes an identifier and a connection position of the communication unit 156 connected to the control apparatus 120 for each control target device 121. The identifier of the communication unit 156 to be connected may indicate a group of the candidate communication units 156 instead of the specific communication unit 156, or may indicate that any communication unit 156 may be connected when there is no constraint. Alternatively, the communication unit 156 may be specified based on identification of the control target device 121. For example, there is a specifying method for connecting to a communication unit 156 different from the communication unit 156 connected to a certain control target device 121.

Examples of a method for defining a connection position include a method of indicating a connection order, a method in which a connection order does not matter (that is, any connection order may be used), and a method indicated by a constraint on a specific control target device 121. Examples of the method indicated by a constraint on a specific control target device 121 include connecting to a certain control target device 121 first (receiving a communication packet from the control apparatus 120 first) or connecting to a certain control target device 121 later (receiving a communication packet from the control apparatus 120 later).

The control target device arrangement information 194 may have a format that can be electronically processed, and format examples of the control target device arrangement information 194 include XML and JSON. The control target device arrangement information 194 may be defined by a unique schema. For example, the control target device arrangement information 194 is held and stored in the memory 104 or the nonvolatile storage medium 105.

A datagram configuration planning unit 195 receives the control target device arrangement information 194 as an input, maps a data area of each control target device 121 to a predetermined area of a logical address, determines a datagram group required for setting the control target device 121 based on a specification and a constraint of the control network 122, and outputs the datagram group as datagram configuration information 196. The datagram configuration planning unit 195 plans a communication timing of the datagram group, and includes the communication timing in the datagram configuration information 196 as needed. For example, the datagram configuration planning unit 195 is implemented by the CPU 101 or an application operating on the CPU 101.

The datagram configuration information 196 includes mapping information of a data area of each control target device 121 to a logical address, a setting command including allocation of the logical address, and datagram information for accessing the logical address. A part of the datagram configuration information 196 may be output as EtherCAT network information (ENI).

The datagram configuration information 196 may have a format that can be electronically processed, and format examples of the datagram configuration information 196 include XML and JavaScript object notation (JSON). The datagram configuration information 196 may be defined by a unique schema. For example, the datagram configuration information 196 is held and stored in the memory 104 or the nonvolatile storage medium 105.

A control target device information storage unit 197 stores information related to the control target device 121. The information includes a communication cycle and a communication data amount when controlling the control target device 121. The communication cycle and the communication data amount are not limited to specific values, and may be a range of possible values.

The information on the control target device 121 stored in the control target device information storage unit 197 may be features of an input and output device provided in the control target device 121. Such features may include input and output points, an update cycle of sensing or actuation, and a software structure when the input and output device is used as an application model. The software structure may be a structure in a programming language or a class definition in an object-oriented language.

Alternatively, the information on the control target device 121 stored in the control target device information storage unit 197 may be a constraint or a protocol on a communication protocol for communicating with the control target device 121. Examples of the information on the control target device 121 stored in the control target device information storage unit 197 include EtherCAT slave information (ESI) in EtherCAT. Alternatively, the information on the control target device 121 may be a physical shape or a setting step for using the device.

### Specific Example of Control Recipe 190

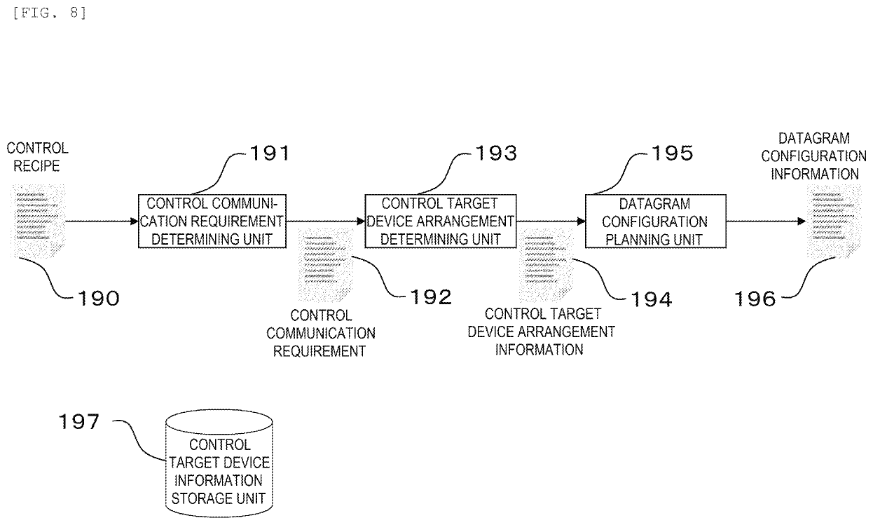

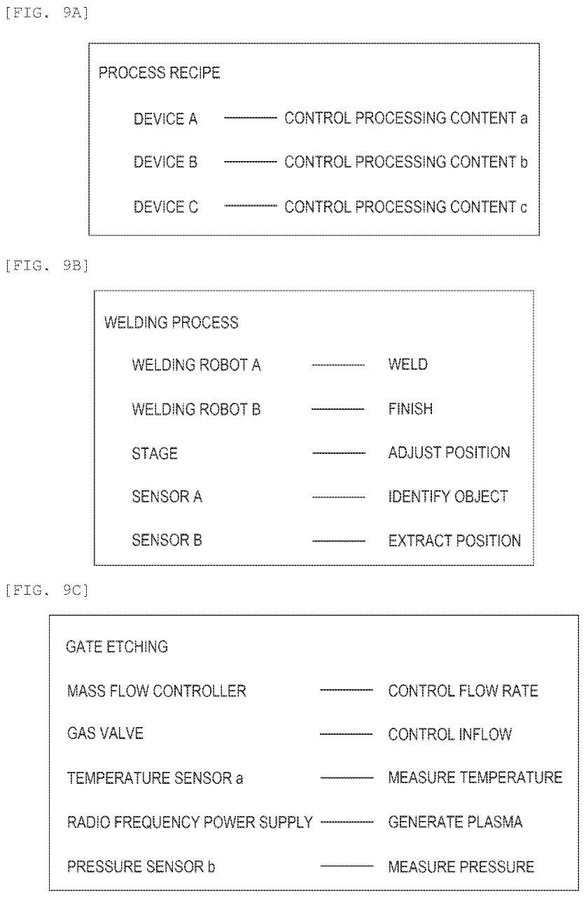

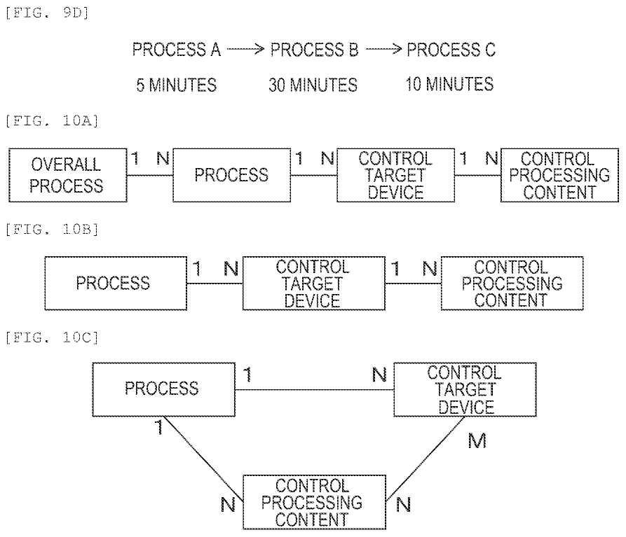

FIGS. 9A, 9B, 9C, and 9D are diagrams showing specific examples of the control recipe 190 shown in FIG. 8. As shown in FIG. 9A, the control recipe 190 includes information on a control apparatus to be used and control processing contents in a specific process of the control system 123. The control recipe 190 may define other constraints such as a positional relationship between a control apparatus and a target object.

FIG. 9B shows an example of the control recipe 190 used in a welding process in a process of an automated vehicle. The control target device 121 includes a robot A that performs welding processing, a robot B that performs finishing processing such as strain removing, a line-driven actuator that moves a platform of an automated vehicle, in other words, a stage, a sensor A that identifies an image of a target object, and a sensor B that specifies a position of the platform of the automated vehicle.

FIG. 9C shows an example of the control recipe 190 used in an etching apparatus which is a semiconductor manufacturing apparatus. The control target device 121 includes a mass flow controller that controls a flow rate of an etching gas, a gas valve that controls an inflow of a gas, a radio frequency power supply for generating plasma for etching, a sensor A that measures a temperature on a wafer, and a sensor B that measures pressure in a chamber.

In certain cases, the control recipe 190 may include an order relationship between control processing, a time relationship (an interval or the like) between control processing, and an execution time of control processing. Processes may be operated by combining a plurality of processes as shown in FIG. 9D. FIG. 9D shows that a plurality of processes are sequentially performed after a predetermined elapsed time. An execution time of each process may be specified when an overall process shown in FIG. 9D are planned, or may be specified when defining each process in FIGS. 9A, 9B, and 9C.

For example, a combination other than those described above includes switching a process to be executed according to a determination result of a specific condition, or repeatedly executing a certain process or a combination of processes until a predetermined condition is satisfied.

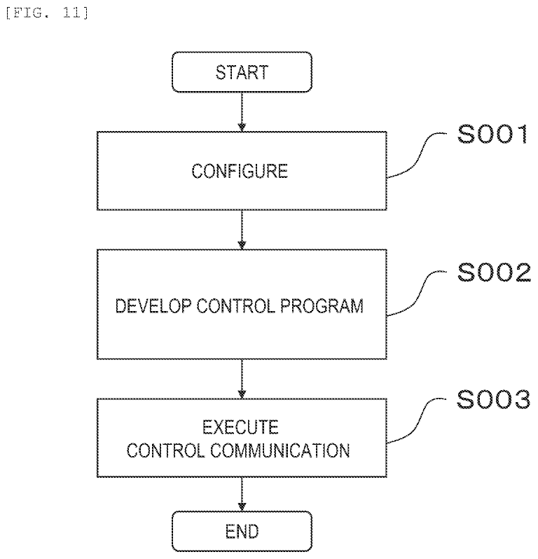

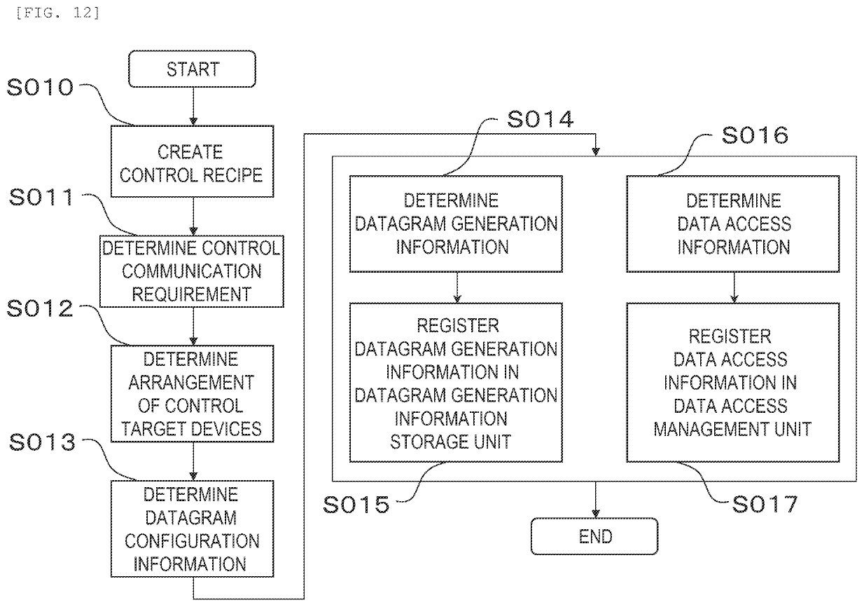

FIG. 10A is a diagram showing an example of a quantity relationship among an overall process, a process, the control target device 121, and a control processing content. FIGS. 10B and 10C are diagrams showing an example of a quantity relationship among the process, the control target device 121, and the control processing content. The overall process includes a plurality of processes, and each process includes a plurality of control target devices 121.

As shown in FIGS. 10A and 10B, each control target device 121 can execute a plurality of control processing contents. Although one control target device 121 is associated with one control processing content in FIGS. 9A, 9B, and 9C, one control target device 121 may be associated with a plurality of control processing contents. In such a case, for example, an execution time of each control processing content, a switching condition, an execution order, and whether parallel execution is possible are defined. Each process may be associated with a plurality of control processing contents, and each control processing content may be associated with a plurality of control target devices 121.

### (Overall Operation Step)

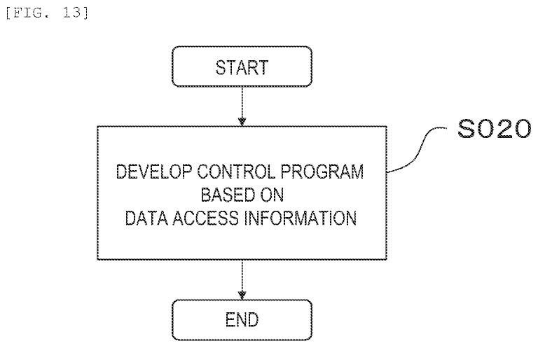

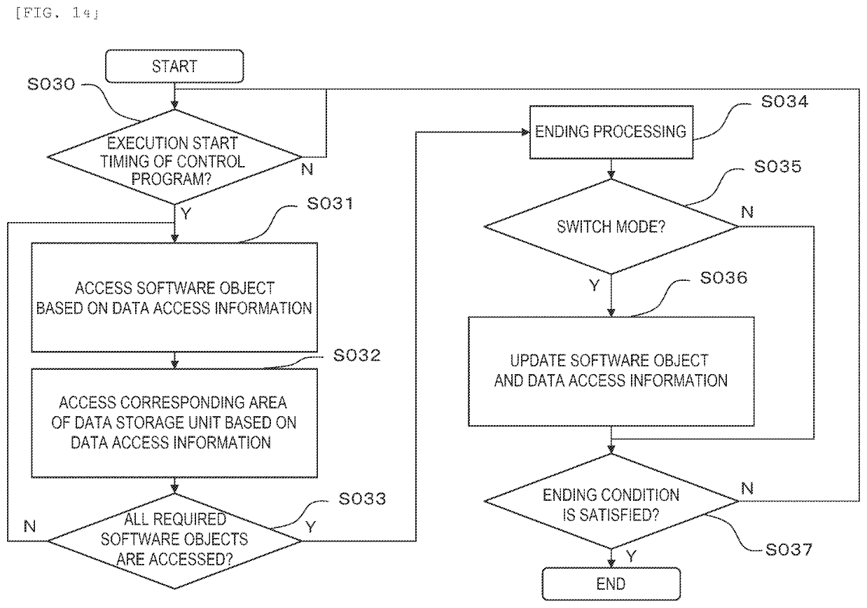

FIG. 11 is a flowchart showing an example of overall operation steps of the control communication system shown in FIG. 1. Each step will be described in detail with reference to FIGS. 12, 13, 14, 15, and 17. In FIG. 11, first, a configuration required for operating the control system 123 is executed (step S001). Next, a control program to be executed by the control apparatus 120 and the calculation unit 159 is developed using a configuration result (step S002). Then, control communication is performed to operate the control system 123 (step S003).

### (Operation Step of Configuration)

FIG. 12 is a flowchart showing an example of operation steps of the configuration shown in FIG. 11. In FIG. 12, first, the control recipe 190 is created (step S010). The control recipe 190 does not need to be newly created as normal, for example, a library of the control recipes 190 created in the past may be created, and the required control recipe 190 may be extracted. Alternatively, the extracted control recipe 190 may be edited and used. For example, an entity that can execute step S010 includes an operator of the control system 123, a system integrator, and a program developer.

Next, the control communication requirement determining unit 191 in the control system management apparatus 124 determines the control communication requirement 192 (step S011). A communication requirement defined in the control recipe 190 may be used as the control communication requirement 192, or a requirement defined in the control recipe 190 may be converted into a communication requirement. For example, a control cycle defined in the control recipe 190 may be set as a communication cycle. Alternatively, a communication data amount may be obtained by adding a size of header or tail information required for executing a communication protocol to a control data amount defined in the control recipe 190. Alternatively, information stored in the control target device information storage unit 197 may be used. In this case, for example, a communication cycle may be determined based on an update cycle of data of the control target device 121.

Then, the control target device arrangement determining unit 193 determines an arrangement of the control target devices 121 (step S012). The arrangement referred to here indicates, among a plurality of communication units 156 (or the PHYs 103) provided in the control apparatus 120, to which communication unit 156 each control target device 121 is connected, and indicates a connection order of a plurality of control target devices 121 connected to the same communication unit 156. As a result, the control target device arrangement determining unit 193 outputs the control target device arrangement information 194.

The control target device arrangement determining unit 193 determines the communication unit 156 to which the control target device 121 is connected so as to satisfy the control communication requirement 192. When the control communication requirement 192 is a communication requirement, an arrangement of the control target devices 121 is determined to satisfy a communication cycle in consideration of a communication data amount and a communication timing.

Alternatively, when the control communication requirement 192 is a physical requirement, the control target device arrangement determining unit 193 connects the control target devices 121 including the control communication requirement 192 having similar attributes to the same communication unit 156. For example, the control target devices 121 whose installation positions are close to one another in height or distance (closeness) are connected to the same communication unit 156. When the installation positions are different in height or when the installation positions are separated, a plurality of communication units 156 provided in the control apparatus 120 are connected to a group of the control target devices 121 having similar attributes.

Grouping in this case may be determined based on an order in which the control target devices 121 are aligned by an index of an installation height of a reference control target device 121, or may be determined by determining a threshold determined based on a feature of the control system 123 and comparing with the threshold. For example, in the case of a semiconductor manufacturing device, the threshold may be determined based on a dimension of a chamber, or in the case of a wirelessly connected control target device 121, the threshold may be determined based on a wirelessly communicable distance.

When a group of the control target devices 121 is classified into a fixed object (the control target device 121 that is stationary and installed in the control system 123) or a mobile object (AGV or the like), the group of the control target devices 121 may be divided into a fixed object group and a mobile object group, and may be connected to different communication units 156. The determination of the arrangement may be performed by evaluating a requirement such as the above-described communication requirement, a physical requirement, and possibility of movement in a composite manner.

Next, the datagram configuration planning unit 195 determines the datagram configuration information 196 (step S013). Thereafter, the generated datagram configuration information 196 is used in two steps of step S014 and step S015, and step S016 and step S017.

In step S014, datagram generation information is determined based on the datagram configuration information 196. The determination may be executed by the calculation unit 159 provided in the control apparatus 120, may be executed by the datagram configuration planning unit 195 provided in the control system management apparatus 124, may be executed by the datagram generating unit 150 or the datagram generation information storage unit 151 in the control apparatus 120, or may be executed by a combination of these units. Alternatively, a function unit that converts the datagram configuration information 196 into datagram generation information may be provided.

Next, the determined datagram generation information is registered in the datagram generation information storage unit 151 (step S015). The registration processing may be executed by any one of the calculation unit 159, the datagram configuration planning unit 195, the datagram generating unit 150, and the datagram generation information storage unit 151, or may be executed by a combination of these units. In steps S014 and S015, the datagram generation information required for operating the control system 123 is stored in the datagram generation information storage unit 151.

On the other hand, in step S016, data access information is determined based on the datagram configuration information 196. The data access information is information representing a relationship between an expression on a control program of an input from and an output to a sensor or an actuator of the control target device 121 and entity data of the input and the output in the data storage unit 152. The data access information includes address conversion information. The address conversion in this case is a conversion between a memory address of a variable representing an input and/or an output of a sensor or an actuator of the control target device 121 on the control program and an address of entity data of the input and the output in the data storage unit 152.

A part of the data access information may include a source code representing an input and an output of a sensor or an actuator of the control target device 121 on the control program. Examples of such a source code include a header file including a structure definition indicating a structure of the input and the output, and a source file of an object-oriented language including a class definition indicating a structure of the input and the output.

For example, the data access information is determined by any one of the calculation unit 159 in the control apparatus 120, the data access management unit 160, and the datagram configuration planning unit 195 in the control system management apparatus 124, or is determined by a combination of these units.

Next, the data access information is registered in the data access management unit 160 (step S017). For example, this registration is performed by any one of the calculation unit 159, the data access management unit 160, and the datagram configuration planning unit 195, or is performed by a combination of these units.

The control communication requirement 192 may be directly set in step S011 without executing step S010. The step S001 of the configuration shown in FIG. 11 is ended by the steps shown in FIG. 12.

### (Development Step of Control Program)

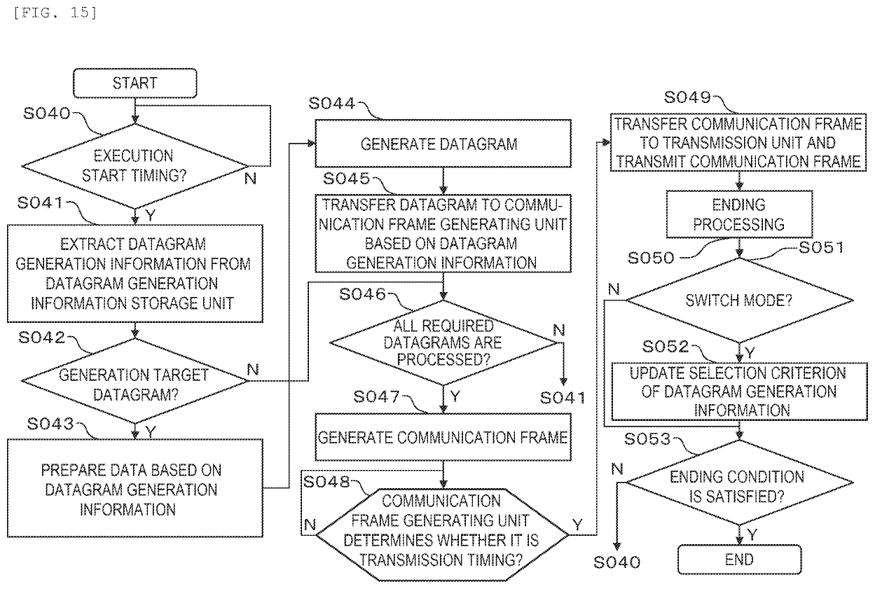

FIG. 13 is a flowchart showing an example of a development step of the control program shown in FIG. 11. In FIG. 13, the control program is developed based on the data access information generated in step S016 (step S020).

### (Execution Step of Control Software)

FIG. 14 is a flowchart showing an example of execution steps of control software executed by the control apparatus 120 when the control system 123 is operated in step S003 shown in FIG. 11. A flow shown in FIG. 14 is executed by, for example, the CPU 101 in the control apparatus 120. In FIG. 14, first, a control application of the calculation unit 159 waits for an execution start timing (step S030). The execution start timing of the control application may be a timing when the control application is activated in a communication cycle specified by the control communication requirement 192. Alternatively, the control application may be activated by an interrupt notification from the communication control IC 102 to the CPU 101.

In terms of function units, for example, the control application is activated by notifying the calculation unit 159 of an interrupt from one or more of the datagram generating unit 150, the communication frame generating unit 153, the transmission unit 154, the receiving unit 155, the communication frame disassembling unit 157, the datagram analyzing unit 158, and the time measurement unit 161.

Examples of an interrupt from the communication control IC 102 to the CPU 101 shown in FIG. 2 and an interrupt from a predetermined function unit to the calculation unit 159 shown in FIG. 3 include a periodic interrupt of the time measurement unit 161 at a communication cycle specified by the control communication requirement 192, a datagram transfer completion interrupt of the datagram generating unit 150, a communication frame transfer completion interrupt of the communication frame generating unit 153, a communication frame transmission completion interrupt of the transmission unit 154, a communication frame reception interrupt of the receiving unit 155, a communication frame reception interrupt of the communication frame disassembling unit 157, a datagram reception interrupt or an analysis processing completion interrupt of the datagram analyzing unit 158.

Next, the control application of the calculation unit 159 accesses a software object representing the control target device 121 via a control program interface for the control target device 121 (step S031). The control program interface is included in the data access information determined in step S016 shown in FIG. 12.

Examples of the software object include a variable on a source code of a control program and an instance in an object-oriented language. A type of the variable includes a structure and a union. Alternatively, the software object is a predetermined area expanded in the memory 104, and is specified by an address and an occupation size on the memory 104. In step S031, processing is executed for an unprocessed software object.

Subsequently, the data access management unit 160 accesses the corresponding area of the data storage unit 152 with reference to the data access information based on an access of the control application (step S032). At this time, when an access type is writing, a value specified in step S031 is writing in the area of the data storage unit 152, and for example, the value specified by the variable is set in the area of the data storage unit 152. On the other hand, when the access type is reading, a value read from the area of the data storage unit 152 is set to be a value of the control program interface (for example, a variable) specified in step S031.

Next, the calculation unit 159 determines whether all required software objects are accessed (step S033). This determination may be performed based on whether all software objects in the data access information are accessed, or may be performed based on whether all required software objects are accessed when a total access size of individual software objects exceeds a predetermined value.

The predetermined value for comparing the total access size is, for example, a maximum size of a communication frame. An access size to each software object may include a size of header and/or tail information on a communication protocol. Alternatively, it may be clearly indicated that all required software objects are accessed by a dedicated API on a program.

When it is determined in step S033 that all required software objects are accessed (Y in step S033), predetermined ending processing is executed (S034).

Examples of the ending processing includes notifying the data storage unit 152 and the datagram generating unit 150 that updating of a required area of the data storage unit 152 is ended.

In a case where the data storage unit 152 has a plurality of storage areas in order to enable an exclusive access from a plurality of function units, examples of the ending processing include requesting copying or switching among internal storage areas. Specifically, examples of the ending processing include copying contents of a storage area for the data access management unit 160 to a storage area for the datagram generating unit 150, or switching storage areas connected to the data access management unit 160 and the datagram generating unit 150 when a plurality of storage areas are arranged in parallel. Alternatively, when an abnormality occurs in steps from step S031 to step S033, for example, the outside is notified of the occurrence of an abnormality. For example, when a total data access size exceeds a predetermined value, the outside is notified of such an abnormality.

Examples of the ending processing include notifying of a communication abnormality in the bus 106, an access abnormality in the memory 104 and the nonvolatile storage medium 105, a soft error temporary failure of a semiconductor) in the CPU 101, the memory 104, and the nonvolatile storage medium 105 that are implemented as a calculation unit and a storage unit of a function unit, or the like, when accessing an area of the data storage unit 152. In order to detect such an abnormality, for example, a device or a function unit having an error checking and correction (ECC) function is used, or data is stored in the data storage unit 152, the memory 104, and the nonvolatile storage medium 105 together with error checking and correction such as a parity check.

By notifying the outside of such an abnormality, a system operator or the like can notice the abnormality and take necessary measures. As a result, execution and operation of the control system 123 can be stabilized, normalized, and recovered. For example, when a data access size exceeds a predetermined value, a reason may be that information is erroneously determined by one or more of the control communication requirement determining unit 191, the control target device arrangement determining unit 193, and the datagram configuration planning unit 195. By investigating the reason, when there is a problem in one or more of the control communication requirement determining unit 191, the control target device arrangement determining unit 193, and the datagram configuration planning unit 195, the problem is solved, thereby making a corresponding function unit highly reliable.

Alternatively, in a case where a system operator or the like uses these function units, when the system operator makes an erroneous setting, for example, the setting is reconsidered and a function for preventing an erroneous setting is added to the control communication requirement determining unit 191, the control target device arrangement determining unit 193, and the datagram configuration planning unit 195. Specifically, for example, a user interface when operating these function units is improved, and a check function for an assumed condition such as a size upper limit is added.

When it is determined in step S033 that not all required software objects are accessed (N in step S033), the processing returns to step S031, and remaining software objects are accessed. On the other hand, when the ending processing is executed in step S034, it is determined whether to switch a mode (step S035). Here, the mode is defined as a set of accesses to a series of software objects.

For example, in the case of EtherCAT, a state transition defined by an EtherCAT state machine (hereinafter, ESM) is defined for the control target device 121. Init, Pre-Operational (PreOp), Safe-Operation (SafeOp), Operational (Op), and Bootstrap (Boot) are defined as states in the ESM.

Processing to be executed is defined for each state, and examples of the processing include a control input and output, an allocation of a logical address, an exclusive access setting of Sync Manager, and a mailbox communication setting. Accordingly, as the state changes, a configuration of a datagram to be transmitted also changes. Therefore, a datagram for a specific state, that is, a set of accesses to a software object is defined as a mode.

For example, the mode switching determination in step S035 is performed based on such a state change in the ESM. The state is reflected in a value of a predetermined register of each control target device 121 when corresponding processing is executed and ended in each control target device 121 based on a state change request from the control apparatus 120. Therefore, a change in the value refers to a change in the state.

For example, it is determined to switch a mode in step S035 when a state changes to a predetermined state in all of the control target devices 121 that are communication targets in a current mode. Alternatively, for example, it is determined to switch a mode when states of a predetermined part of the control target devices 121 change. Alternatively, a mode change may be explicitly instructed by a system operator or the like. Alternatively, it may be determined to switch a mode when a predetermined time elapses or when periodic communication is performed a predetermined number of times.

When it is determined to switch a mode in step S035 (Y in step S035), a software object to be accessed and related data access information are updated (step S036). When the software object and the data access information are updated in step S036, an ending condition is determined (step S037). The same applies to a case where the mode is not switched in step S035 (N in step S035). Examples of the ending condition include reaching a predetermined time, elapse of a predetermined time, and executing control a predetermined number of times. Alternatively, examples of the ending condition include reaching predetermined control performance. Alternatively, a system operator or the like may explicitly instruct to end processing.

When it is determined in step S037 that the ending condition is satisfied (Y in step S037), the processing is ended. When it is determined in step S037 that the ending condition is not satisfied (N in step S037), the processing returns to step S030. The mode switching processing in steps S035 and S036 may be executed first in steps shown in FIG. 14. That is, for example, the mode switching processing is executed before step S030 or is executed after step S030.

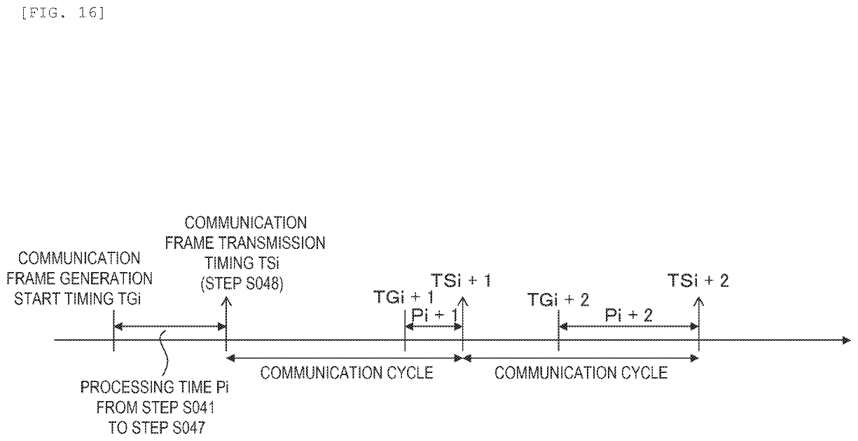

FIG. 15 is a flowchart showing an example of execution steps of transmission processing executed by the control apparatus 120 when the control system 123 is operated in step S003 shown in FIG. 11. In FIG. 15, first, the datagram generating unit 150 waits for an execution start timing (step S040). The execution start timing of the datagram generating unit 150 may be a timing when the datagram generating unit 150 is activated in a communication cycle specified by the control communication requirement 192. For example, the communication cycle is implemented by a periodic interrupt of the time measurement unit 161.

Alternatively, the datagram generating unit 150 may be activated in response to a notification from the calculation unit 159. The notification from the calculation unit 159 to the datagram generating unit 150 is, for example, a notification indicating to start or end a data access to the data storage unit 152 by the calculation unit 159. An ending notification from the calculation unit 159 may be used as the execution start timing of the datagram generating unit 150, and steps in FIGS. 14 and 15 may be continuously executed.

The datagram generating unit 150 may be activated at a transmission timing defined in the datagram generation information. Alternatively, the datagram generating unit 150 may be activated at a cycle that is a greatest common divisor of cycles defined by a plurality of pieces of datagram generation information. A first start time may be set by a system operator or the like, and the time may be set based on a time of the control apparatus 120. Alternatively, the time may be set based on a time system synchronized with a time synchronization protocol such as a distributed clock protocol.

Next, the datagram generating unit 150 extracts datagram generation information from the datagram generation information storage unit 151 (step S041). Then, the datagram generating unit 150 determines whether the datagram generation information extracted in step S041 is a datagram generation target (step S042). Whether the datagram generation information extracted in step S041 is a datagram generation target may be determined according to whether the datagram generation information includes valid or invalid information, and when the datagram generation information includes valid information, the datagram generation information may be determined as a generation target. In the above-described ESM, the datagram generation information may include a state in which a datagram generated according to the datagram generation information is to be transmitted, and when the state matches a state specified as the control apparatus 120, the datagram generation information may be determined as a generation target.

Alternatively, the datagram generation information may include a transmission cycle, and when an elapsed time from a previous transmission time matches the transmission cycle or the transmission cycle elapses, the datagram generating unit 150 may determine the datagram generation information as a generation target. In the case of such a configuration, for example, a unit for storing the previous transmission time may be provided, and the previous transmission time may be stored in the datagram generation information, or the datagram generating unit 150 may include a storage unit and store the previous transmission time. Alternatively, a subsequent scheduled transmission time may be stored, and when the time reaches, the datagram generation information may be determined as a generation target.

A transmission timing may be defined using a predetermined transmission pattern instead of a fixed transmission cycle. For example, it is assumed that transmission is performed at intervals of 200 microseconds, 300 microseconds, and 500 microseconds in a cycle of one millisecond, and when an elapsed time from a previous transmission time matches such a transmission pattern or a transmission cycle elapses, the datagram generating unit 150 determines the datagram generation information as a generation target.

A determination criterion for a generation target may be any one or more of the above-described determination criteria. There may be a plurality of cases including a case where any one condition is matched (a logical sum), a case where all conditions are matched (a logical product), or determination is performed according to any one logical formula. With regard to the logical formula, the datagram generation information is determined as a generation target, for example, when “the datagram generation information includes valid information, and states match each other or a transmission timing matches a predetermined condition”.

When it is determined in step S042 that the datagram generation information is a generation target (Y in step S042), the datagram generating unit 150 prepares data based on the datagram generation information (step S043). At this time, the information initially referred to in the datagram generation information is a command. When a datagram to be generated is a write command, the write command is a command (write or a write direction) from the control apparatus 120 to the control target device 121, and data corresponding to a command value is extracted from the data storage unit 152.

At this time, the datagram generating unit 150 refers to information indicating a position and a size of target data in the data storage unit 152 in the datagram generation information. Required data can be extracted from the data storage unit 152 using the position and the size. A storage position of the data may be included in the datagram generation information, or when there is an order in the datagram generation information, the storage position of the data may be calculated by integrating a size of datagram generation information located prior to an order of the extracted datagram generation information.

When storage areas of the data storage unit 152 are defined by a write command and a read command, for example, a storage position is calculated by adding a size of datagram generation information of the write command only. Whether the write command includes a special command such as an auto increment read multiple write (ARMW) command or a configured read multiple write (FRMW) may be statically defined in advance by a system operator or the like.

On the other hand, when a datagram to be generated is a read command, the control apparatus 120 performs communication (reading and a reading direction) for acquiring information on the control target device 121, and the datagram generating unit 150 generates a datagram whose content is empty or zero and whose data size is a read size without extracting data from the data storage unit 152. This is because a data area corresponding to the read size is required for a read command in the EtherCAT. When there is a feature that a size is constant in the control system 123, size information may not be included in the datagram generation information.

In the case of a special command such as an ARMW command or an FRMW command which reads only a specified control target device 121 and writes data to the other control target devices 121, the datagram generating unit 150 may extract data from the data storage unit 152, or in the case of a read command, the datagram generating unit 150 may generate a datagram whose content is empty or zero and whose data size is a read size. Switching between the two cases may be performed based on address information included in the same datagram generation information. For example, when a command is ARMW and an auto increment address is 0, the control target device 121 adjacent to the control apparatus 120 is read.

In such a case, since transmitted datagram information is immediately overwritten by reading processing on the adjacent control target device 121, processing of extracting data from the data storage unit 152 in the control apparatus 120 is no longer necessary. Therefore, when a command is ARMW and an auto increment address is 0, for example, data is not extracted from the data storage unit 152.

Subsequently, the datagram generating unit 150 generates a datagram based on the datagram generation information and the prepared data (step S044). For example, in order to generate the datagram shown in FIG. 6, the datagram generation information includes at least the command 179, the address 181, and the size 182. The index 180, the IRQ 186, and the WKC 178 may be included in the datagram generation information when values are to be specified. When it is not necessary to specify the values of the index 180, the IRQ 186, and the WKC 178, for example, the values are set to be a default value (for example, 0). The MORE 185 may be included in the datagram generation information when it is desired to explicitly indicate whether a datagram is a final datagram.

In step S044, the datagram generating unit 150 generates a datagram by combining header information extracted from the datagram generation information, the data prepared in step S043, and the WKC 178. The datagram generating unit 150 transfers the generated datagram to the corresponding communication frame generating unit 153 based on the datagram generation information (step S045).

A plurality of communication frame generating units 153 are provided and are associated with the individual PHYS 103 shown in FIG. 2. In terms of a relationship between function units, the communication frame generating unit 153 is associated with the communication unit 156. Therefore, the datagram generating unit 150 transfers the datagram to the communication frame generating unit 153 associated with the PHY 103 and the communication unit 156 to which the datagram is to be transmitted. In order to achieve such a transfer, the datagram generation information includes an identifier of the communication frame generating unit 153 that is a transfer destination of the datagram.

Information included in the datagram generation information is not limited to the identifier of the communication frame generating unit 153 as long as the communication frame generating unit 153 that is a transfer destination of the datagram can be identified. For example, the information may include a path between function units connected to the target communication frame generating unit 153. The path is a path between the communication control IC 102 and the PHY 103 in the configuration example shown in FIG. 2.

A plurality of communication frame generating units 153 that are transfer destinations of the datagram may be provided. For example, since a command is a broadcast command (for example, a BRD command, a BWR command, or a BRW command) when a content to be notified to all of the control target devices 121 is acquired or information is acquired from all of the control target devices 121, a datagram is transmitted to all of the communication frame generating units 153. Alternatively, for example, a datagram is transferred to a plurality of communication frame generating units 153 even when the datagram is not transferred to all of the communication frame generating units 153.

In this case, since the datagram is transferred to a plurality of communication frame generating units 153, an expression of the communication frame generating units 153 that are transfer destinations of the datagram, which is included in the datagram generation information, is in a format of a bitmap. For example, each bit indicates the individual communication frame generating unit 153, and a value is indicated by a truth value or 0 and 1. For example, when the truth value is true or when the value is 1, the datagram is transferred to the corresponding communication frame generating unit 153.

When a datagram is transferred to a plurality of communication frame generating units 153, the datagram may be transmitted simultaneously or sequentially. From the viewpoint of an operation of the control system 123, it is desirable to transmit the datagram simultaneously in order to shorten an overall processing delay.

After the datagram is transferred to the communication frame generating unit 153 in step S045, or when it is determined in step S042 that the datagram generation information is not a generation target (N in step S042), the datagram generating unit 150 determines whether all pieces of required datagram generation information are processed (step S046). This determination may be performed based on whether all pieces of datagram generation information in the datagram generation information storage unit 151 are processed, or when a total data size of individual datagram generation information exceeds a predetermined value, it may be determined that all pieces of required datagram generation information are processed. The predetermined value for comparing the total data size is, for example, a maximum size of a communication frame.

The data size of individual datagram generation information may be calculated including a size of header or tail information on a communication protocol. When the MORE 185 is included in the datagram generation information and the MORE 185 is 0 (that is, when there is no subsequent datagram), a datagram may be determined as a final datagram, and it may be determined that all pieces of required datagram generation information are processed. Alternatively, the determination may be performed based on information on other headers included in the datagram generation information. For example, when the command 179 of the datagram generation information is a predetermined command, datagram generation information may be determined as final datagram generation information, or when the index 180, the address 181, and the IRQ 186 are included in the datagram generation information and have predetermined values, datagram generation information may be determined as final datagram generation information.

Further, the datagram generating unit 150 may perform determination based on a combination of a plurality of parameters. For example, when the command 179 and the address 181 have predetermined values at the same time, datagram generation information may be determined as final datagram generation information. The determination is not limited to being performed based on a parameter, and when a value of data extracted from the data storage unit 152 is a predetermined value, datagram generation information may be determined as final datagram generation information. Whether datagram generation information is final datagram generation information may be determined based on a combination of a parameter constituting the header 176 and a value of data extracted from the data storage unit 152.

When it is determined in step S046 that all pieces of required datagram generation information are processed (Y in step S046), the processing proceeds to step S047. When it is determined in step S046 that not all pieces of required datagram generation information are processed (N in step S046), the processing returns to step S041.

In step S047, the communication frame generating unit 153 combines datagrams transferred from the datagram generating unit 150, adds header and tail information according to a communication protocol of the control network 122, and generates a communication frame. In the case of EtherCAT, the Ethernet header 171 and the FCS 173 are combined with a datagram group, as shown in FIG. 6.

An order of connecting the datagrams is, for example, an order in which the datagrams are transferred from the datagram generating unit 150. Alternatively, the datagrams may be rearranged based on configuration contents. For example, the datagrams may be rearranged in ascending order or descending order according to sizes of the datagrams. Alternatively, a datagram that stores a predetermined command may be arranged at the start of the communication frame. Specifically, a read command (an LRD command) for a logical address is arranged and aggregated at the start of the communication frame.

The rearrangement may be reflected in an order of registering datagram generation information in the datagram generation information storage unit 151 in step S015 shown in FIG. 12, or may be reflected in an order of storing datagram generation information in the datagram generation information storage unit 151 after the registration. Alternatively, the rearrangement may be reflected in an order in which the datagram generating unit 150 accesses datagram generation information stored in the datagram generation information storage unit 151, in step S041 shown in FIG. 15.

When the communication frame is generated, the MORE 185 of a final datagram may be set to be 0 (indicating that there is no subsequent datagram), and the MORE 185 of the other datagrams may be set to be 1 (indicating that there is a subsequent datagram). Alternatively, in step S044, it may be determined whether a datagram being generated by the datagram generating unit 150 is a final datagram, and when it is determined that the datagram being generated is a final datagram, the MORE 185 may be set to be 0, and when it is determined that the datagram being generated is not a final datagram, the MORE 185 may be set to be 1. A determination criterion used by the datagram generating unit 150 at this time is the same as that in step S046. Alternatively, a value of the MORE 185 may be included in datagram generation information and reflected when a datagram is generated in step S044.

Next, the communication frame generating unit 153 determines whether it is a transmission timing of the generated communication frame (step S048). At this time, it may be determined that it is a transmission timing immediately after the end of step S047 without particularly determining the transmission timing. Alternatively, transmission may be activated in a communication cycle specified by the control communication requirement 192. Alternatively, a transmission timing may be determined based on a transmission cycle defined by the datagram generation information. For example, the communication cycle is implemented by a periodic interrupt of the time measurement unit 161.

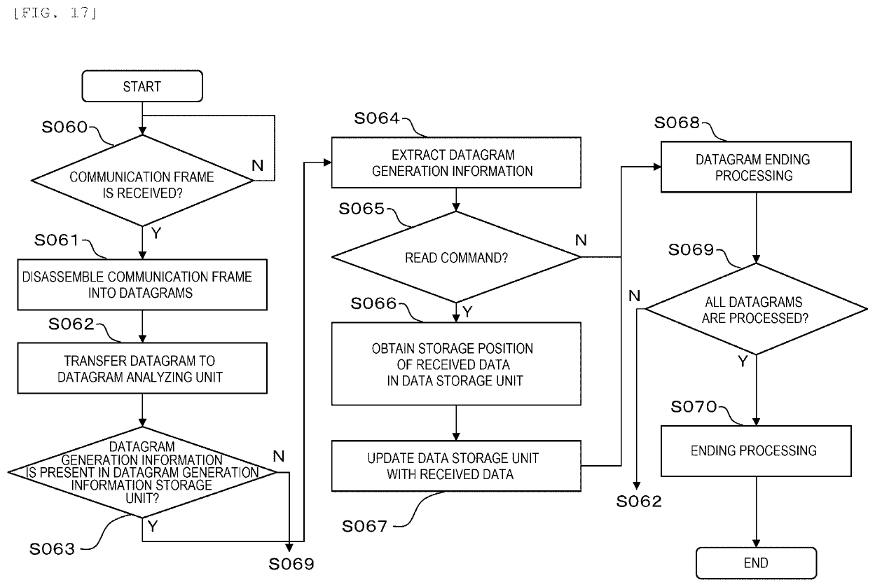

In step S040, the datagram generating unit 150 also waits for a start timing of a communication frame construction step. In order to make periodicity of the start of transmission processing in step S048 accurate, the execution start timing in step S040 may be a time obtained by subtracting processing time from step S041 to step S047 from a periodic execution timing in step S048. FIG. 16 is a diagram showing an example of a relationship between the execution start timing in step S040 and the periodic execution timing in step S048 in FIG. 15.

Due to a reason such as execution of a transmission pattern described in step S042, selected datagram generation information may be changed depending on a cycle. In view of such a circumstance, a processing time Pi from step S041 to step S047 may change depending on a cycle i, as shown in FIG. 16. In such a case, a time obtained by subtracting a maximum value of the processing time Pi from step S041 to step S047 from a periodic execution timing TSi of step S048 may be set as an execution start timing TGi in step S040. Alternatively, a time obtained by subtracting the processing time Pi from step S041 to step S047 corresponding to the cycle i from the periodic execution timing TSi of step S048 every time may be set as the execution start timing TGi in step S040.

A predetermined margin may be added to the processing time Pi from step S041 to step S047. When indeterminism of the processing time is high, the margin needs to be increased, and when determinism of the processing time is high, the margin can be reduced. It is desirable that the communication control IC 102, the datagram generating unit 150, the communication frame generating unit 153, and the transmission unit 154 execute hardware processing such as FPGA, CPLD, and ASIC.

By adopting such an implementation form, determinism of the processing time Pi from step S041 to step S047 can be improved, the execution start timing TGi in step S040 and the periodic execution timing TSi in step S048 can be determined with high accuracy, and highly accurate periodic communication can be achieved. When the execution start timing TGi in step S040 and the periodic execution timing TSi in step S048 can be determined with high accuracy by reducing the margin, a communication cycle or a control cycle can be shortened, and accordingly, performance of the control system 123 can be improved.

Returning to FIG. 15, when it is determined in step S048 that it is the transmission timing of the communication frame, the communication frame generating unit 153 transfers the communication frame to the transmission unit 154 and transmits the communication frame via the transmission unit 154 (step S049). Next, the communication frame generating unit 153 executes predetermined ending processing (step S050). In the ending processing, for example, the calculation unit 159 is notified that the transmission is ended. Alternatively, in the ending processing, for example, when an abnormality occurs in steps from step S041 to step S049, the calculation unit 159 is notified of the occurrence of the abnormality. For example, when a total data access size exceeds a predetermined value, the calculation unit 159 is notified of such an abnormality.

In the ending processing, when a communication abnormality during accessing an area of the data storage unit 152, an access abnormality in the memory 104 and the nonvolatile storage medium 105 that implement the data storage unit 152, a soft error (a temporary failure of a semiconductor) in the communication control IC 102, the memory 104, and the nonvolatile storage medium 105 that constitute a calculation unit or a storage unit of a function unit, or the like occurs, the calculation unit 159 may be notified of such an abnormality. In order to detect such an abnormality, for example, a device or a function unit having an error checking and correction (ECC) function is used, or data is stored in the data storage unit 152, the memory 104, and the nonvolatile storage medium 105 together with error checking and correction such as a parity check.

Measures and effects for such an abnormality notification are similar to those in step S034 shown in FIG. 14. Specifically, for example, a notification associated with the ending processing is implemented as an interrupt from the communication control IC 102 to the CPU 101.

Alternatively, in the ending processing, the communication frame generating unit 153 or the transmission unit 154 may store a transmission time of a communication frame. By storing the transmission time, it is possible to measure a communication time when the same datagram is received, and it is possible to evaluate and visualize communication performance, and determine an abnormality by comparing with a timeout value. The transmission time may be stored for each datagram at the time of transferring the datagram in step 045 instead of for each communication frame.

Next, it is determined whether to switch a mode (step S051). The determination of mode switching is similar to that in step S035 shown in FIG. 14. When it is determined to switch the mode in step S051 (Y in step S051), a selection criterion of datagram generation information to be selected is updated (step S052). Alternatively, the datagram generation information stored in the datagram generation information storage unit 151 may be updated.

After step S052, an ending condition is determined (S053). The same applies to a case where the mode is not switched in step S051 (N in step S051). Examples of the ending condition include reaching a predetermined time, elapse of a predetermined time, and executing control a predetermined number of times. Alternatively, examples of the ending condition include reaching predetermined control performance. Alternatively, a system operator or the like may explicitly instruct to end processing. When it is determined in step S053 that the ending condition is satisfied (Y in step S053), the processing is ended. When it is determined in step S053 that the ending condition is not satisfied (N in step S053), the processing returns to step S040.

The mode switching processing in steps S051 and S052 may be executed first in steps shown in FIG. 15. That is, for example, the mode switching processing is executed before step S040 or is executed after step S040. Steps from step S047 to step S050 are executed by each of a plurality of PHYS 103, the communication frame generating unit 153, and the transmission unit 154, and thus these steps may be executed in parallel.

Since datagram generation information may include a communication cycle with the communication frame generating unit 153 that is a transfer destination, a configuration of the communication frame may change for each communication unit 156 over time. Accordingly, for example, processing is independently executed for each communication unit 156 and each associated function unit (the communication frame generating unit 153 and the transmission unit 154). Therefore, for example, a plurality of communication frame generating units 153 are provided for each communication unit 156 and execute the steps shown in FIG. 15.

A plurality of datagram generation information storage units 151 may be provided for each communication unit 156. With such a configuration, it is possible to flexibly implement the control system 123 according to a control communication requirement of the control system 123 and the control target device 121, a constraint on a physical arrangement of the control system 123, and the like.

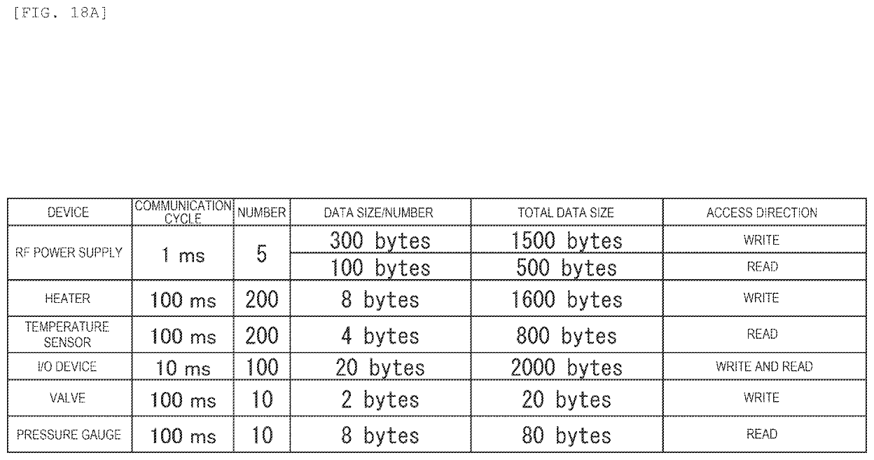

FIG. 17 is a flowchart showing an example of execution steps of reception processing executed by the control apparatus 120 when the control system 123 is operated in step S003 shown in FIG. 11. In FIG. 17, first, the receiving unit 155 waits for reception of a communication frame (step S060). When the receiving unit 155 receives the communication frame, the receiving unit 155 transfers the communication frame to the communication frame disassembling unit 157, and the communication frame disassembling unit 157 disassembles the received communication frame into datagrams (step S061). When the received communication frame is not an EtherCAT frame, the communication frame may be discarded and the processing may be ended, or the calculation unit 159 or the like may be notified that a non-EtherCAT frame is received, or the calculation unit 159 or the like may be notified of the received communication frame.

After the communication frame disassembling unit 157 disassembles the communication frame into datagrams, the communication frame disassembling unit 157 transfers the individual datagrams to the datagram analyzing unit 158 (step S062). When the datagram analyzing unit 158 receives the datagram, the datagram analyzing unit 158 searches the datagram generation information storage unit 151 to determine whether there is datagram generation information corresponding to the datagram (step S063).

In step S063, whether there is corresponding datagram generation information is determined based on a content of the received datagram. That is, when header information or a data length in the received datagram matches header information included in the datagram generation information, the datagram analyzing unit 158 determines that there is datagram generation information. At this time, the determination may be performed when a part of parameters such as the command 179 and the address 181 matches without determining that all parameters of the header information match.

For example, in the case of an auto increment address command, since each control target device 121 processes a node address (specifically, adds 1), the node address may have a value different from that at the time of transmission. Therefore, for example, a determination range of different header information is changed or an expected value of a comparison target is calculated according to a value of a part of the header information. Specifically, when the command 179 is an auto increment address command, for example, only a register address is compared without determining a node address in the address 181, or an expected value of a node address is calculated based on the number of control target devices 121 (the number of control target devices 121 is added to a node address at the time of transmission) and the expected value is compared.

When the datagram generation information storage unit 151 stores the corresponding datagram generation information (Y in step S063), the datagram analyzing unit 158 extracts the datagram generation information (step S064). Next, the datagram analyzing unit 158 determines whether the received datagram is a read command (step S065). When the received datagram is a read command, received data needs to be reflected in the data storage unit 152. Therefore, when the received datagram is a read command (Y in step S065), the datagram analyzing unit 158 determines a storage position of the received data in the data storage unit 152 based on the searched datagram generation information (step S066).

The storage position of the received data may be included in the datagram generation information, or when there is an order in the datagram generation information, the storage position of the received data may be calculated by integrating a size of datagram generation information located prior to an order of the extracted datagram generation information. At this time, when storage areas of the data storage unit 152 are defined by a write command and a read command, for example, the storage position may be calculated by adding a size of datagram generation information of the read command only. Whether a special command such as an ARMW command or an FRMW command is included in the read command may be determined by a system operator or the like, or may be statically defined in advance.

After the storage position of the received data is determined, the datagram analyzing unit 158 extracts the received data from the datagram and updates a corresponding area of the data storage unit 152 (step S067). After step S067, or when the received datagram is not a read command in step S065 (N in step S065), ending processing of datagram processing is executed (step S068). The ending processing of the datagram processing is, for example, counting up the number of times of receiving a datagram and a received data size. Alternatively, for example, retransmission processing may be executed when an abnormality occurs.

As an abnormality determination method, for example, an expected value of the WKC 178 at the time of receiving the datagram is the datagram generation information, the expected value is compared with the WKC 178 of the received datagram, and when the expected value does not match the WKC 178, it is determined that there is an abnormality. Alternatively, for example, a timeout value is determined, and when a time from a datagram transfer time in step S045 or a communication frame transmission time in step S049 shown in FIG. 15 to a time when the communication frame is received in step S060 or a time when the datagram is received in step S062 is larger than the timeout value, it is determined that there is an abnormality. In this case, the timeout value may be included in the datagram generation information. be Alternatively, an abnormality may determined based on contents of a received packet or datagram. Specifically, for example, the FCS 173 has an abnormal value, a predetermined value is included in the data area 177, and a predetermined bit of the IRQ 186 is 1 for an interrupt notification from the control target device 121. When an abnormality occurs, the abnormality may be notified and presented to the outside such as the calculation unit 159.

After step S068 or when it is determined in step S063 that there is no datagram generation information corresponding to the received datagram (N in step S063), the datagram analyzing unit 158 determines whether all datagrams are processed (step S069). For example, it is determined whether all datagrams included in the received communication frame are processed. Alternatively, it may be determined that all datagrams are processed when a datagram matching a predetermined condition such as a value of a header parameter and a value of the WKC 178 is received.

When it is determined in step S069 that all datagrams are processed (Y in step S069), ending processing of the communication frame is executed (step S070). When it is determined in step S069 that not all datagrams are processed (N in step S069), the processing returns to step S062. The ending processing of the communication frame is, for example, counting up the number of times of receiving a communication frame and a received data size. Alternatively, for example, retransmission processing may be executed when an abnormality occurs. A criterion for determining an abnormality in this case is similar to that in step 068.

When retransmission is performed in response to an abnormality, retransmission may be performed in units of communication frame, or retransmission may be performed in units of datagram determined to be abnormal due to WKC mismatch or the like. Alternatively, retransmission may be performed when an abnormality is detected in a cyclic redundancy check (CRC) using the FCS 173 in the received communication frame. The abnormality determination by CRC may be performed immediately after the communication frame is received in step S060 (Y in step S060). In this case, when an abnormality is detected, retransmission processing may be executed or the processing may return to step S060 again. In an abnormality determination, for example, the number of times of abnormality occurrence is counted up, the outside such as the calculation unit 159 or the like is notified of an abnormality.

In the ending processing of the communication frame in step 070, for example, the calculation unit 159 is notified that the reception processing is ended. At this time, the calculation 159 may be notified that the reception processing is ended for each piece of reception processing of a received communication frame for each communication unit 156. Alternatively, when a predetermined time elapses, when a predetermined number of communication frames are processed or when a predetermined received data size (a reception size of a communication frame or a total reception size for a predetermined area shown in FIG. 6) is processed, and when a predetermined number of datagrams of the control target device 121 are processed, the calculation unit 159 may be notified that the reception processing is ended. These statistical values may be determined for each communication unit 156, or may be determined by a total value of all communication units 156 or a plurality of communication units 156. When the calculation unit 159 is notified that the reception processing is ended, for example, the datagram analyzing unit 158 includes a unit that presents an occurrence factor.

In the ending processing of a communication frame, for example, the data storage unit 152 or the calculation unit 159 is notified that updating of a required area of the data storage unit 152 is ended. Alternatively, when the data storage unit 152 has a plurality of storage areas in order to enable an exclusive access from a plurality of function units, examples of the ending processing include requesting copying or switching among internal storage areas. Specifically, examples of the ending processing include copying contents of a storage area for the datagram analyzing unit 158 to a storage area for the data access management unit 160, or switching storage areas connected to the data access management unit 160 and the datagram generating unit 150 when a plurality of storage areas are arranged in parallel.

Alternatively, in the ending processing of communication frame, for example, when an abnormality occurs in steps from step S061 to step S069, the calculation unit 159 is notified of the occurrence of the abnormality. For example, when a format of the received communication frame does not match a format defined by a communication protocol, the calculation unit 159 is notified of such an abnormality.

Alternatively, when a communication abnormality during accessing an area of the data storage unit 152, an access abnormality in the memory 104 and the nonvolatile storage medium 105 that implement the data storage unit 152, a soft error in the communication control IC 102, the memory 104, and the nonvolatile storage medium 105 that constitute a calculation unit or a storage unit of a function unit, an abnormality in step S068, or the like occurs, the calculation unit 159 may be notified of such an abnormality. In order to detect such an abnormality, for example, a device or a function unit having an error checking and correction (ECC) function is used, or data is stored in the data storage unit 152, the memory 104, and the nonvolatile storage medium 105 together with error checking and correction such as a parity check.

In a case where the calculation unit 159 is notified of the occurrence of an abnormality, when the communication unit 156 in which an abnormality occurred, a communication frame, a datagram, and the like can be specified, for example, the calculation unit 159 is notified by combining identification information of one or more of the communication unit 156 in which an abnormality occurred, the communication frame, the datagram, and the like. Measures and effects for such an abnormality notification are similar to those in step S034 shown in FIG. 14. Specifically, for example, a notification associated with the ending processing is implemented as an interrupt from the communication control IC 102 to the CPU 101.

Alternatively, in the ending processing of communication frame, the communication frame generating unit 153 or the transmission unit 154 may store a reception time of the communication frame. By storing the reception time, it is possible to measure a communication time when the communication frame is received, and it is possible to evaluate and visualize communication performance, and determine an abnormality by comparing with a timeout value. The reception time may be stored immediately after the communication frame is received in step S060 (Y in step S060). For example, the reception time is measured for each communication unit 156. In this manner, it is possible to measure a communication time for each communication unit 156, and it is possible to confirm and verify whether a connection configuration of the control target device 121 for each communication unit 156 is appropriate.

The mode switching processing in steps S051 and S052 shown in FIG. 15 may be executed after step S070. The reception processing executed by the calculation unit 159 is included in the steps shown in FIG. 14.

### Specific Application Examples

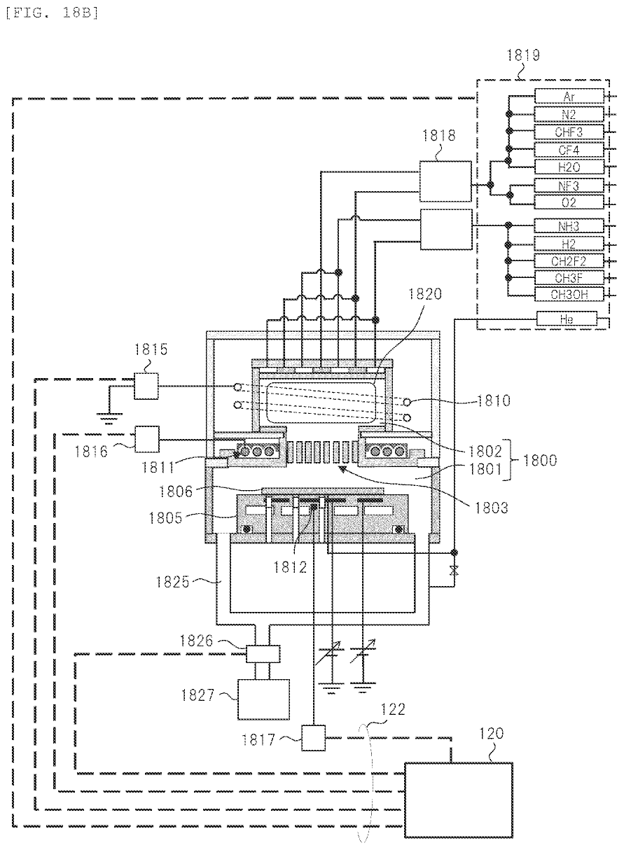

Specific application examples of the steps shown in FIGS. 12, 14, 15, 16, and 17 will be described. FIG. 18A is a diagram showing an example of specific components and required specifications of the control system 123 shown in FIG. 1. Here, it is assumed that the control system 123 is a semiconductor manufacturing apparatus and includes a plurality of devices having requirements shown in FIG. 18A. The requirements shown in FIG. 18A corresponds to the control communication requirement 192 in step S011 shown in FIG. 12. The control communication requirement 192 may be generated by analyzing the control recipe created in step S010 shown in FIG. 12, or may be defined by a system operator or the like.

In FIG. 18A, an I/O device represents, for example, an input and output device such as a mass flow controller or a stage drive system. An access direction includes writing a direction of specifying a command value from the control apparatus 120 to the control target device 121, and reading a direction in which the control apparatus 120 acquires information from the control target device 121. For example, the I/O device is a device capable of writing and reading the same area, and a command value is specified in the case of writing, sensor information is acquired in the case of reading, and the like.

FIG. 18B is a schematic diagram showing a specific configuration example of the control system 123 shown in FIG. 18A. The control system 123 shown in FIG. 18B constitutes a plasma processing apparatus, and for example, the control system 123 constitutes an ICP etching apparatus here. The plasma processing apparatus shown in FIG. 18B includes a processing chamber 1800 provided with a wafer processing chamber 1801 and a discharge processing chamber 1802. The processing chamber 1800 is located inside a vacuum container.

Plasma 1820 is formed in the depressurized processing chamber 1800, specifically, in the discharge processing chamber 1802. Specifically, a processing gas for forming plasma is supplied into the discharge processing chamber 1802 from a mass flow controller 1819 that is an I/O device via a gas distributor 1818. The mass flow controller 1819 adjusts a flow rate of the processing gas. In a state where the processing gas is supplied, a radio frequency power supply (an RF power supply) 1815 supplies radio frequency power to an ICP coil (an electrode) 134 for forming plasma. Accordingly, the plasma 1820 is formed.

A stage 1805 on which a wafer 1806 is located is provided in the processing chamber 1800, specifically, in the wafer processing chamber 1801. The wafer 1806 is processed using the plasma 1820 formed in the discharge processing chamber 1802. In the example, neutral particles such as active species (radicals) in the plasma 1820 are introduced into the wafer processing chamber 1801 through a flow path 1803, and are adsorbed on a surface of a film to be processed on an upper surface of the wafer 1806 to form a compound layer.

The plasma processing apparatus includes a heater for adjusting a temperature of the wafer 1806, that is, an infrared light lamp 1811 here, and a heater power supply 1816 for supplying power to the infrared light lamp 1811. A temperature sensor for detecting a temperature of the stage 1805 and the wafer 1806, that is, a thermocouple 1812 here, is provided inside the stage 1805. The thermocouple 1812 is connected to a thermocouple thermometer 1817.

An exhaust port 1825 is provided below the stage 1805, and the exhaust port 1825 is connected to an exhaust pump 1827 via a valve 1826. The valve 1826 adjusts an exhaust amount of a gas in the processing chamber 1800. Although not shown, the plasma processing apparatus includes a pressure gauge or the like for measuring pressure in the processing chamber 1800. In such a configuration, controllers of the radio frequency power supply 1815, the heater power supply 1816, the mass flow controller 1819, and the valve 1826 constitute the control target devices 121. The control apparatus 120 controls the control target devices 121 via the control network 122.

In FIG. 18A, the control apparatus 120 includes two communication units 156 of the communication unit 156a and the communication unit 156b. The control target device arrangement determining unit 193 in the control system management apparatus 124 determines the communication unit 156 to which each control target device 121 is connected so as to satisfy the control communication requirement 192 shown in FIG. 18A. Here, a communication time can be calculated according to Formula (1).

$$Communication time = communication frame transmission time + \qquad ( 1 )$$

$$control target device 121 delay + cable transmission delay =$$

$$total data size / communication bandwidth +$$

$$communication delay per device \times number of control target devices 121 +$$

$$total cable length / signal transmission speed$$

In general, since the cable transmission delay of the third term in Formula (1) is negligibly small compared to the communication frame transmission time of the first term and the control target device 121 delay of the second term, the first term and the second term are calculated here.

When all control target devices 121 are connected to one communication unit 156a, a communication time is calculated according to Formula (2). A communication delay per control target device 121 is set to be one microsecond.

$$\begin{matrix}\begin{matrix}( 2000 bytes + 1600 bytes + 800 bytes + \\ 2000 bytes + 20 bytes + 80 bytes ) / \\ 100 Mbps + 1 microsecond \times \\ ( 5 + 200 + 200 + 100 + 10 + 10 )\end{matrix} = 6500 bytes / 100 Mbps + \\ 1 microsecond \times 525 \\ = 520 microseconds + \\ 525 microseconds \\ = 1045 microseconds \\ = 1.045 milliseconds\end{matrix} \qquad ( 2 )$$

Since this value exceeds one millisecond that is a requirement of a communication cycle of the RF power supply, the communication requirement cannot be satisfied. Therefore, a configuration in which all control target devices 121 are connected to one communication unit 156 is not appropriate, and thus, it is necessary to distribute the communication units 156 to which the control target device 121 is to be connected.

In the calculation of the communication time in Formulas (1) and (2), an inter-frame gap (a communication time corresponding to 12 bytes), a preamble (seven bytes), and a communication time of a start frame delimiter (SFD, one byte) when communication frames are separated are not considered. Although it is clear that the communication requirement is not satisfied at the time calculated according to Formula (2), even when the communication time calculated according to Formula (1) satisfies the communication requirement, it is necessary to calculate the inter-frame gap, the preamble, and the SFD according to Formula (3).

$$Communication time = communication frame transmission time + control target device 121 delay + cable transmission delay + overhead for each communication frame \qquad ( 3 )$$

As described above, the overhead for each communication frame in Formula (3) is a processing time including a time such as the inter-frame gap, the preamble, and the SFD.

Examples of a method for determining the communication unit 156 in the control apparatus 120 to which the control target device 121 is to be connected include a method of ranking a group of the control target devices 121 based on a predetermined attribute and sequentially connecting the control target devices 121 to the communication unit 156 within a range satisfying a communication requirement. Examples of the attribute for ranking the control target devices 121 include a type, a communication cycle, a data size, and an access direction of devices shown in FIG. 18A, and a manufacturer and a manufacturer serial number of the control target device 121. When determining the communication unit 156, the determination may be performed by selecting the control target devices 121 one by one, or the determination may be performed for each group of the control target devices 121 grouped based on the same attribute.

Here, examples of a grouping method based on a device type include ranking the control target devices 121 based on shortness of the communication cycle, and determination is performed in order. In FIG. 18A, a device having a shortest communication cycle is the RF power supply. It is assumed that a group of RF power supplies is connected to the communication unit 156a, a communication time of the group of the RF power supplies is calculated according to Formula (4).

$$\begin{matrix}2000 bytes / 100 Mbps + 1 microsecond \times 5 = 160 microseconds + \\ 5 microseconds \\ = 165 microseconds\end{matrix} \qquad ( 4 )$$

Since there is a margin for one millisecond of a communication cycle, when a group of I/O devices having a second shortest communication cycle is added to the communication unit 156a, a communication time is calculated according to Formula (5).

$$\begin{matrix}\begin{matrix}( 2000 bytes + 2000 bytes ) / \\ 100 Mbps + 1 microsecond \times ( 5 + 100 )\end{matrix} = 4000 bytes / 100 Mbps + \\ 1 microsecond \times 105 \\ = 320 microseconds + \\ 105 microseconds \\ = 425 microseconds\end{matrix} \qquad ( 5 )$$

Accordingly, it is determined that the group of I/O devices is connected to the communication unit 156a in addition to the RF power supply group.

A group of heaters, a group of temperature sensors, a group of valves, and a group of pressure gauges have the same communication cycle. When a second attribute is ranked based on smallness of the total data size, the group of valves has the smallest total data size. Here, it is assumed that the group of valves is further connected to the communication unit 156a. A communication time in this case is calculated according to Formula (6).

$$\begin{matrix}\begin{matrix}( 2000 bytes + 2000 bytes + 20 bytes ) / \\ 100 Mbps + 1 microsecond \times ( 5 + 100 + 10 )\end{matrix} = 4020 bytes / 100 Mbps + \\ 1 microsecond \times 115 \\ = 321.6 microseconds + \\ 115 microseconds \\ = 436.6 microseconds\end{matrix} \qquad ( 6 )$$

The group of pressure gauges has a second smallest total data size. Here, it is assumed that the group of pressure gauges is further connected to the communication unit 156a. A communication time in this case is calculated according to Formula (7).

$$\begin{matrix}\begin{matrix}( 2000 bytes + 2000 bytes + \\ 20 bytes + 80 bytes ) / 100 Mbps + \\ 1 microsecond \times ( 5 + 100 + 10 + 10 )\end{matrix} = 4100 bytes / 100 Mbps + \\ 1 microsecond \times 125 \\ = 328 microseconds + \\ 125 microseconds \\ = 453 microseconds\end{matrix} \qquad ( 7 )$$

The group of temperature sensors has the third smallest total data size. Here, it is assumed that the group of temperature sensors is further connected to the communication unit 156a. A communication time in this case is calculated according to Formula (8).

$$\begin{matrix}\begin{matrix}( 2000 bytes + 2000 bytes + \\ 20 bytes + 80 bytes + 800 bytes ) / \\ 100 Mbps + 1 microsecond \times \\ ( 5 + 100 + 10 + 10 + 200 )\end{matrix} = 4900 bytes / 100 Mbps + \\ 1 microsecond \times 325 \\ = 392 microseconds + \\ 325 microseconds \\ = 717 microseconds\end{matrix} \qquad ( 8 )$$

As described above, even when the group of I/O devices, the group of valves, the group of pressure gauges, and the group of temperature sensors are connected to the communication unit 156a in addition to the group of RF power supplies, it is possible to satisfy a communication cycle of one millisecond that is a communication requirement of the group of RF power supplies. A remaining group is a group of heaters, and since the communication time calculated according to Formula (2) when the group of heaters is connected to the communication unit 156a does not satisfy the communication requirement, the group of heaters cannot be all connected to the communication unit 156a. In this case, it may be determined that the group of heaters is connected to the communication unit 156b, or it may be determined that a part of the group of heaters is connected to the communication unit 156a within a range satisfying the communication requirement.

As described above, when the control target devices 121 are grouped based on a predetermined type, calculation is simplified, and it is possible to easily determine the communication unit 156 to which a group of the control target devices 121 is connected in a short calculation time. Although connection to one communication unit 156 is performed from a group having a short communication cycle until the communication requirement is satisfied in the above description, such a determination may be performed from a group having a long communication cycle. In the case of performing calculation in such a manner, the communication unit 156a is connected to the group of heaters, the group temperature sensors, and the group of I/O devices, and the communication unit 156b is connected to the group of RF power supplies.

Alternatively, a group of the control target devices 121 to be connected to the communication unit 156 may be determined by using an optimization algorithm such as a steepest descent method. In this case, examples of an evaluation index include a calculation index based on a numerical value index such as a communication time, a communication cycle, the number of devices, a data size, and a total data size.

For example, when there is a request to equalize the number of connected devices for each communication unit 156, the number of connected devices for each communication unit 156 is calculated, and an optimization algorithm is applied to minimize a variance and a standard deviation of the number of connected devices. Such an optimization algorithm can be similarly applied to a case where there is a request for other indexes such as equalizing a communication time, equalizing a communication cycle, and equalizing a total data size.

Alternatively, the optimization algorithm may be applied to maximize or minimize a value obtained by weighting and adding a plurality of indexes of a communication cycle, the number of devices, a data size, and a total data size. Alternatively, the optimization algorithm may be applied to maximize and minimize a numerical index (including a weighted addition value of a plurality of indexes) such as a communication time, a communication cycle, the number of devices, a data size, and a total data size in a communication network connected to the specific communication unit 156. For example, when there is a request to minimize a communication cycle of a communication network in one communication unit 156, a configuration is determined in which only the group of RF power supplies is connected to the communication unit 156a and the group of heaters, the group of temperature sensors, and the group f I/O devices are connected to the communication unit 156b.

The optimization algorithm may be applied not only to a group grouped based on a predetermined attribute but also to each control target device 121.

According to the above configuration, for example, when a communication time of each communication unit 156 is equalized, communication other than control communication can be performed using a surplus bandwidth. For example, communication of operation information or the like of a device can be used for maintenance such as device diagnosis and life prediction. Alternatively, a communication cycle of the single communication unit 156 is minimized, and when there is a surplus time, the communication cycle can be further shortened, and control performance of the control system 123 can be improved.

For determination of the communication unit 156 that is a connection destination of the control target device 121 automatically determined according to the above methods, the control target device arrangement determining unit 193 may include a graphical user interface (GUI) tool, a human machine interface (HMI) tool, and the like, and a system operator or the like may perform a manual adjustment. In this manner, even when there is a discrepancy between a result of the optimization algorithm and an intention of the system operator, the intention of the system operator can be easily reflected. Alternatively, a requirement or an index different from a requirement or an index determined by the communication unit 156 may be input by the GUI tool or the HMI tool, and a violation may be checked and displayed.

With the configuration described above, the control target device arrangement determining unit 193 can determine the communication unit 156 that is a connection destination of the control target device 121 so as to satisfy the control communication requirement 192. The control target device arrangement determining unit 193 can determine the control target device arrangement information 194 including an identifier of the communication unit 156 that is a connection destination of the control target device 121.

### (In Case of Three or More Ports)

The above-described determination of the control target device arrangement information 194 by the control target device arrangement determining unit 193 is performed in the same manner even when there are three or more communication units 156. When determining an arrangement, the individual communication units 156 may be distinguished and weighted. For example, when the specific communication unit 156 uses a high-performance and high-reliability communication device, a group of control target devices 121 having a short communication cycle or a group of control target devices 121 having a large communication data amount may be preferentially connected.

Alternatively, in a case where the control communication requirement 192 is a physical requirement, when a connection distance to the control target devices 121 is short by using the specific PHY 103 (the communication unit 156) based on a relationship among installation positions of the PHYs 103 on the control apparatuses 120, a group of the control target devices 121 may be preferentially connected to the PHY 103 (the communication unit 156). In a similar example, when an antenna for wireless communication is attached to the PHY 103, the specific control target device 121 may be connected to the specific PHY 103 from the viewpoint of connection reliability of wireless communication with the control target device 121.

(Coping with Abnormality)

In a case where the control communication requirement 192 cannot be satisfied even when all of the communication units 156 are used, a system operator or the like may be notified by an external notification unit or the like. In this case, information about which requirement is lacked and to what extent may be presented for the control communication requirement 192. Alternatively, information about whether the control communication requirement 192 can be satisfied by relaxing certain conditions may be presented.

Examples of a relaxation measure include increasing the number of communication units 156, increasing a communication cycle and a delay constraint, reducing a data size, and reducing the number of control target devices 121 to be connected. In addition, when it is assumed that one relaxation measure or a plurality of relaxation measures are applied, a required amount of change may be calculated and presented to a system operator or the like.

For example, in a case where a requirement of a communication delay is one millisecond, a total data size is 22000 bytes, the number of the control target devices 121 is 400, and two communication units 156 are used, the requirement of the communication delay cannot be satisfied according to Formula (9) even when the communication units 156 are equally allocated. Although a calculation of a header and an inter-frame gap generated by dividing a communication frame is omitted in Formula (9) in order to simplify the calculation from the viewpoint of description, the calculation is included in practice.

$$( 22000 bytes / 2 ) / 100 Mbps + 1 microsecond \times 400 / 2 = 880 microseconds + 200 microseconds = 1.08 milliseconds \qquad ( 9 )$$

In such a case, for example, the following relaxation measures are presented.
Increase at least one communication unit 156.
Increase the communication cycle to 1.08 milliseconds (when only the communication cycle is a target method) . . . . Reduce the data size by 2000 bytes (when only the data size is a target method).
Reduce the number of control target devices 121 to 240 (when only the number of control target devices 121 is a target method). That is, since “(1 millisecond-880 microseconds)/1 microsecond=120” and there are two communication units 156, “120×2=240”.
Reduce the data size by 1000 bytes and reduce the number of control target devices 121 to 320 (when the data size and the number of control target devices 121 are target methods). That is, since “(22000 bytes-1000 bytes)/2)/100 Mbps=840 microseconds”, “(1 millisecond 840 microseconds)/1 microsecond=160”, and there are two communication units 156, “160×2=320”.

In the case of a plurality of target methods, how to allocate the target methods, or a plurality of selections or limit values that can be set may be presented.

With such a configuration, the system operator or the like can grasp a cause of a case where the control communication requirement 192 cannot be satisfied at an early stage, can take an appropriate measure at an early stage by presenting the measure by the control target device arrangement determining unit 193, and can achieve a normal operation of the control target device 121 at an early stage.

### (Planning Method of Datagram Configuration Planning Unit 195)

Next, the datagram configuration planning unit 195 determines the datagram configuration information 196 based on the control target device arrangement information 194 determined by y the control target device arrangement determining unit 193. This processing corresponds to step S013 in FIG. 12. The datagram configuration information 196 includes information on an allocation of a logical address and a communication timing of each datagram.

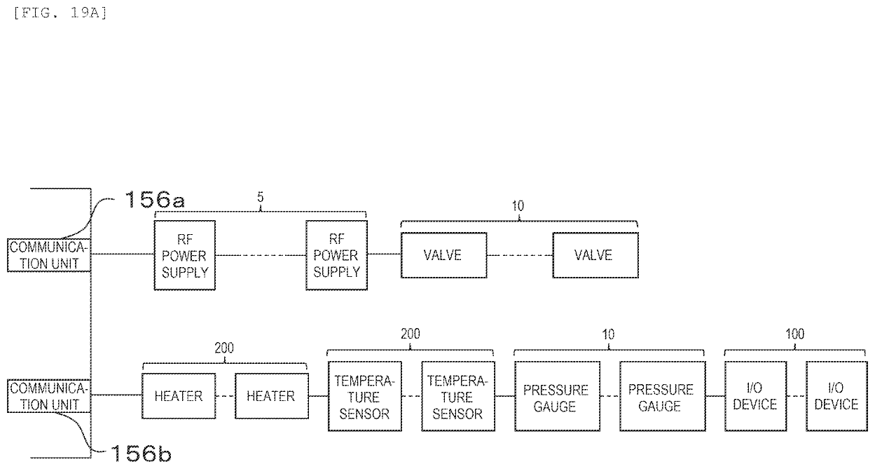

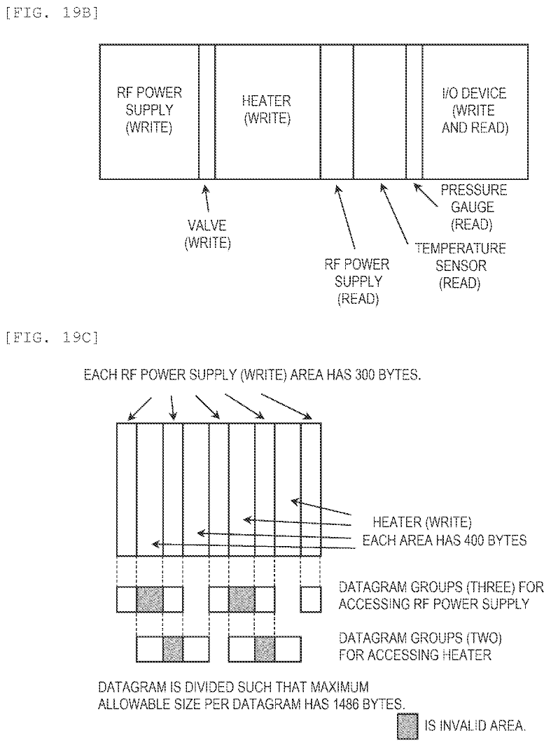

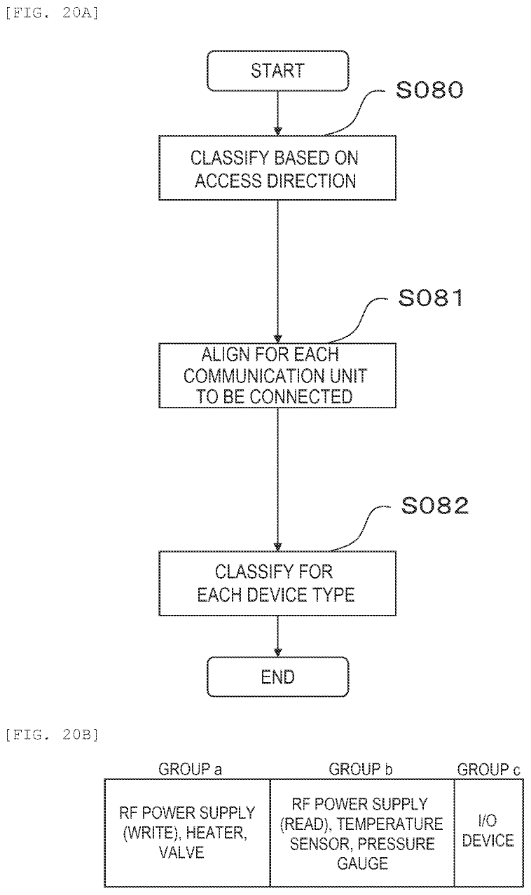

FIG. 19A is a diagram showing an example of a specific connection relationship of the control system 123 represented by the control target device arrangement information 194 shown in FIG. 8. In FIG. 19A, a group of five RF power supplies and a group of ten valves that are the control target devices 121 are connected to the communication unit 156a in the control apparatus 120 based on the control target device arrangement information 194. A group of 200 heaters, a group of 200 temperature sensors, a group of 10 pressure gauges, and a group of 100 I/O devices that are the control target devices 121 are connected to the communication unit 156b in the control apparatus 120.

FIG. 19B is a diagram showing an example of a logical address space allocated to the control target devices 121 shown in FIG. 19A. In EtherCAT, it is desirable to reduce the number of datagrams for a plurality of control target devices 121 by utilizing a logical address in order to reduce overheads of the header 176 and the WKC 178 of the datagrams.

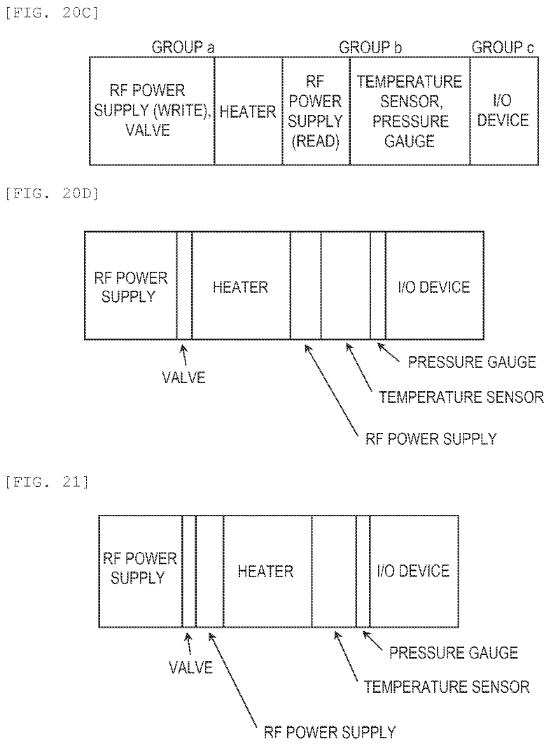

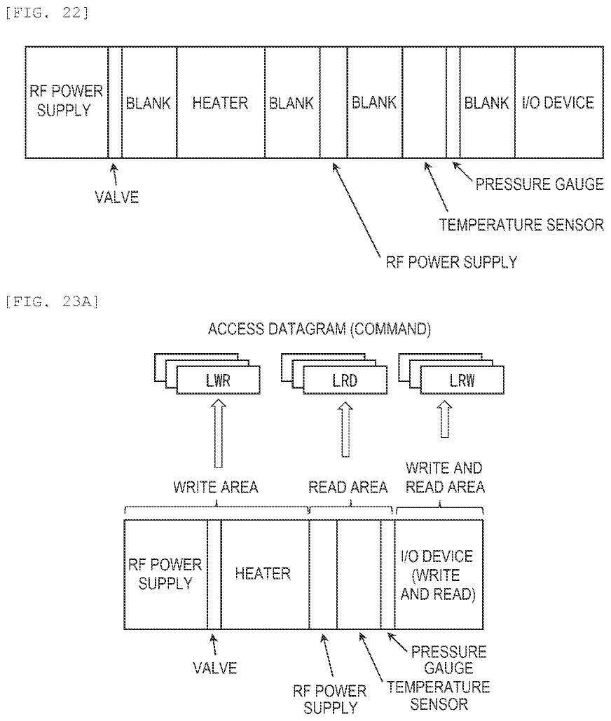

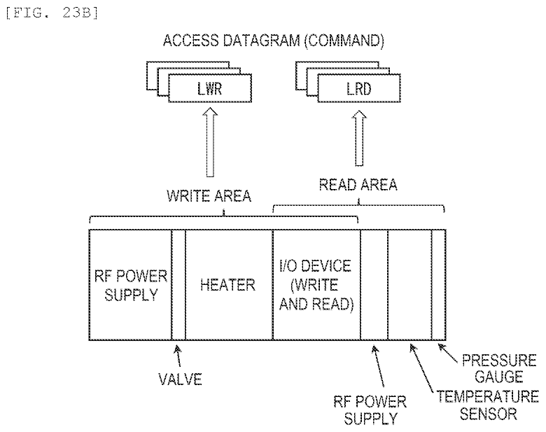

FIG. 20A is a flowchart showing an example of steps for allocating the logical address space shown in FIG. 19B. FIGS. 20B, 20C, and 20D are diagrams showing specific examples of the steps shown in FIG. 20A. In FIG. 20A, first, the datagram configuration planning unit 195 classifies a group of the control target devices 121 based on an access direction (read or write) (step S080).

Taking FIGS. 18A and 19A as an example, a write area of the RF power supplies and write areas of the valves and the heaters are classified into a group a, and a read area of the RF power supplies and read areas of the temperature sensors and the pressure gauges are classified into a group b. Common write areas and read areas for the I/O devices are classified into a group c. As an example of this stage, a logical address space as shown in FIG. 20B is determined. Either a write area or a read area may be arranged first (that is, an area with a lower logical address).

Next, the datagram configuration planning unit 195 aligns areas allocated to each of the communication units 156 to be connected in each group (step S081). In the group a, the RF power supplies and the valves are connected to the same communication unit 156a, and the heaters are connected to the communication unit 156b. Therefore, a write area of the RF power supplies, a write area of the valves, and a write area of the heaters are aligned in this order. The same applies to the group b. As long as there is a device group connected to the same communication unit 156 in the same group, an order of allocation is not particularly limited. For example, write areas of the valves and the RF power supplies may be arranged in this order. As an example of this stage, a logical address space as shown in FIG. 20C is determined.

The datagram configuration planning unit 195 classifies the logical address space for each device type (step S082). As an example of this stage, a logical address space as shown in FIG. 20D similar to that in FIG. 19B is determined.

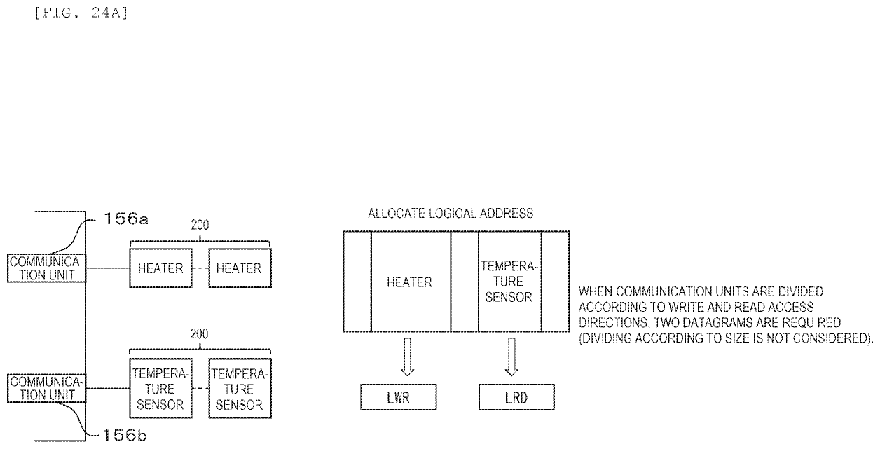

FIG. 21 is a diagram showing a modification of FIGS. 19B and 20D. Steps S080 and S081 in FIG. 20A may be reversed. An allocation of a logical address space in this case is as shown in FIG. 21. When access directions are aligned after devices are grouped for each of the communication units 156 to be connected, whether writing is arranged first or reading is arranged first in each group may be different.

Further, the classification for each device type may not be performed in step S082. An allocation order in the same group after access directions are classified and aligned for the communication units 156 to be connected may be determined based on one or more of a length of a communication cycle, a magnitude of a data size, and a magnitude of a manufacturing serial number. For example, an allocation is performed in ascending order of a communication cycle, and when the control target devices 121 have the same communication cycle, the allocation may be performed in ascending order of a manufacturing serial number.

When a logical address is allocated as shown in FIG. 19B (FIG. 21D), since data areas of the control target devices 121 connected to the same communication unit 156 in the same access direction are continuously allocated, the data areas can be accessed with a datagram according to the same logical address command. Accordingly, the number of datagrams can be reduced to a minimum necessary limit.

For example, calculation can be performed as follows for the write area of the RF power supplies and the write area of the valves that are connected to the communication unit 156a. First, a size of the write area is 300 bytes×5+2 bytes×10=1520 bytes. On the other hand, in the case of an EtherCAT frame, when the number of datagrams in one frame is 1, a maximum size of the data area 177 is calculated according to Formula (10).

$$Maximum size of data area 177 = Ethernet frame maximum length - Ethernet header length - FCS size - EtherCAT common header length - datagram header length - WKC length = 1518 bytes - 14 bytes - 4 bytes - 2 bytes - 10 bytes - 2 bytes = 1486 bytes \qquad ( 10 )$$

Therefore, in order to perform communication between the write area of the RF power supplies and the write area of the valves that are connected to the communication unit 156a, two EtherCAT frames are required. For the heaters connected to the communication unit 156b, since a size of the write area is 8 bytes×200=1600 bytes, two EtherCAT frames are required. In this case, in the entire control system 123, the number of frames is 2+2=4, and a size of the transmitted data area 177 is 1520+1600=3120 bytes.

### (Necessity of Dividing Datagram Based on Data Size)

As described above, when the datagram configuration planning unit 195 plans the datagram configuration information 196, for example, a maximum size of the data area 177 is considered as a specification and a constraint of the control network 122. Specifically, when an input and output area or a data area of the predetermined control target device 121 connected to each communication unit 156 exceeds the maximum size of the data area 177 in which communication is possible in the EtherCAT, a datagram is divided.

A size at which a datagram is divided may be the maximum size of the data area 177 or may be any size equal to or smaller than the maximum size of the data area 177. 1486 bytes in Formula (10) indicate a case where the number of datagrams is 1, and when the number of datagrams is multiple, since the header 176 and the WKC 178 of a datagram are added, a maximum allowable size of the data area 177 is different. For example, when there are two datagrams, 1486 bytes-10 bytes-2 bytes=1474 bytes are the maximum allowable size of the data area 177 of the two datagrams.

### (Consideration of Communication Cycle for Determining the Number of Datagrams)

That is, in order to determine a maximum size per datagram to be planned, it is necessary to determine the number of datagrams included in the same communication frame. In order to determine the number of datagrams, it is necessary to consider and evaluate a communication cycle of each datagram. For example, in a case where a plurality of datagrams for different control target devices 121, or a plurality of datagrams divided by a constraint of a maximum size are required to have the same communication cycle of 100 milliseconds, when a total size of data area of the datagrams exceeds the maximum allowable size of the data area 177, the datagrams cannot be transmitted.

In order to solve this problem, for example, communication timings are shifted within a range in which the datagrams do not have a requirement of a communication offset or the requirement of the communication offset is satisfied. For example, even when the datagrams have the same cycle of 100 milliseconds, it is not necessary to simultaneously transmit two datagrams by shifting communication timings (for example, ten milliseconds), and thus a total size of data area can be obtained in a manner of not exceeding the maximum allowable size of the data area 177.

In this case, a shifted time needs to be equal to or longer than a time required for transmission of a communication frame. For example, when a transmission interval between a communication frame to be transmitted first and a communication frame to be transmitted later is 100 microseconds, a data size of the communication frame to be transmitted first is 100 microseconds×100 Mbps/(8 bit/byte)=1250 bytes (including an IFG, a preamble, and an SFD). Accordingly, a size of a datagram is determined in consideration of a shifted transmission interval.

Therefore, for example, the datagram configuration planning unit 195 determines division of datagrams and a communication timing within a range in which a communication requirement is satisfied while considering a specification and a constraint (for example, the maximum allowable size of the data area 177) of the control network 122. When a datagram configuration and a communication timing that can satisfy a requirement cannot be determined by a communication cycle and a communication offset requirement, for example, an external presentation unit notifies a system operator or the like of such an abnormality. According to such a notification, the system operator can recognize that there is a problem in a communication configuration and a communication plan, can take measures such as changing a configuration of the control system 123 and changing a communication requirement, and can cope with the problem so as to reliably operate the control system 123.

### (In Case of Not Allocating Based on Access Direction and Communication Unit 156 to be Connected)

FIG. 19C is a diagram showing an example of a logical address space serving as a comparative example of FIG. 19B. It is assumed that the write area of the RF power supplies and the write area of the heaters are alternately allocated as shown in FIG. 19C without applying a flow shown in FIG. 20A. Since the write area of the valves is small, the write area of the valves is allocated to a surplus space.

In this case, as shown in FIG. 19C, the number of datagrams that access the areas is five, and there is a problem that the data area 177 that is accessed by the control target devices 121 that are not actually connected has invalid areas in the datagrams. Therefore, a total of the data areas 177 to be transmitted in the control network 122 is 1000 bytes+1000 bytes+300 bytes+1100 bytes+1100 bytes=4500 bytes, which is larger than an originally required minimum data amount of 3100 bytes (=1500 bytes+1600 bytes). This refers to that a communication bandwidth is consumed in a waste manner and utilization efficiency of a communication resource is reduced.

Although datagrams can be divided to access individual areas, an increase in the number of datagrams causes an increase in overheads of the header 176 and the WKC 178, and thus utilization efficiency of a communication resource is reduced in either case. Therefore, according to the flow shown in FIG. 20A, the number of datagrams can be reduced and utilization efficiency of a communication resource can be improved by allocating a logical address based on a communication access direction and the communication unit 156 to be connected.

### (Setting of Unallocated Area)

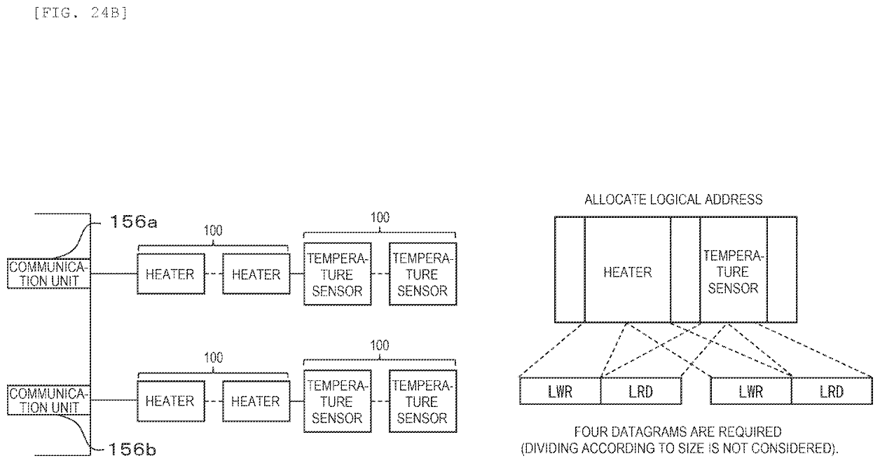

FIG. 22 is a diagram showing another modification of FIGS. 19B and 20D. When a logical address is allocated, as shown in FIG. 22, there may be a blank between areas corresponding to individual groups or collections in a group (for example, collections based on the same device type). In FIG. 22, as an example of allocating a logical address, a group of the control target devices 121 connected to the same communication unit 156 and having the same access direction is set as one group, and a blank logical address is provided immediately after the group. For example, an unallocated area is provided immediately after a series of write areas for a group of the RF power supplies and a group of the valves.

With such a configuration, when the control target device 121 is added later, a blank region can be allocated, and it is not necessary to change a setting of an existing device. Alternatively, in the case of making a change by connecting a group of heaters to the communication unit 156a, a write area of the group of heaters can be accessed by the same LWR datagram by moving the write area of the group of heaters to a blank area. However, there is a possibility that a datagram needs to be divided due to a constraint of an upper limit size per datagram. Therefore, for example, a size of an unallocated area is determined by assuming an access area of a group of control target devices 121 that are assumed to be added in the future.

(Coping with LRW Allowable Device)

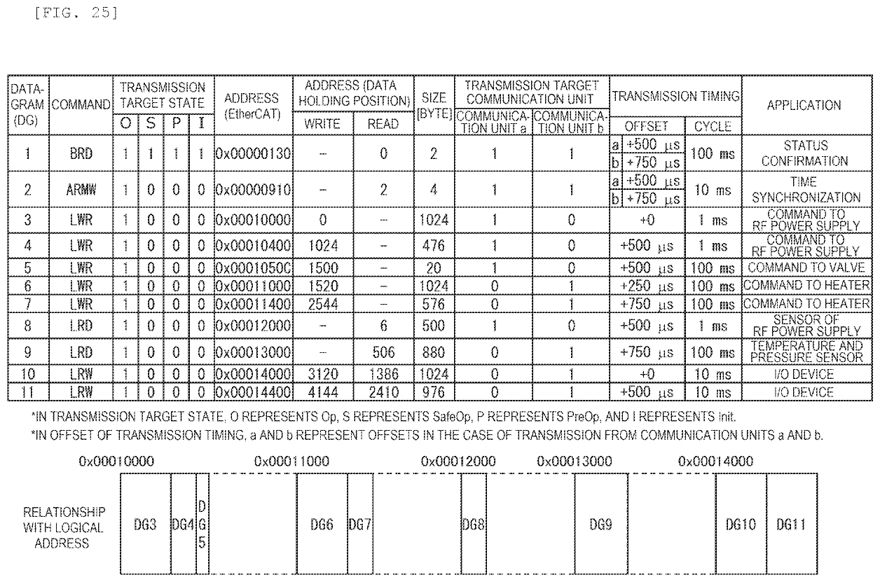

FIG. 23A is a diagram showing an example of a correspondence relationship between the logical address space shown in FIG. 19B and an access datagram (a command) in EtherCAT. FIG. 23B is a diagram showing an example of a correspondence relationship different from that shown in FIG. 23A. For the control target device 121 such as an I/O device having an area in which the control target device 121 can write data to and read data from the same area, as shown in FIG. 23A, a write and read area independent of a write area and a read area may be allocated for an LRW datagram. In this case, the write area, the read area, and the write and read area may be arranged in any order.

Alternatively, as shown in FIG. 23B, a write area and a read area may be expanded, and an input and an output of the control target device 121 capable of writing data to and reading data from the same area may be allocated to an overlapping area. In this case, when there is an overlapping area between the write area and the read area, either the write area or the read area may be arranged first (an area with a lower logical address).

In a method shown in FIG. 23A, a data size on a communication frame is a minimum necessary limit. In the case of FIG. 23A, the data size on the communication frame is 880 bytes+2000 bytes+1600 bytes=4480 bytes. However, a type of a datagram needs to include at least three types of logical address reading (LRD), logical address reading and writing (LRW), and logical address writing (LWR).

In a method shown in FIG. 23B, the types of datagrams can be limited to LRD and LWR. Accordingly, overheads of the header 176 and the WKC 178 on the datagrams can be reduced. It is possible to reduce a storage capacity for managing the datagram generation information of the datagram generation information storage unit 151. On the other hand, for the control target device 121 capable of writing data to and reading data from the same area, since repeated datagrams need to be generated, there is a concern that a data size on a communication frame may increase. In the case of FIG. 23B, the data size on the communication frame is (880 bytes+2000 bytes)+ (2000 bytes+1600 bytes)=6480 bytes.

Whether to adopt the allocation method shown in FIG. 23A or FIG. 23B is determined by comparing a magnitude of the overheads of the header 176 or the WKC 178 caused by an increase in the number of datagrams with an increase in the data size on the communication frame. However, in the method according to FIG. 23B, there is a possibility that the communication frame needs to be divided due to an increase in a size on the communication frame, and as a result, there is a concern that the number of datagrams may increase, which may balance out an effect of reducing the number of types of datagrams.

The number of datagrams is calculated according to Formula (11) in the case of FIG. 23A, and is calculated according to Formula (12) in the case of FIG. 23B. Number of Datagrams:

In the case of FIG. 23A

$$ceil ( 800 bytes / 1486 bytes ) + ceil ( 2000 bytes / 1486 bytes ) + ceil ( 1600 bytes / 1486 bytes ) = 1 + 2 + 2 = 5 \qquad ( 11 )$$

In the case of FIG. 23B

$$ceil ( 2800 bytes / 1486 bytes ) + ceil ( 3600 bytes / 1486 bytes ) + 2 + 3 = 5 \qquad ( 12 )$$

Here, “ceil ( )” represents a ceiling function. As described above, since the number of datagrams is increased due to an increase in the size on the communication frame, the number of datagrams is equal and there is no difference. On the other hand, the data size on the communication frame in FIG. 23A is smaller than that in FIG. 23B (4480 bytes<6480 bytes). Therefore, it is desirable to use the allocation method shown in FIG. 23A from the viewpoint of utilization efficiency of a communication resource (low utilization of a network bandwidth, in other words, a small total data size on the communication frame) when the method shown in FIG. 23A and the method shown in FIG. 23B are compared.

### (Change of Communication Unit 156 to be Connected)

When it is assumed that a group of the control target devices 121 is reconnected to another communication unit 156, for example, as shown in FIG. 23A, areas on continuous logical addresses are allocated to a group of control target devices 121 having the same access direction.

For example, in the allocation shown in FIG. 23A, it is assumed that a connection destination of a group of heaters is changed from the communication unit 156b to the communication unit 156a. In this case, since a write area of the group of heaters is continuous with a write area of a group of RF power supplies and a group of valves, it is only necessary to change an access size in the same LWR datagram. Accordingly, division of the LWR datagram can be avoided, and generation of a LWR datagram having an invalid area can be prevented.

In the case of FIG. 23A, the required number of datagrams is calculated according to Formula (13).

$$ceil ( ( size of write area of RF power supply + size of write area of valve + size of write area of heater ) / maximum size per datagram ) = ceil ( ( 300 bytes \times 5 + 20 bytes + 1600 bytes ) / 1486 bytes ) = 3 \qquad ( 13 )$$

If the write area of the RF power supplies is allocated to an area separated from the write area of the valves and the write area of the heaters, the required number of datagrams is calculated according to Formula (14).

$$ceil ( ( size of write area of RF power supply + size of write area of valve ) / maximum size per datagram ) ) + ceil ( size of write area of heater / maximum size per datagram ) = ceil ( ( 300 bytes \times 5 + 20 bytes ) / 1486 bytes ) + ceil ( 1600 bytes / 1486 bytes ) = 4 \qquad ( 14 )$$

Alternatively, when a datagram is accessed without being divided, it is necessary to generate an LWR datagram including the write area of the RF power supplies and an area between the write area of the valves and the write area of the heaters, and since the area between the write area of the valves and the write area of the heaters is an invalid area, utilization efficiency of a communication resource and a communication bandwidth is lowered.

(Plan of Allocating Logical Addresses Together with Control Target Device Arrangement Information 194)

Determination of the datagram configuration information 196 by the datagram configuration planning unit 195 and determination of the control target device arrangement information 194 by the control target device arrangement determining unit 193 may be performed together. For example, only a group of heaters and a group of temperature sensors may be considered as targets among the control target devices 121 shown in FIG. 18A.

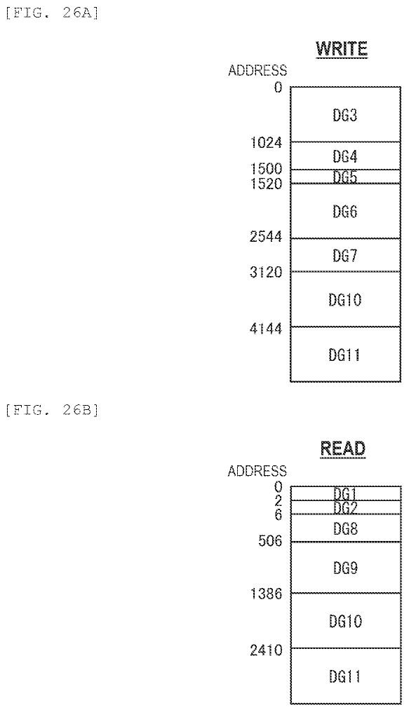

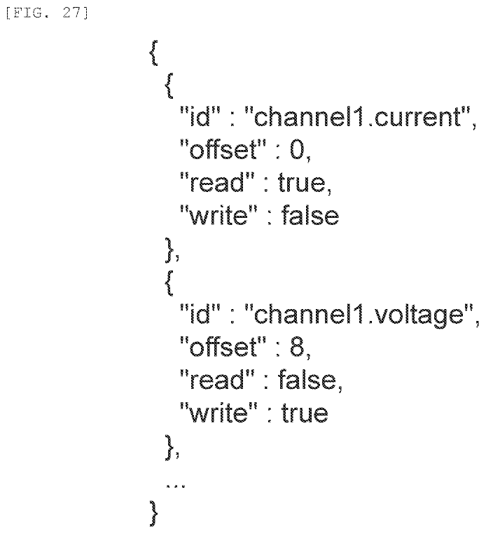

FIG. 24A is a diagram showing an example of a case where the determination of the control target device arrangement information 194 and the determination of the datagram configuration information 196 shown in FIG. 8 are performed together. FIG. 24B is a diagram showing a comparative example of FIG. 24A. From the viewpoint of efficiency of a datagram using logical address, a configuration and an allocation of a logical address shown in FIG. 24A are efficient. As shown in FIG. 24A, when a group of heaters is all connected to the communication unit 156a, a group of temperature sensors is all connected to the communication unit 156b, and the group of heaters and the group of temperature sensors having the same access direction are allocated to continuous logical addresses, the number of datagrams is calculated according to Formula (15).

$$ceil ( 1600 bytes / 1498 bytes ) + ceil ( 800 bytes / 1498 bytes ) = 2 + 1 = 3 \qquad ( 15 )$$

On the other hand, as shown in FIG. 24B, when each of the group of heaters and the group of temperature sensors is divided into halves and the heaters and temperature sensors are distributed and connected to the respective communication units 156, the number of datagrams is increased as calculated according to Formula (16), and utilization efficiency communication resource is lowered.

$$2 \times ceil ( 800 bytes / 1498 bytes ) + 2 \times ceil ( 400 bytes / 1498 bytes ) = 2 + 2 = 4 \qquad ( 16 )$$

From the viewpoint of reducing the number of datagrams while considering an access direction and a logical address, determination of the communication unit 156 to which the control target device 121 is connected (the determination of the control target device arrangement information 194) and determination of an allocation of the logical address (the determination of the datagram configuration information 196) may be performed. In this case, the control target device arrangement determining unit 193 and the datagram configuration planning unit 195 may cooperate with each other, or respective functions of the control target device arrangement determining unit 193 and the datagram configuration planning unit 195 may be expanded to independently perform the determination.

### (Start Address of Logical Address and Start Address of Each Block)

A start address of a series of areas allocated to a logical address space may be an address 0 of the logical address space or a predetermined address position. When a predetermined address position is set as the start address, a series of areas need to be arranged in the logical address space and arranged in an address range.

Utilization of the logical address space is useful in that a plurality of control target devices 121 can be collectively accessed by the same command (for example, LRD). Therefore, it is desirable that areas of a group of the control target devices 121 having the same access direction and connected to the same communication unit 156 are allocated to continuous logical addresses. Even for a group of control target devices 121 having the same access direction and connected to different communication units 156, when the group of control target devices 121 may be connected to the same communication unit 156 due to a system change, it is desirable to allocate the group of control target devices 121 to continuous logical addresses in a similar manner.

On the other hand, among the control target devices 121 having different access directions and connected to different communication units 156 or among the control target devices 121 having the same access direction and connected to different communication units 156, the control target devices 121 having a low possibility of being connected to the same communication unit 156 in the future do not need to be allocated to continuous logical addresses. Here, the start address of a group that does not need to be allocated to continuous logical addresses does not need to be continuous with an immediately preceding group, and may be spaced apart from the immediately preceding group. For example, in order to facilitate management, the control target devices 121 may be allocated to addresses the number of which is a multiple of a predetermined integer or addresses aligned to a predetermined size (for example, addresses that are aligned in units of 256 bytes and of which last 8 bits are 0).

### (Other Datagrams)

The determination of the datagram configuration information 196 performed by the datagram configuration planning unit 195 may include determining the following groups of datagrams after determining an allocation to a logical address.
Determination of a group of datagrams for allocating the determined logical address
Management including transition of ESM
Initialization of a group of datagrams (for example, setting of Sync Manager)
A group of datagrams for time synchronization (distributed clock).
Other required groups of datagrams

Since the logical address can be allocated according to a setting for a field bus memory management unit (FMMU) in an EtherCAT IC provided in the control target device 121, a group of datagrams for accessing the FMMU is required. When information for generating the required datagrams is determined (step S014 in FIG. 12), the datagram generation information required for generating the datagrams is registered in the datagram generation information storage unit 151 (step S015 in FIG. 12).

### Specific Example of Datagram Generation Information

FIG. 25 is a diagram showing a specific example of the datagram generation information stored in the datagram generation information storage unit 151 shown in FIG. 3. The datagram generation information storage unit 151 manages information required for generating a datagram for each datagram (DG) as datagram generation information. The datagram generation information is determined based on the datagram configuration information 196 as shown in FIG. 12. Examples of information included in the datagram generation information include information constituting a datagram, information for controlling transmission of a datagram, and information related to reception of a datagram.

### <Information Constituting Datagram>

Among the information included in the datagram generation information, examples of the information constituting a datagram include one or more of the command 179, the index 180, the address 181, the size 182, the MORE 185, the IRQ 186, and the WKC 178 shown in FIG. 6. Further, the datagram generation information may include position information of the data storage unit 152 in which a data area of a target datagram is arranged.

A value common to all may be set and used as a parameter that does not need to be defined for each datagram. For example, a value of the index 180 may be set, and the value may be used for all pieces of datagram generation information. Alternatively, a default value may be set for a parameter that does not need to be defined. For example, since the IRQ 186 is basically a parameter used by the control target device 121, the IRQ 186 may not be included in the datagram generation information.

An item that can be determined based on other parameters may not be included in the datagram generation information. For example, when data is arranged in the data storage unit 152 without an interval from the start, a position of a data area in the data storage unit 152 can be determined by adding a size of start datagram generation information. Therefore, the position of the data area in the data storage unit 152 may not be included in the datagram generation information. In this case, the data area may be divided into a data area for writing and a data area for reading, and the data area may be positioned by adding a size of the data area for writing and a size of the data area for reading.

For example, a command such as an LRW command for reading and writing is included in each of a write command and a read command. An ARMW command and an FRMW command may be included in each of a write command and a read command, or may be included in only one of a write command and a read command.

In the example shown in FIG. 25, a storage area of the data storage unit 152 is divided into a write area and a read area, an address (write) indicates a data storage position in the write area, and an address (read) indicates a data storage position in the read area. For the MORE 185, it is possible to determine whether datagram generation information being processed indicates a final datagram based on a transmission target state shown in FIG. 25, whether the datagram generation information is final datagram generation information, a constraint of a data size in a communication frame, and the like, and a value of the MORE 185 can be determined. Therefore, the MORE 185 may not be included in the datagram generation information.

### <Information Related to Transmission>

Among the information included in the datagram generation information, examples of the information on the transmission include a transmission target state, information on the communication unit 156 from which a packet is transmitted, that is, information on a transmission target communication unit, in other words, information on a communication port that transmits a packet, and a transmission timing.

### <Information for Controlling Transmission of Datagram (Transmission State)>

A transmission target state indicates that the control apparatus 120 manages a transition of a state in a unique state machine or an ESM, defines a state serving as a transmission target in each piece of datagram generation information, and processes the state as a transmission target when states match. For example, according to the ESM, a transmission state of datagram generation information is defined by a bitmap of Init, PreOp, SafeOp, and Op. In this case, a bit representing a Boot state may be added.

In FIG. 25, since all bits of a BRD command of a datagram DG1 are 1, for example, the datagram DG1 is processed and a defined datagram is transmitted when a state of the control apparatus 120 is any state. For example, the state of the control apparatus 120 is set by software based on the state of the control apparatus 120. For example, the datagram is transmitted when a state set in the control apparatus 120 matches a state set as 1 in the datagram generation information.

### <Information for Controlling Transmission of Datagram (Information of Transmission Target Communication Unit)>

The communication unit 156 from which a datagram is transmitted is defined as the communication unit 156 to which the datagram is to be transferred, that is, a transmission target communication unit, in the datagram generation information. For example, the transmission target communication unit is defined using a bitmap indicating the specific communication unit 156 for each bit.

In FIG. 25, a bit [1] indicates the communication unit 156a, a bit [0] indicates the communication unit 156b, and it is indicated that a datagram is transferred to the corresponding communication unit 156 when a value of a bit is “1”. For example, since a value of a bit [1] is “1” and a value of a bit [0] is “0” in an LWR command of a datagram DG3, it is indicated that a datagram is transferred only to the communication unit 156a. Instead of a bitmap, an identifier of the individual communication unit 156 may be included in the datagram generation information.

### <Information for Controlling Transmission of Datagram (Transmission Timing)>

A transmission timing indicates a timing at which a target datagram defined by the datagram generation information is transmitted. For example, when all datagrams have the same start time, a transmission cycle is defined. Alternatively, when start times are different, for example, an offset time from a common timing and a cycle may be defined. In the case of other transmission patterns, for example, a transmission pattern is defined as information indicating a timing. For example, a transmission pattern may be defined as a list of offset times from a start time or information indicating a transmission timing within a predetermined time slot.

A timing specified here may be a timing at which generation of a datagram is started instead of transmission of a datagram, and transmission timings of datagrams may be specified separately and independently by the same method. In this case, a transmission timing may be specified for each communication unit 156. A transmission timing or a generation timing of a datagram may be specified for each slave serving as a transmission target instead of for each datagram. In the case of a datagram accessed in units of slave such as an APRD command, for example, the datagram is transmitted to the slave at a defined transmission timing.

Alternatively, in the case of a datagram that can target a plurality of slaves such as an LWR command, the datagram may be transmitted to all target slaves at a specified timing, or the datagram may be transmitted to one or more of the target slaves at a specified timing. In such a case, the datagram generation information may include an identifier of a slave which is a communication target for each datagram. In the case of a command for a logical address, one datagram may have a plurality of identifiers of slaves.

### <Information Related to Reception of Datagram>

Examples of the information related to reception of a datagram include a data position in the data storage unit 152 that stores a data area of a received datagram. Alternatively, examples of the information related to reception of a datagram includes an expected value of the WKC 178 or the IRQ 186 at the time of reception. Whether desired communication is performed can be determined by comparing a received value with the expected value. When the desired communication is not performed, retransmission may be performed, or a system operator or the like may be presented with or notified of an abnormality. Accordingly, the system operator can grasp occurrence of an abnormality and take measures to contribute to a stable operation of the control system 123.

### <Change of Datagram Generation Information>

When there is no change in an operation condition of the control system 123, information determined in advance may be used as the datagram generation information, and when there is a change, the operation condition may be changed dynamically when the system is operating. For example, when processing of the control system 123 proceeds and the control recipe 190 or a control step is changed, the datagram generation information may also be changed.

Therefore, the datagram generation information storage unit 151 may hold a plurality of sets of datagram generation information. Alternatively, when the control target device 121 connected to the predetermined communication unit 156 is disabled due to a reason such as maintenance of the control system 123 and cleaning of a predetermined device, datagram generation based on the datagram generation information related to the communication unit 156 and the control target device 121 is disabled.

In the example shown in FIG. 25, eleven datagrams DG1 to DG11 are defined. For example, a datagram DG1 is a datagram for reading states of all of the control target devices 121 constituting the control system 123, and is used for determining a state in an ESM. A datagram DG2 is a datagram for time synchronization, and distributes time information of the control target device 121 serving as a time reference to the other control target devices 121.

Datagrams DG3 and DG4 are datagrams for writing data to a write area of an RF power supply. Since a size of the write area is larger than a maximum size of the data area 177, a datagram is divided into two datagrams. Although a division size is 1024 bytes, the division size may be 1486 bytes of the maximum size of the data area 177. A datagram can be divided into any size as along as the number of datagrams is not excessively increased.

A datagram DG5 is a datagram for writing a command value to a valve. Since a communication cycle is different from that of writing data to the write area of the RF power supply, another datagram is used. However, since the write area of the valve is allocated to a logical address space that is continuous with the write area of the RF power supply, the datagram DG5 may be combined with the datagram (the datagram DG4) for writing data to the write area of the RF power supply for the purpose of reducing the number of datagrams.

In this case, there is no datagram generation information of the datagram DG5, and a size of the datagram DG4 is 496 bytes (476 bytes+20 bytes). Since the communication cycle which is originally a communication cycle of 100 milliseconds is set to be one millisecond, utilization efficiency of a communication resource is lowered, but there is no problem in this case since there are sufficient communication resources (a proportion of communication time).

The datagrams DG6 and DG7 are datagrams for writing a command value to a heater. Since the heater is connected to the communication unit 156b, a value of a bit [0] (the communication unit 156b) in information indicating the communication unit 156 which is a transmission target is “1”. Since a size of the write area is larger than a maximum size of the data area 177, a datagram is divided into two datagrams. A datagram DG8 is a datagram for reading data from a read area of the RF power supply.

A datagram DG9 is a datagram for reading measurement values of a temperature sensor and a pressure gauge. Since both the temperature sensor and the pressure gauge have the same communication cycle and are allocated to continuous logical addresses, an access with the same datagram is efficient. Datagrams DG10 and DG11 are datagrams for reading data from and writing data to an I/O device.

### (Determination Example of Transmission Timing)

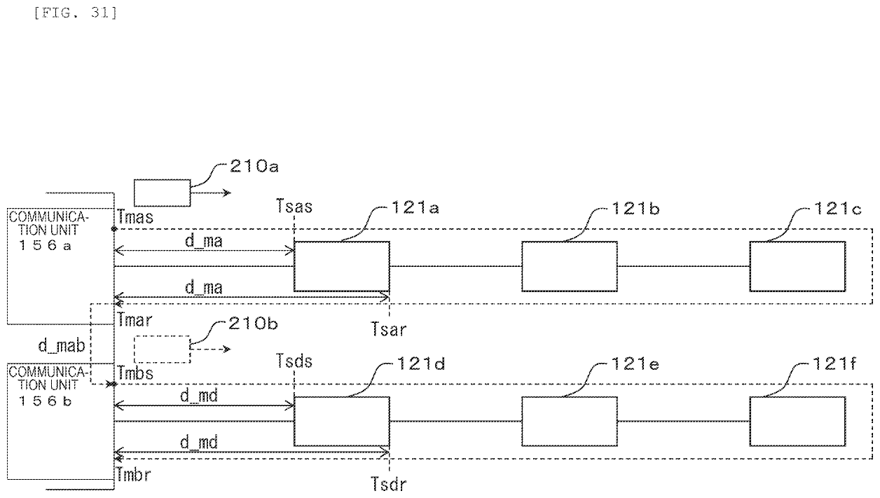

FIG. 28 is a flowchart showing an example of steps for determining a time offset of the transmission timings shown in FIG. 25. The steps shown in FIG. 28 are executed for each communication unit 156. As a communication requirement, it is assumed that there is no time offset of transmission timings and a communication cycle is given as shown in FIG. 25. In FIG. 28, first, a greatest common divisor of communication cycles of all datagrams serving as transmission targets is calculated and set as a basic communication cycle (step S090). In the example shown in FIG. 25, the basic communication cycle is one millisecond in the communication unit 156a and ten milliseconds in the communication unit 156b.

Next, a group for grouping datagrams is determined (step S091). Even when communication cycles are different, if there is no time offset of transmission timings, transmission timings of a plurality of datagrams may overlap at a certain timing. For example, the datagram DG6 and the datagram DG10 have different communication cycles of 100 milliseconds and ten milliseconds, but the communication cycles overlap each other every 100 milliseconds and the datagram DG6 and the datagram DG 10 are transmitted at the same time. Therefore, a total size of the data area 177 is 1024 bytes+1024 bytes=2048 bytes, which exceeds a maximum size of an Ethernet frame.

In order to avoid such a situation, a combination of datagrams to be grouped in the same communication frame is determined even when it is not in every communication cycle. In this case, a total of sizes in one group (all datagrams or the data area 177) is selected to be equal to or smaller than the maximum size of the Ethernet frame or a maximum allowable size of the data area 177 in an EtherCAT frame.

A method for selecting a datagram may be determined by applying a search method or an optimization method based on an attribute value of the datagram. Alternatively, a group of datagrams may be aligned in ascending order or descending order based on the attribute value, and may be sequentially selected within a range in which a data size condition is satisfied. Specifically, for example, first, a group of datagrams is aligned in descending order based on a size, and second (in the case of the same size), the datagrams are aligned in ascending order based on a communication cycle, and are sequentially selected.

Taking FIG. 25 as an example, the datagram DG3 having a maximum size (1024 bytes) is selected from datagrams to be transmitted to the communication unit 156a. Among the datagrams to be transmitted to the communication unit 156b, the datagram DG10 having a short communication cycle (ten milliseconds) is selected from the datagrams DG6 and DG10 having a maximum size (1024 bytes).

On the other hand, when the datagram DG6 (a communication cycle is 100 milliseconds) and the datagram DG10 are included in the same group, a total size of the data area 177 is 2048 bytes, which exceeds 1474 bytes of a maximum allowable size, and thus the datagram DG6 and the datagram DG10 are not included in the same group. Therefore, the datagram DG10 is set as a first group in the datagrams to be transmitted to the communication unit 156b.

In this case, since there is a margin up to the maximum allowable size, the remaining aligned datagrams may be evaluated in order and grouped into a group (for example, the datagram DG5 having a size of 20 bytes may be included in the same group), or grouping may be stopped when a condition is violated. Here, it is assumed that grouping is stopped when a condition is violated.

Thereafter, grouping is performed as follows when the same steps are repeated.
Datagram to be transmitted to communication unit 156a
First group: datagram DG3 (1024 bytes)
Second group: datagrams DG8, DG4, DG5, DG2, DG1 (500 bytes+476 bytes+20 bytes+4 bytes+2 bytes=1002 bytes)
Datagram to be transmitted to communication unit 156b
First group: datagram DG10 (1024 bytes)
Second group: datagram DG6 (1024 bytes)
Third group: datagram DG11 (976 bytes)
Fourth group: datagrams DG9, DG7, DG2, DG1 (880 bytes+576 bytes+4 bytes+2 bytes=1462 bytes)

Next, a basic communication cycle is divided to determine a minimum unit of a transmission interval based on the determined number of groups (step S092). Since the datagrams to be transmitted to the communication unit 156a are divided into two groups, one millisecond calculated in step S090 is divided by two, and a transmission interval is 500 microseconds. Since the datagrams to be transmitted to the communication unit 156b are divided into four groups, ten milliseconds calculated in step S090 is divided by four, and a transmission interval is 2.5 milliseconds.

In a case where there is a remainder when the basic communication cycle is divided according to the number of groups, a smallest integer that is larger than the number of groups and does not cause a remainder may be used in consideration of facilitating control and management. Although the transmission interval is calculated by dividing the basic communication cycle by the number of groups, the transmission interval may be any value shorter than the basic communication cycle. For example, the transmission interval may be calculated by calculating a power of an appropriate integer (for example, 5 or 10) that is larger than the number of groups and does not cause a remainder and dividing the basic communication cycle. In this case, the transmission interval needs to be a length of a time during which a communication frame including grouped datagrams can be transmitted.

Next, it is determined whether datagrams can be transmitted within the transmission interval in all groups of datagrams using the transmission interval calculated in step S092 (step S093). Since the group of datagrams to be transmitted to the communication unit 156a has a transmission interval of 500 microseconds, a transmittable data size per transmission interval is “500 microseconds×100 Mbps/(8 bits/byte)=6250 bytes”. Since this value is larger than a maximum length of an Ethernet frame, datagrams of any group can be transmitted.

Similarly, since a group of datagrams to be transmitted to the communication unit 156b has transmission interval of 2.5 milliseconds, a transmittable data size per transmission interval is “2.5 milliseconds×100 Mbps/(8 bits/byte)=31250 bytes”. Since this value is larger than a maximum length of an Ethernet frame, datagrams of any group can be transmitted.

When a total size of the data area 177 of the groups determined in step S091 is a size at which a datagram cannot be transmitted within one transmission interval, it may be determined that a datagram cannot be transmitted within the transmission interval in all groups of datagrams (N in step S093), a size condition may be updated to a transmittable data size per transmission interval, and the processing may return to step S091. Alternatively, when there is a surplus transmission interval, a plurality of transmission intervals may be allocated. In this case, it is determined that datagrams can be transmitted within the transmission interval in all groups of datagrams (Y in step S093).

From the above steps, a time offset of transmission timings in each group (a time offset within a basic communication cycle of one millisecond) is determined as follows as shown in FIG. 25 (step S094).
Datagram to be transmitted to communication unit 156a
   First group: +0.
   Second group: +500 microseconds
Datagram to be transmitted to communication unit 156b
   First group: +0.
   Second group: +2.5 milliseconds
   Third group: +5 milliseconds
   Fourth group: +7.5 milliseconds

The time offset of transmission timings may be manually determined by a system operator or the like, or a group may be determined by a system operator or the like. Alternatively, a system operator may determine a transmission interval. Alternatively, a system operator or the like may make a change based on the transmission timing determined in the steps shown in FIG. 28.

### (Operation of Data Access Management Unit 160)

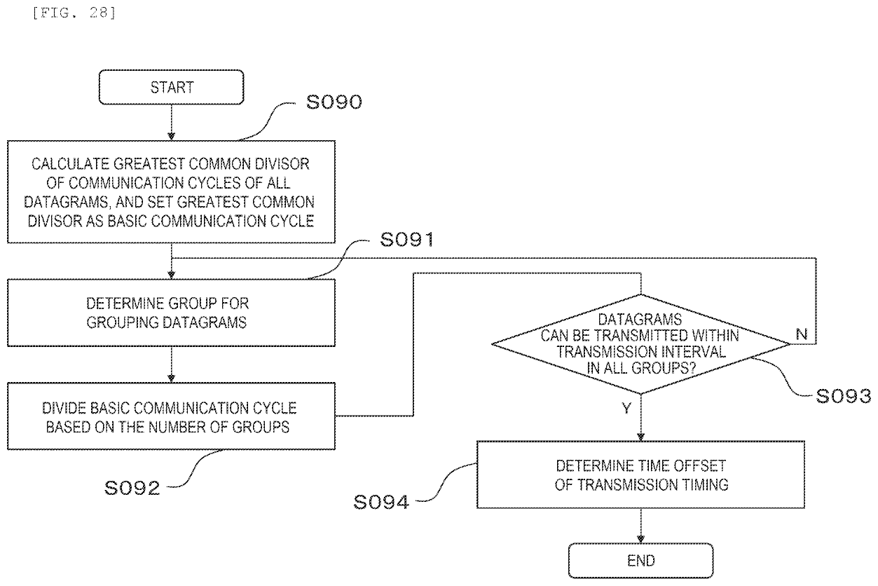

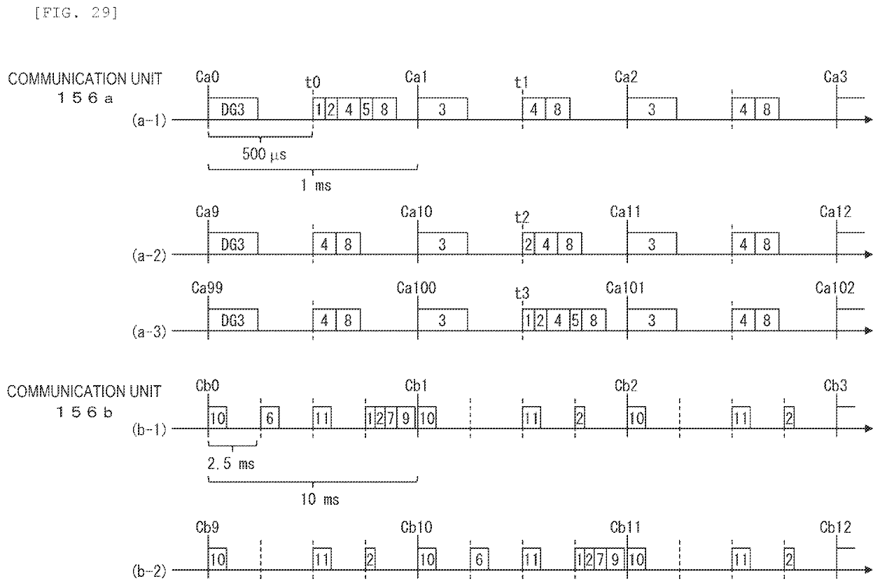

On the other hand, data access information is determined based on the datagram configuration information 196 in software development (step S016 shown in FIG. 12). Here, it is assumed that the data storage unit 152 is divided for writing and reading, and data is arranged in order of the datagram generation information from the start of the data storage unit 152. FIGS. 26A and 26B are diagrams showing examples of data storage positions in the data storage unit 152 shown in FIGS. 3 and 25.

For example, as shown in FIG. 26A, it is assumed that a write area of an RF power supply, that is, the datagrams DG3 and DG4 are allocated to an area corresponding to 1500 bytes from an offset 0 byte. Based on the data storage position, the data access management unit 160 provides software with an application programming interface (API) for accessing data constituting the datagram as data access information.

An application program accesses data of the datagram via the API, thereby instructing an output to an actuator of the control target device 121 or acquiring sensor information. Examples of the API for software include a programming function, a structure, a class definition in an object-oriented language, an object, and an instance. Examples of the API for software include a device name, an access direction, data, and a size. In addition, definition information of an input and output device or a component constituting the control target device 121 may be provided, the input and output device or the component may be accessed through the API.

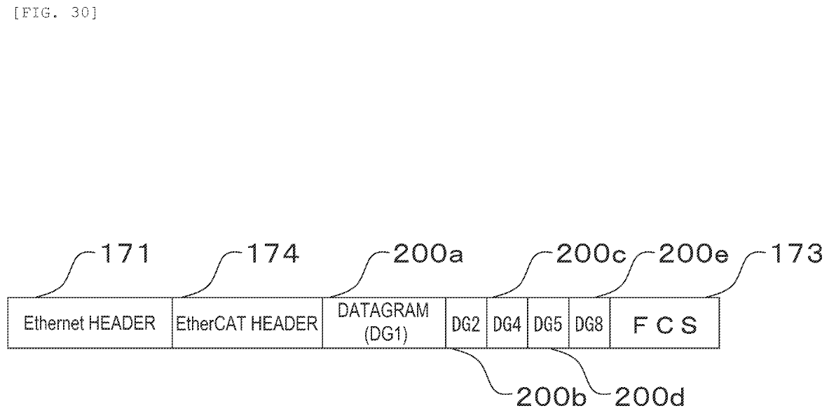

FIG. 27 is a diagram showing an example of API definition information provided by the data access management unit 160. Although components are shown in a Javascript object notation (JSON) format in the example shown in FIG. 27, the format is not limited as long as the components can be electronically processed, such as an extensible markup language (XML) format. An expression format is not limited to those in the example shown in FIG. 27.

Although an access type is set in which reading and writing are respectively specified by truth values for keys “read” and “write” in the example shown in FIG. 27, for example, reading and writing may be indicated by values such as “read”, “write”, and “read/write” for a key “access”. An identifier (“id”) may be specified in a hierarchical manner. Although “channell. current” (refers to specifying of a current value) is set for a key “id” in the example of FIG. 27, for example, a plurality of hierarchies such as a value “1” for a key “channel” and “current” for a key “type” may be set.

An example of an API using the above configuration will be described. For example, the following example is for specifying a parameter in an object-oriented language.

### Example 1 of setting value (write)

rf power [0]=rf power (“conf. json”);
rf power [0]. channel [0]. voltage=10;

Here, conf .json is, for example, definition information shown in FIG. 27. Using the definition information shown in FIG. 27, a class or an instance is defined such that a software object representing an RF power supply internally has an array of channel objects and each channel object has an element representing a voltage value.

For example, when a voltage value permits only writing, an error or exception may occur in a subsequent program.

// An error or an exception occurs due to a trial of reading.

$$a = rf\_power [ 0 ] . channel [ 0 ] . voltage$$

The following is an example of a setting according to a function.

### //Example 2 of setting value

set parameter (RF POWER CHANNEL 1 VOLTAGE, 10);

In this example, a header file or the like in which a constant RF POWER CHANNEL 1 VOLTAGE is defined is generated using the definition information shown in FIG. 27, and when a set parameter ( ) function is executed by specifying the constant, for example, middleware or a software library is generated so as to write a value of 10, which is an argument of the set parameter ( ) function, to a corresponding position of the data storage unit 152.

The following is an example of reading.

### //Example 1 of setting value (read)

long current;

$$current = rf\_power [ 0 ] . channel [ 0 ] . current ;$$

### //Example 2 of setting value (read)

current=get parameter (RF POWER CHANNEL 1 CURRENT);

Here, when a size of an input and output device or a component is not a standard type such as integer (int), float, double, or long, for example, an array, a pointer, or the like is an argument or a return value.

In a programming development support using the above data access information, an access to the data storage unit 152 by an object, an instance operation, middleware, or a software library via a predetermined API is implemented by registering data access information in the data access management unit 160 (step S017 in FIG. 12). The object, the instance, the middleware, and the software library associate, based on the data access information, specification of the control target device 121, an input and output device, and a component on an application with a data storage position in the data storage unit 152.

A data structure representing a predetermined area of the control target device 121 or the data storage unit 152 according to the data access information may be associated with a data structure which is an international standard or an industry standard. For example, there is an object defined by a CAN application protocol over EtherCAT (CoE) or Servo drive profile over EtherCAT (SoE), which is an upper application protocol of EtherCAT.

With such a configuration, an application developer does not need to be aware of details of the datagram configuration information 196 and the datagram generation information and details of a data storage position in the data storage unit 152, and can develop an application for the control target device 121 in the control system 123. Therefore, advantages such as a reduction in the number of development steps, a reduction in the number of setting steps, and easy development can be obtained.

Furthermore, even when a configuration of the control system 123 is changed or the datagram configuration information 196 and the datagram generation information are changed, the application developer can easily and quickly develop a compatible application by automatic generation and automatic planning performed by the data access management unit 160 and the datagram configuration planning unit 195. When only a configuration of connection is changed, it is not necessary to change the application, and it is possible to quickly operate the control system 123.

### Specific Example of Transmission Processing

Next, specific examples of datagram generation processing and communication frame transmission processing executed k by the datagram generating unit 150, the communication frame generating unit 153, and the transmission unit 154 will be described. This corresponds to the operation shown in FIG. 15.

The datagram generating unit 150 waits for an execution start timing of datagram generation according to step S040 shown in FIG. 15. Here, it is assumed that a communication cycle specified by each datagram shown in FIG. 25 and a time offset of transmission timings are applied. However, the processing may be started upon completion of an access of an application to the data storage unit 152 via the data access management unit 160, or any transmission pattern may be specified. Alternatively, a start timing of the processing may be specified at a time interval instead of a constant cycle.

FIG. 29 is a diagram showing datagrams generated by the datagram generating unit 150 based on the datagram generation information shown in FIG. 25 and timings of the datagrams. In FIG. 29, timings Ca0, Cal, Cb0, and Cb1 indicate the number of a basic communication cycle, and the reference numerals a and b indicate identifiers of the communication unit 156, here, the transmission unit 154. Ca0 and Cb0 are a first basic communication cycle, and Ca100 and Cb100 are a 101st basic communication cycle (a period from 100 milliseconds to 101 milliseconds when a basic communication cycle is one millisecond).

(a-1), (a-2) and (a-3) of FIG. 29 show groups of datagrams to be transmitted to the transmission unit 154a, and (b-1), (b-2) of FIG. 29 show groups of datagrams to be transmitted to the transmission unit 154b. For example, when it is a start time (Ca0, Cb0) set by a system operator or the like, the datagram generating unit 150 sequentially extracts datagram generation information from the datagram generation information storage unit 151 (corresponding to S041 in FIG. 15).

Specifically, the datagram generating unit 150 first extracts information on the datagram DG1. Since a time offset of transmission timings is 500 microseconds, it is determined that the datagram DG1 is not a datagram of a transmission target, and information on the subsequent datagram DG2 is extracted. Similarly, since a time offset of transmission timings is 500 microseconds in the information on the datagram DG2, it is determined that the datagram DG2 is not a datagram of a transmission target, and information on the subsequent datagram DG3 is extracted.

Since a time offset of transmission timings is 0 in the information on the datagram DG3, the datagram DG3 is a transmission target from the viewpoint of transmission timing. Here, it is assumed that the control apparatus 120 completes an initialization setting and the like, and thereby bringing a state to Op. Since Op is 1 (true of a truth value), the datagram DG3 is a transmission target from the viewpoint of state (corresponding to Y in step S042 in FIG. 15). Therefore, the datagram DG3 is a transmission target in the viewpoint of transmission timing and state, and thus the datagram generating unit 150 starts to generate the datagram DG3.

The datagram generating unit 150 extracts data from the data storage unit 152 based on the datagram generation information shown in FIG. 25 in which an address of a write buffer is 0 and a size is 1024 bytes as the address information stored in the data storage unit 152 (corresponding to step S043 in FIG. 15). The datagram generating unit 150 generates a datagram together with required header information (the command 179, the address 181) in the datagram generation information (corresponding to step S044 in FIG. 15).

In this case, since the command 179 of the datagram DG3 is LWR and is a write command, the datagram generating unit 150 extracts data from the data storage unit 152. Since the communication unit 156 serving as a transfer destination of the datagram DG3 is the communication unit 156a, the datagram generating unit 150 transfers the datagram DG3 to the communication frame generating unit 153a connected to the communication unit 156a (corresponding to step S045 in FIG. 15).

The datagram generating unit 150 extracts datagram generation information of the subsequent datagram DG4 and continues the same processing. As a result, a datagram to be generated subsequently is the datagram DG10. The datagram generating unit 150 extracts data from the data storage unit 152 based on the datagram generation information in which an address of a write buffer is 3120 and a size is 1024 bytes as the address information stored in the data storage unit 152 (corresponding to step S043 in FIG. 15). The datagram generating unit 150 generates a datagram together with required header information (the command 179, the address 181) in the datagram generation information (corresponding to step S044 in FIG. 15).

In this case, since the command 179 of the datagram DG 10 is LRW and is a write command, data is extracted from the data storage unit 152. Since the communication unit 156 serving as a transfer destination of the datagram DG10 is the communication unit 156b, the datagram generating unit 150 transfers the datagram DG10 to the communication frame generating unit 153b connected to the communication unit 156b (corresponding to step S045 in FIG. 15).

Since a time offset of transmission timings is 500 microseconds, the datagram DG11 is not a datagram of a transmission target. Since processing of all pieces of datagram generation information is ended, datagram generation processing of the datagram generating unit 150 in the cycles Cal and Cb0 shown in FIG. 29 is ended (corresponding to Y in step S046 shown in FIG. 15). Since the datagrams DG3 and DG10 are generated as final datagrams of the communication units 156, the datagram generating unit 150 may set the MORE 185 to be 0 (there is no subsequent datagram).

The communication frame generating unit 153 of each communication unit 156 connects datagrams transferred from the datagram generating unit 150, adds the Ethernet header 171, the EtherCAT header 174, and the FCS 173 to generate a communication frame (corresponding to step S047 in FIG. 15), and transfers the communication frame to the transmission unit 154. The transmission unit 154 transmits the communication frame at a transmission timing (corresponding to step 049 in FIG. 15).

A timing when the transmission unit 154 transmits the communication frame may be a time point when the communication frame is transferred from the communication frame generating unit 153. Alternatively, the timing may be a transmission timing specified in FIG. 25. In this case, for example, a predetermined time interval is provided in response to the start of the datagram generating processing executed by the datagram generating unit 150.

Alternatively, the datagram generation processing of the datagram generating unit 150 may be started at a time obtained by subtracting a predetermined time from the timing when the transmission unit 154 transmits the communication frame. In this case, for example, a time interval between the timing when the transmission unit 154 transmits the communication frame and a start timing of the datagram generation processing of the datagram generating unit 150 is set to be a datagram generation processing time (a margin may be added) of the datagram generating unit 150.

When the datagram generating unit 150 is implemented by an application on a real-time OS, or a dedicated IC such as a CPLD, an FPGA, or an ASIC, determinism of the datagram generation processing time is high, and thus a margin of the time interval between the timing when the transmission unit 154 transmits the communication frame and a start timing of the datagram generation processing of the datagram generating unit 150 can be reduced. In this manner, since a calculation time of a control application of the calculation unit 159 can be ensured to be long, more pieces of advanced and complicated processing can be executed, or a control communication cycle can be shortened, and thus control performance of the control system 123 can be improved.

The timing of transmitting the communication frame may be independently set for each transmission unit 154. For example, as described in FIG. 28, since a time offset of transmission timings is set to be 500 microseconds in the transmission unit 154a and 2.5 milliseconds in the transmission unit 154b here, the time measurement unit 161 notifies the datagram generating unit 150 of a timing each time 500 microseconds and 2.5 milliseconds elapse (corresponding to step S040 in FIG. 15). In this case, as described above, the time measurement unit 161 may notify the datagram generating unit 150 of the start of datagram generation at a time obtained by subtracting a predetermined time from a transmission timing of the communication frame generating unit 153 and the transmission unit 154.

In the example shown in FIG. 29, the datagram generating unit 150 starts processing at to ((a-1) of FIG. 29) after 500 microseconds elapse from the cycle Ca0. The datagram generating unit 150 processes the datagram generation information by the same steps as an operation in the cycle Ca0, and generates the datagrams DG1, DG2, DG4, DG5, and DG8. A status at this time is Op. When the datagram generating unit 150 generates the datagram DG8 including a read command (an LRD command), the datagram generating unit 150 ensures, in the datagram DG8, the empty data area 177 having the same size (here, 500 bytes) as that included in the datagram generation information.

In this manner, the datagram generating unit 150 generates datagrams at a timing of the time offset of 500 microseconds in the cycle Cal and at timings of 2.5 milliseconds, 5 milliseconds, and 7.5 milliseconds in the cycle Cb0 ((a-1) and (b-1) of FIG. 29). In the cycle Cal, since a second basic communication cycle (one millisecond to two milliseconds) is entered, the datagrams DG1, DG2, and DG5 whose communication cycles are ten milliseconds and 100 milliseconds are excluded from datagrams of a transmission target (t1 in (a-1) of FIG. 29).

However, the datagram DG2 having a communication cycle of ten milliseconds is generated again in the cycle Ca10 after ten milliseconds (t2 in (a-2) of FIG. 29), and the datagrams DG1 and DG5 having a communication cycle of 100 milliseconds are generated again in the cycle Ca100 after 100 milliseconds (t3 in (a-3) of FIG. 29). Such an operation also applies to the transmission unit 154b.

### Specific Example of Reception Processing

Next, specific examples of reception processing of receiving a communication frame and disassembling the communication frame into datagrams by the datagram analyzing unit 158, the communication frame disassembling unit 157, and the receiving unit 155 shown in FIG. 3 will be described. This corresponds to an operation shown in FIG. 17. First, on the premise that the control target device 121 received a datagram including a read command (an LRD command), the control target device 121 substantially returns data to the control apparatus 120 by writing data in an empty data area ensured in advance in the datagram.

The receiving unit 155 waits for reception of the communication frame according to step S060 shown in FIG. 17. This is executed for each communication unit 156. When the receiving unit 155 receives the communication frame, the communication frame disassembling unit 157 disassembles the received communication frame into datagrams. At this time, the communication frame disassembling unit 157 confirms an EtherType in the Ethernet header 171 and confirms that the communication frame is an EtherCAT frame.

Next, the communication frame disassembling unit 157 starts to extract the datagram 175 from an area of the first datagram 175 (a packet data area), and sequentially extracts the datagram 175 based on the size 182 in the header 176 (corresponding to step S061 in FIG. 17). The communication frame disassembling unit 157 transfers the extracted datagram 175 to the datagram analyzing unit 158 (corresponding to step S062 in FIG. 17). At this time, the communication frame disassembling unit 157 may transfer accompanying information together with the received datagram to the datagram analyzing unit 158. Examples of such information include an identifier of the communication unit 156 that received the datagram and a reception time.

The datagram analyzing unit 158 extracts datagram generation information stored in the datagram generation information storage unit 151 and compares the datagram generation information with the datagram transferred from the communication frame disassembling unit 157.

Specifically, a header parameter and a datagram size of the received datagram, and the identifier of the communication unit 156 that received the datagram are compared with the datagram generation information.

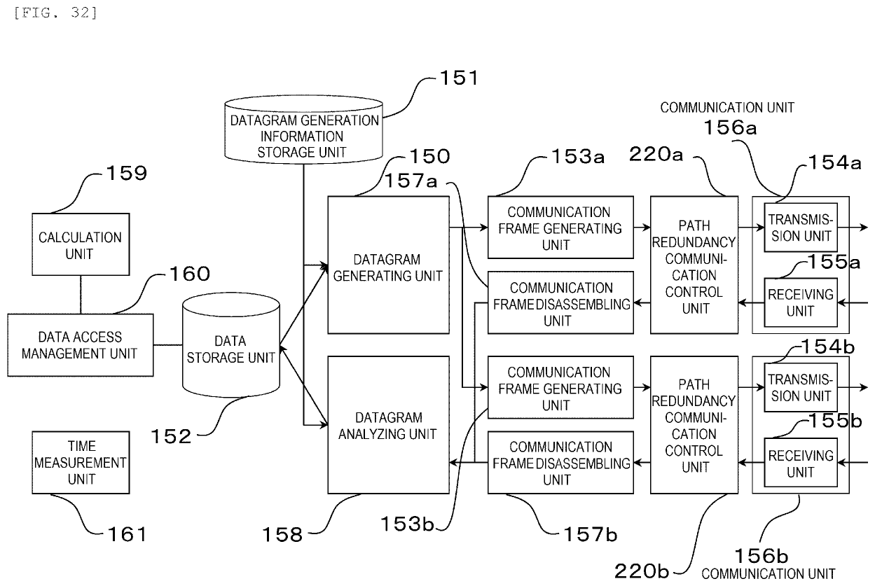

FIG. 30 is a diagram showing a configuration example of a communication frame received by a receiving unit shown in FIG. 3. Here, it is assumed that the receiving unit 155a receives the communication frame shown in FIG. 30. The communication frame disassembling unit 157a first extracts a datagram 200a from the received communication frame and transfers the datagram 200a to the datagram analyzing unit 158.

The datagram analyzing unit 158 sequentially extracts datagram generation information stored in the datagram generation information storage unit 1 151, compares the command 179, the address 181, and the size 182 extracted from the datagram 200a, and uses matched datagram generation information in reception processing. In the comparison of the datagram generation information, the index 180, the MORE 185, and the IRQ 186 may be stored in the datagram generation information and compared with information on the received datagram 200a.

Alternatively, an expected value of the WKC 178 may be stored in the datagram generation information and compared with information on the received datagram 200a. Alternatively, the comparison of any one of the command 179, the address 181, and the size 182 may be omitted. Alternatively, an identifier of the communication unit 156 that received the datagram, specifically, an identifier of the receiving unit 155 may be compared with an identifier of the communication unit 156 in the datagram generation information.

Alternatively, consistency between a reception time of the datagram 200a and a transmission timing defined in the datagram generation information may be evaluated. Specifically, for example, a delay time (which may include a margin) from transmission to reception is stored in the datagram generation information, and when a time from a transmission time to a reception time of a communication frame including the datagram falls within the delay time in the datagram generation information, it is determined that the received datagram matches the datagram generation information. When a real-time communication method is used for the control network 122, since time determinism of the communication delay is high, the delay time can be defined with high accuracy and a low margin.

The delay time may be compared for a single datagram or for a set of datagrams. For example, at to in (a-1) of FIG. 29, the datagrams DG1, DG2, DG4, DG5, and DG8 are transmitted, and d among received datagrams, it may be determined that each of the datagrams DG1, DG2, DG4, DG5, and DG8 is received, and then it may be determined that whether each of the datagrams DG1, DG2, DG4, DG5, and DG8 is received within the delay time. Alternatively, it may be determined that a set of the datagrams DG1, DG2, DG4, DG5, and DG8 is received, and then it may be determined whether the set of datagrams is received within the delay time.

Any one or more of the above comparison conditions may be determined as an abnormality factor. For example, an expected value of the WKC 178 of the received datagram may be stored in the datagram generation information, and when the expected value does not match the WKC 178 of the received datagram, it may be determined that there is an abnormality.

Alternatively, when a datagram cannot be received within the delay time defined in the datagram generation information, it may be determined that t there is an abnormality.

An abnormality determination is not limited to a factor for determining a match between datagrams. For example, when a calculated value of an error detection code calculated based on the received communication frame does not match the FCS 173, it may be determined that there is an abnormality. Alternatively, when a data length defined in the EtherCAT header 174 does not match a size of a group of the datagrams 175, or when a data length defined in the header 176 does not match a data length of the data area 177, it may be determined that there is an abnormality.

Alternatively, when an arrangement of datagrams 200a to 200e in the received communication frame is different from an expected arrangement of datagrams, it may be determined that there is an abnormality. Such various abnormality determinations are performed by one or more of the receiving unit 155, the communication frame disassembling unit 157, and the datagram analyzing unit 158.

When an abnormality is detected, a system operator or the like may be notified of the abnormality, or a datagram or a communication frame may be retransmitted by one or more of the datagram generating unit 150, the communication frame generating unit 153, the transmission unit 154, the receiving unit 155, the communication frame disassembling unit 157, and the datagram analyzing unit 158. By notifying a system operator or the like of such an abnormality, the system operator or the like can notice the abnormality and take necessary measures. Accordingly, execution and an operation of the control system 123 can be normalized and recovered.

When a non-EtherCAT frame is received or when datagram generation information matching a received datagram is not found, the communication frame or the datagram may be discarded, the communication frame or the datagram may be measured and stored as statistical information, or a system operator or the like may be notified of such kind of information. The datagram analyzing unit 158 may have a function of comparing and determining in parallel datagram generation information matching a received datagram, and may execute processing of searching for datagram generation information in parallel for datagrams transferred from the communication frame disassembling unit 157 even when processing of a datagram transferred previously is not completed.

In the example shown in FIG. 30, the datagram analyzing unit 158 first compares the command 179, the address 181, and the size 182 included in the transferred datagram 200a with the datagram generation information shown in FIG. 25. When the command 179 included in the datagram 200a is a BRD, the address 181 is 0x00000130, and the size 182 is 2 bytes, the datagram analyzing unit 158 extracts the datagram DG1 as datagram generation information. Since the address 181 can be processed by the control target device 121, only certain values (for example, lower 16 bits) may be compared, or the datagram analyzing unit 158 may calculate an expected value of the address 181 from the datagram generation information and compare the address 181 with the expected value. The same applies to the following datagrams 200. Since the datagram analyzing unit 158 recognizes that a data storage position in the data storage unit 152 is 0 based on the extracted datagram generation information (corresponding to step S066 in FIG. 17), the datagram analyzing unit 158 stores a value of the data area 177 of the datagram 200a with 2 bytes from an address 0 of a read buffer of the data storage unit 152 (corresponding to step S067 in FIG. 17).

In the datagram 200b to be transferred subsequently, the command 179 is ARMW, the address 181 is 0x00000910, and the size 182 is 4 bytes. In this case, the datagram analyzing unit 158 extracts the datagram DG2 as datagram generation information. Since the datagram analyzing unit 158 recognizes that a data storage position in the data storage unit 152 is 2 based on the extracted datagram generation information, the datagram analyzing unit 158 stores a value of the data area 177 of the datagram 200b with 4 bytes from an address 2 of a read buffer of the data storage unit 152.

In the datagram 200c to be transferred subsequently, the command 179 is an LWR, the address 181 is 0x00010400, and the size 182 is 476 bytes. In this case, the datagram analyzing unit 158 extracts the datagram DG4 as datagram generation information. The datagram analyzing unit 158 recognizes that a data storage position in the data storage unit 152 is 1024 based on the extracted datagram generation information. In this case, since the command 179 of the datagram DG4 is a write command, the data storage unit 152 may not be updated, and a value of the data area 177 of the datagram 200c may be stored with 476 bytes from an address 1024 of a write buffer of the data storage unit 152.

The datagram analyzing unit 158 repeats, for the datagrams 200d and 200e, the same processing as those of the datagrams 200a, 200b, and 200c. Since all received datagrams are processed (corresponding to Y in step S069 shown in FIG. 17), the reception processing is ended.

### (Simultaneous Reception by Multiple Communication Units 156)

Based on a relationship between a transmission timing and a reception timing, datagrams can be simultaneously transferred from a plurality of communication units 156 (including identification of the receiving unit 155 and the communication frame disassembling unit 157) to the datagram analyzing unit 158. In this case, the datagram analyzing unit 158 may select and process one of a plurality of datagrams on a first-come first-served basis or based on a priority defined for each communication unit 156 (including identification of the receiving unit 155 and the communication frame disassembling unit 157). Alternatively, a predetermined communication unit 156 (including identification of the receiving unit 155 and the communication frame disassembling unit 157) may be emphasized, and the datagram analyzing unit 158 may wait for transfer of a datagram from the communication unit 156 until a predetermined time elapses.

Alternatively, the datagram analyzing unit 158 may include a mechanism capable of processing a plurality of datagrams in parallel and may process datagrams transferred from a plurality of communication units 156 (including identification of the receiving unit 155 and the communication frame disassembling unit 157) in parallel. In this case, when the data storage unit 152 can be accessed in parallel, processing up to processing of storing data in the data storage unit 152 can be executed in parallel. However, in a case where the data storage unit 152 is not compatible with parallel accesses, for example, an access to the data storage unit 152 is similar to any one of the above configuration examples from the communication unit 156 (including identification of the receiving unit 155 and the communication frame disassembling unit 157) to the datagram analyzing unit 158.

### (Multiple Reception Areas)

A situation may occur in which the control target devices 121 connected to different communication units 156 are accessed using the same EtherCAT address. For example, the control target device 121 connected to the communication unit 156a and the control target device 121 connected to the communication unit 156b may be allocated to overlapping logical address spaces or may be accessed by the same auto increment address command.

In such a case, a logical sum of received values may be calculated and stored in the data storage unit 152, or a priority may be defined for each communication unit 156 to be connected and a value accessed to the control target device 121 connected to the communication unit 156 having a highest priority may be stored in the data storage unit 152. Whether the logical sum is calculated and stored in the data storage unit 152 or a value received by the predetermined communication unit 156 is stored in the data storage unit 152 may be determined based on datagram information from which the value is acquired. For example, a determination method based on a command serving as the datagram information includes a method in which a logical sum is calculated when a value is acquired by a BRD command in any one datagram, and when a value is acquired by one LRD command, the value acquired by the LRD command is stored in the data storage unit 152. Alternatively, a storage area may be ensured in the data storage unit 152 for each communication unit 156 to be connected. In this case, information indicating that a storage area is ensured in the data storage unit 152 for each communication unit 156 is set in the datagram generation information, and a storage position in the data storage unit 152 is held and stored for each communication unit 156.

When a storage position of data for each piece of datagram generation information is continuous, a data area having a size obtained by multiplying a data size by the number of communication units 156 is ensured in the data storage unit 152. For example, when a size of the data area 177 is 10 bytes and a storage position of the communication unit 156a is used as a reference, a storage position for the communication unit 156b is +10, and when the communication unit 156c is present, a storage position of the communication unit 156c is +20. The datagram analyzing unit 158 stores a value of the data area 177 of a datagram received from each communication unit 156 in each area of the data storage unit 152. At this time, for example, in order to calculate and store a logical sum of received values, a data area common to a plurality of communication units 156 may be provided instead of a data area for each communication unit 156.

Alternatively, while a storage area for each communication unit 156 is ensured in the data storage unit 152, an address of the data storage unit 152 accessed by the datagram analyzing unit 158 or the data access management unit 160 may be common, and a unit for identifying a storage area for each communication unit 156 may be separately provided. For example, when the data access management unit 160 accesses the data storage unit 152, the data storage unit 152 identifies the communication unit 156 by a unit such as a software register, and a control application or the data access management unit 160 specifies a storage area for each communication unit 156 by the software register.

For the datagram analyzing unit 158, for example, the data storage unit 152 similarly provides a unit that identifies a storage area for each communication unit 156 according to a method such as a control signal, and the storage area for each communication unit 156 is identified according to the control signal when the datagram analyzing unit 158 stores received data in the data storage unit 152. When the control application and the data access management unit 160 update data in the data storage unit 152 and when the datagram generating unit 150 extracts data from the data storage unit 152, the storage area for each communication unit 156 may be identified by the same method.

### (Schedule Unit)

FIG. 36 is a functional block diagram showing a functional configuration example of the control apparatus 120 shown in FIG. 1 different from that in FIG. 3. In FIG. 36, communication schedule units 240a and 240b are added to the configuration example shown in FIG. 3. In the specification, the communication schedule units 240a and 240b are collectively referred to as a communication schedule unit 240. FIG. 36 shows a configuration example in which the calculation unit 159 generates a communication frame, the communication schedule unit 240 schedules the communication frame and a communication frame transferred from the communication frame generating unit 153, and the transmission unit 154 transfers the scheduled communication frames.

The communication schedule unit 240 schedules the communication frame generated by the calculation unit 159 in such a manner and a communication frame generated by the communication frame generating unit 153. For example, the communication schedule unit 240 gives priority to the communication frame transferred from the communication frame generating unit 153. When a communication frame transferred from the calculation unit 159 and a communication frame transferred from the communication frame generating unit 153 are simultaneously transferred to the communication schedule unit 240, for example, the communication frame transferred from the communication frame generating unit 153 is preferentially transferred to the transmission unit 154.

Alternatively, even if a communication frame is transferred from the calculation unit 159 first, when a communication frame is transferred from the communication frame generating unit 153 during the transfer of the communication frame from the calculation unit 159, for example, transfer of the communication frame from the calculation unit 159 is set to wait. In this case, the communication schedule unit 240 cooperates with one or more of the datagram generating unit 150, the communication frame generating unit 153, and the time measurement unit 161, so that a timing at which the communication frame is transferred from the communication frame generating unit 153 can be grasped, and whether there is interference when the communication frame transferred from the calculation unit 159 is transferred to the transmission unit 154 can be determined. When interference is expected, for example, transfer of the communication frame transferred from the calculation unit 159 to the transmission unit 154 is set to wait.

When a communication frame is transferred from the calculation unit 159 to the communication schedule unit 240, for example, a configuration is provided to specify to which communication schedule unit 240 the communication frame is to be transferred. For example, the communication schedule unit 240 is implemented by one or more of the CPU 101 or an application operating on the CPU 101, the communication control IC 102, and the PHY 103.

### (Intermediate Node)

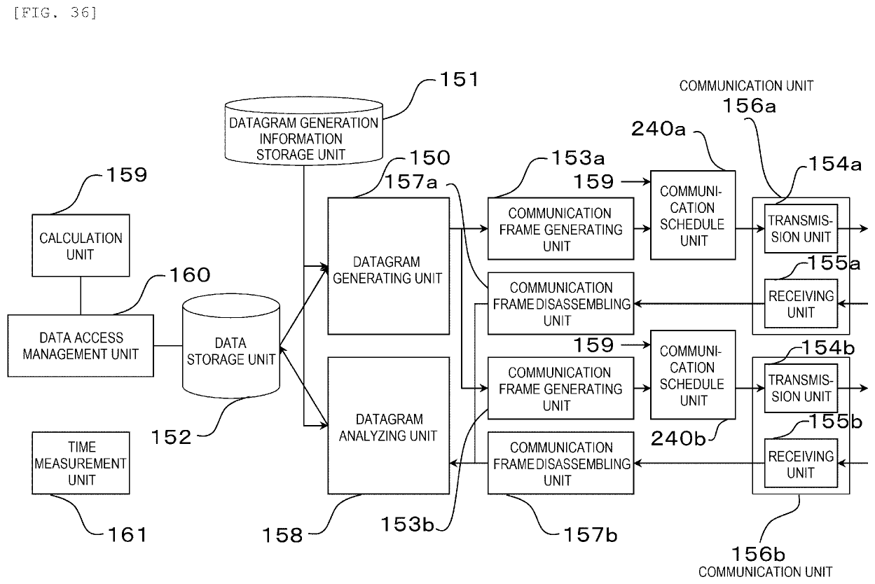

FIG. 35 is a schematic diagram showing a configuration example of the control communication system according to the first embodiment different from that in FIG. 1. In FIG. 230 is added to the 35, a communication apparatus configuration example shown in FIG. 1. As shown in FIG. 35, function units excluding the calculation unit 159 and the data access management unit 160 in the control apparatus 120 shown in FIG. 3 may be configured as the intermediate communication apparatus 230. In this case, for example, information transmitted from the control apparatus 120 to the communication apparatus 230 is the data area 177. For example, information set in the datagram generation information storage unit 151 is set in the communication apparatus 230 from the control apparatus 120 via the control network 122.

### (Multiple Communication Control ICs 102)

In the configuration example shown in FIG. 2, a plurality of communication control ICs 102 may be provided, and the datagram generation information storage unit 151 and the data storage unit 152 may be implemented in the memory 104 or the nonvolatile storage medium 105. The datagram generating unit 150, the communication frame generating unit 153, the communication unit 156, the communication frame disassembling unit 157, and the datagram analyzing unit 158 may be implemented in each communication control IC 102.

### (Software Implementation)

The functions shown in FIG. 3 may be implemented as software operating on the CPU 101 using any one or more of the CPU 101, the memory 104, and the nonvolatile storage medium 105 shown in FIG. 2.

### (Effects)

With the above configurations, it is possible to implement a control communication system that is excellent in utilization efficiency of a computer resource and a communication resource. Specifically, it is possible to shorten a communication delay and increase a communication capacity for each communication unit 156 by using a plurality of communication units 156 and determining the control target device 121 to be connected to each communication unit 156 according to a communication requirement of the control target device 121. Since the number of control target devices 121 to be connected to each communication unit 156 can be flexibly determined by such as changing the number of control target devices 121, the degree of freedom of a physical arrangement of the control target devices 121 can be improved. Further, since communication data for a plurality of communication units 156 can be collected and stored in the data storage unit 152, computer resources can be efficiently used. Therefore, costs of an implemented component can be reduced.

### Second Embodiment

In the second embodiment, a time synchronization protocol is further executed for the first embodiment. Reference numerals used in the second embodiment refer to the same functions, elements, and the like as those described in the first embodiment unless otherwise specified.

Generally, a protocol called a distributed clock for time synchronization is executed in the EtherCAT. The distributed clock takes the following steps.

### 1. Determine Communication Delay Between Time Reference Slave and Each Slave

A master transmits a datagram (an access to predetermined register) in which each slave measures reception time. Due to a feature that a packet circulates in a network, reception times of an outbound path and a return path of each slave are collected. A communication delay among slaves is calculated based on a relationship between the collected reception times and a network topology. The communication delay is integrated for each slave to determine a communication delay between a time reference slave and each slave. The determined communication delay is set for each slave. The time reference slave is generally a slave corresponding to the distributed clock closest to the master.

### 2. Set Time Correction Value for Each Slave

A time is also measured at the time of receiving, by an EPU of each slave, a datagram transmitted when determining the communication delay between the time reference slave and each slave. The master collects a reception time of the EPU of each slave and calculates a time difference between the time reference slave and each slave. The time difference is set for each slave as a time correction value. Each slave synchronizes with the time reference slave based on the time correction value set according to the communication delay determined in step 1.

### 3. Correct Time Drift

Thereafter, the master reads a time of the time reference slave and transmits a time distribution datagram to be distributed to other slaves. For example, a predetermined number of time distribution datagrams are continuously transmitted at the time of initialization, and are periodically transmitted thereafter. An ARMW command or the like in which an access address is set in a synchronization time register of the time reference slave is used as the time distribution datagram. According to the ARMW command, the time reference slave stores a time of the time reference slave (a time serving as a reference time) in a datagram, and the other slaves acquire the reference time stored in the ARMW and write the reference time in the synchronization time register. By this operation, each slave corrects a time drift (a slight shift of a clock) set at a synchronization time inside each slave.

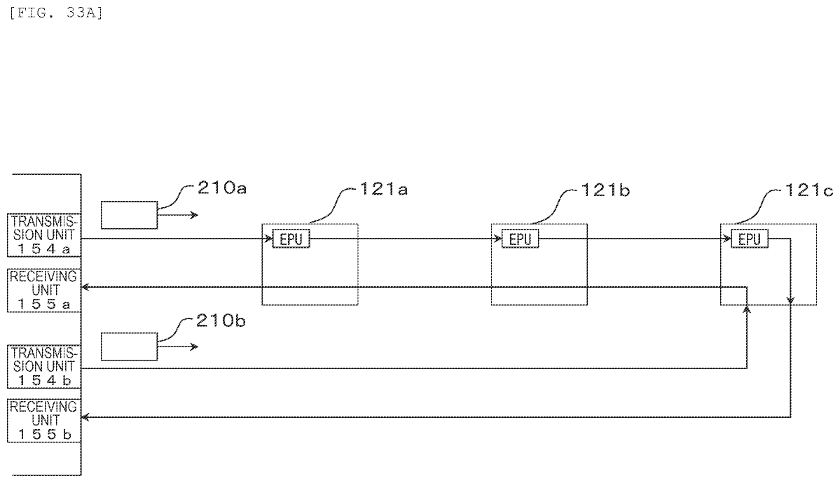

FIG. 31 is a diagram showing an operation example when a time synchronization protocol is applied in the control communication system according to the second embodiment. FIG. 31 shows the control system 123 in which three control target devices 121a, 121b, and 121c are connected to the communication unit 156a, and three control target devices 121d, 121e, and 121f are connected to the communication unit 156b.

### (1. Determine Communication Delay Between Time Reference Slave and Each Slave)

In order to determine the communication delay, it is assumed that a packet 210a including a reception time measuring datagram is transmitted from the communication unit 156a. The reception time measuring datagram is, for example, a broadcast write (BWR) command to a receive time port 0 register. In this case, the time measurement unit 161 measures a transmission time Tmas and a reception time Tmar in the communication unit 156a. The reference numeral m of a first character indicates master, the reference numeral a of a second character indicates the communication unit 156a, the reference numeral s of a third character indicates transmission, and the reference numeral r of a third character indicates reception.

The control target device 121a is set as a time reference slave. The communication delay among the control target devices 121a, 121b, and 121c is measured by a regular DC protocol. The communication delay between the control target device 121a and each of the control target devices 121d, 121e, and 121f is measured as follows. That is, when the communication unit 156a receives the packet 210a, the packet 210a is transferred to the communication unit 156b. At this time, the time measurement unit 161 measures transmission time Imbs and a reception time Tmbr in the communication unit 156b. The reference numeral b of a second character indicates the communication unit 156b.

Since the communication delay among the control target devices 121d, 121e, and 121f can be measured by a regular DC protocol, when a delay between the control target devices 121a and 121d can be measured, a communication delay between the control target device 121a and each of the control target devices 121d, 121e, and 121f can be calculated.

A delay d ad between the control target devices 121a and 121d is calculated according to Formula (17).

$$d\_ad = ( Tsar - Tsas ) + d\_ma + d\_mab + d\_md \qquad ( 17 )$$

Here,

Tsar indicates a reception time of the packet 210a in an outbound path of the control target device 121a,

Tsas indicates a reception time of the packet 210a in a return path of the control target device 121a,
d_ma indicates a communication delay between the control apparatus 120 and the control target device 121a,
d_mab indicates a transfer delay from the communication unit 156a to the communication unit 156b in the control apparatus 120, and
d_md indicates communication delay between the control apparatus 120 and the control target device 121d.

The communication delays d_ma, d_mab, and d_md are calculated according to respective Formulas (18), (19), and (20).

$$d\_ma = \{ ( Tmar - Tmas ) - ( Tsar - Tsas ) \} / 2 \qquad ( 18 )$$

$$d\_mab = Tmbs - Tmar \qquad ( 19 )$$

$$d\_md = \{ ( Tmbr - Tmbs ) - ( Tsdr - Tsds ) \} / 2 \qquad ( 20 )$$

Therefore, the delay d ad between the control target devices 121a and 121d can be calculated, and thus the communication delay between the control target device 121a and each of the control target devices 121e and 121f can also be calculated.

The transfer delay d_mab from the communication unit 156a to the communication unit 156b in the control apparatus 120 can be determined at the time of design regardless of a condition at the time of execution as long as a packet is transferred in a cut-through manner without being buffered when the packet is received by the communication unit 156a. Therefore, on the premise that the transfer delay d_mab at the time of design is used, the packet 210a may not be transferred to the communication unit 156b, and a packet 210b (shown by a dotted line in FIG. 31) may be transmitted from the communication unit 156b. The time measurement unit 161 measures a transmission time Tmbs and a reception time Tmbr of the packet 210b in the communication unit 156b.

When a design value of the transfer delay d_mab is used, the delay d ad between the control target devices 121a and 121d can also be calculated according to Formula (17), and thus a communication delay between the control target device 121a serving as a time reference and each of the other control target devices 121 can be calculated. When the packet 210b is transmitted, a reception time measuring datagram in the packet 210b may be defined as datagram generation information independent of a reception time measuring datagram in the packet 210a. In this case, a transmission timing may be defined independently.

Alternatively, when the packet 210a is transferred without using the packet 210b, for example, information indicating that a transfer operation is performed for a target datagram may be included in the datagram generation information. The target datagram is not limited to a datagram related to time synchronization. A timing of transmitting a packet from the communication unit 156b may not be an immediate timing of transferring the packet immediately after the packet is received from the communication unit 156a, and may be a timing when the communication unit 156 waits for a predetermined transmission timing. In this case, for example, a timing of transmitting a reception time measuring datagram in the packet 210a is defined for each of the communication unit 156a and the communication unit 156b and the timing is included in datagram generation information.

When the communication unit 156b waits for the transmission of the packet 210a and when the communication unit 156b waits for a certain constant period, for example, the waiting time is added to a communication delay from the control target device 121a serving as a time reference to each of the control target devices 121d, 121e, and 121f. Alternatively, when the waiting period is not constant, for example, an influence of the waiting time may be canceled by measuring and calculating an increased waiting period by the time measurement unit 161.

For example, the delay d ad between the control target devices 121a and 121d is calculated according to Formula (21).

$$d\_ad = ( Tsar - Tsas ) + d\_ma + {d\_mab}^{′} - d\_wait + d\_md \qquad ( 21 )$$

Here, d_mab′ indicates a transfer delay from the communication unit 156a to the communication unit 156b including the waiting period d wait. Formula (21) is equivalent to Formula (17) by subtracting the waiting period d wait.

### (2. Set Time Correction Value for Each Slave)

When the packet 210a received by the communication unit 156a is transferred to the communication unit 156b, a communication delay between the time reference slave and other slaves can be determined. Therefore, a time difference can be calculated by calculating a difference between a reception time of a reception time measuring datagram in the EPU of each control target device 121 and a reception time of a reception time measuring datagram in the EPU of the time reference slave as in the regular DC protocol.

When the packet 210b is transferred from the communication unit 156b, an adjustment is required since reception times of the control target devices 121d, 121e, and 121f are different from one another. When a reception time of the packet 210b in the EPU of the control target device 121d is defined as Tsde (the reference numeral e of a third character indicates the EPU), Tsde′ in which a time difference is adjusted is calculated according to Formula (22).

$${Tsde}^{′} = Tsde + adj \qquad ( 22 )$$

Since the time difference adj is a difference between a transmission time when the packet 210a is transferred and an actual transmission time, the time difference adj is calculated according to Formula (23).

$$adj = ( Tmar + d\_mab ) - Tmbs \qquad ( 23 )$$

Since the time difference adj is the same in the control target devices 121e and 121f, corrected reception times in the EPUs of the control target devices 121e and 121f can be calculated according to Formula (22). Thereafter, a time difference from the time reference slave may be calculated as in the regular DC protocol.

### (3. Correct Time Drift)

Since it is required to distribute a time of the control target device 121a which is the time reference slave to the other control target devices 121, a time distribution datagram is transmitted from the communication unit 156a and transferred from the communication unit 156b after the time distribution datagram is received by the communication unit 156a. In this case, a communication delay of the time distribution datagram between the control target devices 121a and 121d needs to be the same as a communication delay of the reception time measuring datagram between the control target devices 121a and 121d.

Therefore, a timing at which the time distribution datagram is transmitted from the communication unit 156b is the same as the transfer delay d_mab from the communication unit 156a to the communication unit 156b, and thus, for example, the timing is the same as a transmission timing of the reception time measuring datagram. A management and expression method of the time distribution datagram in datagram generation information is similar to that of the reception time measuring datagram.

### (In Case of Setting Master as Time Reference)

The control target device 121 may not be set as a time reference, and the control apparatus 120 may be set a time reference. In this case, operations are as follows.

### <1. Determine Communication Delay Between Time Reference Slave and Each Slave>

The control apparatus 120 transmits a reception time measuring datagram from each communication unit 156. At this time, the time measurement unit 161 measures a transmission time and a reception time from each communication unit 156. The control apparatus 120 calculates a communication delay between the control apparatus 120 and the control target device 121 adjacent to the control apparatus 120 and a communication delay between the control apparatus 120 and each control target device 121 based on a time measured by the time measurement unit 161, a reception time measured by each control target device 121, and information on a network topology.

A method for calculating the communication delay between the control apparatus 120 and the control target device 121 adjacent to the control apparatus 120 is the same as the method for calculating d_ma in Formula (18) and d_md in Formula (20). The calculated communication delay is set for each control target device 121. When the control target device 121a shown in FIG. 31 is set as a time reference, it is not necessary to set a communication delay for the control target device 121a, and thus this point is different in a case where the control apparatus 120 is set as a time reference.

### <2. Set Time Correction Value for Each Slave>

Since the control apparatus 120 is set as a time reference, a difference between a transmission time of each communication unit 156 and a reception time of the EPU of each control target device 121 is calculated as a time difference. The time difference is set as a time correction value for a slave which is each control target device 121.

### <3. Correct Time Drift>

Since the control apparatus 120 is set as a time reference, only the control apparatus 120 updates time information of the time distribution datagram, and the control target device 121 only acquires the time information. Therefore, for example, when an ARMW command is transmitted as a time distribution datagram from the control apparatus 120, a node address of the ARMW command is set to be 1. In this manner, the control target device 121 only reads information on the datagram unless each control target device 121 counts up and reaches zero.

The time distribution datagram is transmitted from each communication unit 156, and a transmission time in each communication unit 156 is stored in a data area of the time distribution datagram. Therefore, for example, one or more of the communication frame generating unit 153, the transmission unit 154, and the communication unit 156 have a function of storing a transmission time acquired from the time measurement unit 161 in the time distribution datagram.

### (Supplementation in Case of Executing Time Synchronization Protocol)

Although a case where there are two communication units 156 is described above as an example, the same applies to a case where there are three or more communication units 156. An order in the case of transferring the reception time measuring datagram and the time distribution datagram sequentially in the communication units 156 is set in which, for example, the control target device 121 including a clock with highest accuracy (a crystal oscillator, a software timer, or the like) is set as a time reference, priority is given to the communication unit 156 connected to the control target device 121. In such a case, examples of a communication requirement defined by the control communication requirement 192 include synchronization accuracy to be obtained by the control system 123.

For example, the control target device arrangement determining unit 193 determines the communication unit 156 in the control apparatus 120 to which the control target device 121 is connected and a connection order of each control target device 121 to the communication unit 156 based on accuracy of a clock included in each control target device 121. For example, the control target device 121 including a clock with high accuracy is adjacent to the control apparatus 120 and is set as a time reference.

An order of the second and subsequent communication units 156 that a communication frame is transferred is determined based on time determinism when the communication frame passes through a group of the control target devices 121 connected to the communication units 156. For example, in the case of the communication unit 156 to which the number of connected control target devices 121 is small, since an absolute value of a communication delay through a group of the control target devices 121 is small, a measurement error is reduced and accuracy of calculating a delay and a time error is improved.

Alternatively, in order to reduce cumulative errors of measured times or delays, for example, priority is given to the communication unit 156 to which the control target device 121 that requires high synchronization accuracy is connected. A priority criterion may be used as a selection criterion of the communication unit 156 that first transmits a datagram for time synchronization. A requirement having required synchronization accuracy may be determined by comparing a synchronization accuracy requirement of the control target device 121 having a most strict requirement among the control target devices 1 connected to the communication unit 156, or may be determined based on a statistical value (an average value, a variation, a weighted value, or the like) for the synchronization accuracy requirement of the control target device 121 connected to the communication unit 156.

Since one or more of the transmission unit 154, the receiving unit 155, and the communication unit 156 execute predetermined processing (transfer to another communication unit 156, measurement of a transfer delay, and the like) on the reception time measuring datagram and the time distribution datagram, for example, a datagram can be identified based on a parameter (parameters shown in FIG. 6) on the datagram or a communication frame including the datagram.

### (Effects)

With the above configurations, the following effects can be obtained in addition to the various effects described in the first embodiment. That is, even when a plurality of communication units 156 are used, it is possible to implement the control system 123 in which times of the control target devices 121 connected to the respective communication units 156 can be synchronized with one another while shortening communication times for the control target devices 121 connected to the respective communication units 156, and communication performance and time synchronization are required.

### Third Embodiment

The third embodiment provides a configuration in which reliability is further increased by path redundancy as compared with the first embodiment or the second embodiment. Reference numerals used in the third embodiment refer to the same functions, elements, and the like as those described in the first and second embodiments unless otherwise specified.

### (Functional Configuration of Path Redundancy)

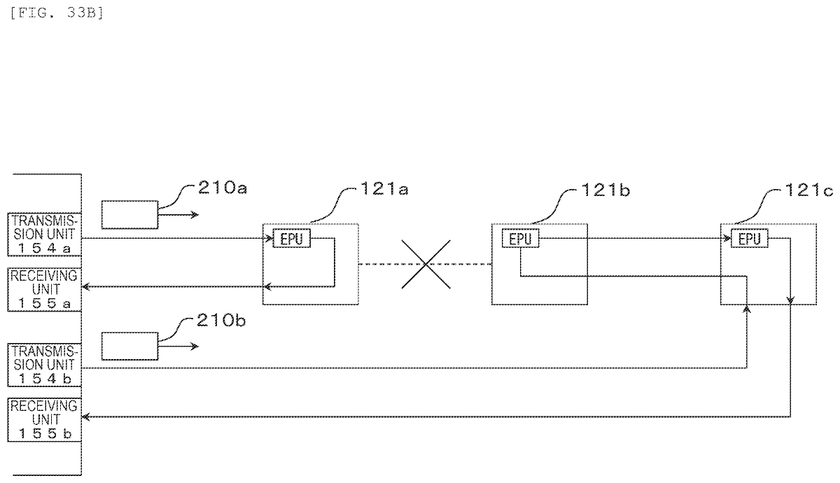

FIG. 32 is a functional block diagram showing a functional configuration example of the control apparatus 120 shown in FIG. 1 in a control communication system according to the third embodiment. In FIG. 32, path redundancy communication control units 220a and 220b are added to the configuration example shown in FIG. 3. In the specification, the path redundancy communication control units 220a and 220b are collectively referred to as a path redundancy communication control unit 220. The path redundancy communication control unit 220 is a function unit that controls path redundancy communication.

The path redundancy communication control unit 220 copies a communication frame transferred from the communication frame generating unit 153 and transmits the communication frame to the transmission units 154a and 154b or simply transmits the communication frame to the transmission unit 154a. The path redundancy communication control unit 220 transfers communication frames received from the receiving unit 155a and the receiving unit 155b to the communication frame disassembling unit 157 or the transmission unit 154b. If necessary, the contents received from the receiving unit 155a and the receiving unit 155b are combined. The combination refers to, for example, taking a logical sum of contents received by logical address read (LRD) or broadcast read (BRD). For example, the path redundancy communication control unit 220 is implemented by one or more of the CPU 101 or an application operating on the CPU 101, and the communication control IC 102.

In the present embodiment, two communication units 156 are used to implement one EtherCAT network in order to achieve path redundancy. Therefore, the communication unit 156 that is a transfer destination of a datagram in datagram generation information may be specified by an identifier of the communication frame generating unit 153, or may be specified by identifiers of the two communication units 156 that constitute one EtherCAT network. Alternatively, an identifier may be defined using two or more communication units 156 as one unit, and the identifier may be used as a unit of a transfer destination of a datagram that is connected to the path redundancy communication control unit 220. IEEE 802.1 AX (link aggregation) may be used as such an aggregation method of the communication units 156.

### (Path Redundancy: Copy and Transmission)

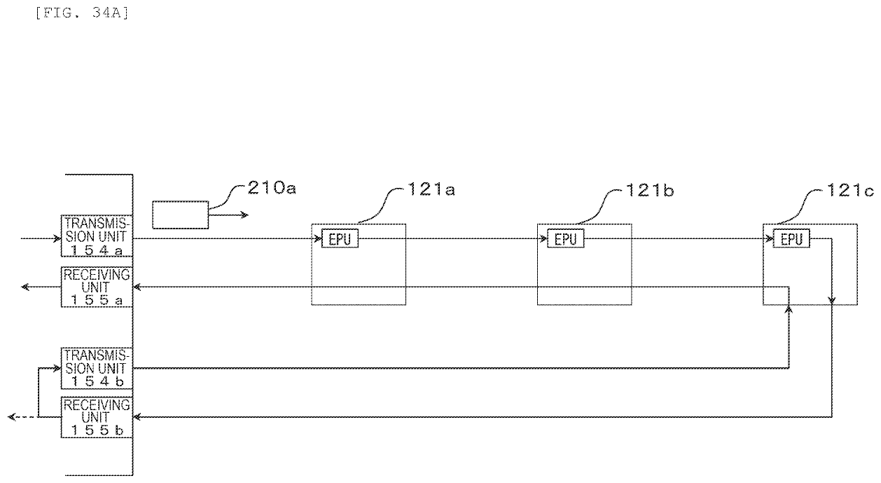

FIGS. 33A and 33B are diagrams showing operation examples of the control system 123 including the control apparatus 120 shown in FIG. 32. In FIGS. 33A and 33B, the path redundancy communication control unit 220 copies a communication frame transferred from the communication frame generating unit 153, and the communication frame is transmitted from both of the transmission units 154a and 154b.

When a path is normal as shown in FIG. 33A, a communication frame transmitted from the transmission unit 154a is received by the receiving unit 155b, and a communication frame transmitted from the transmission unit 154b is received by the receiving unit 155a. On the other hand, when a path is abnormal as shown in FIG. 33B, a communication frame transmitted from the transmission unit 154a is received by the receiving unit 155a, and a communication frame transmitted from the transmission unit 154b is received by the receiving unit 155b.

In either case, for example, the path redundancy communication control unit 220 combines the data areas 177 of datagrams in the received communication frames into a logical sum and transfers the logical sum to the communication frame disassembling unit 157. Processing of a communication frame may be changed according to a command of a received datagram, and for example, in the case of an LRD command or a BRD command, a logical sum and other commands such as an APRD command may be sequentially transferred to the communication frame disassembling unit 157 without combining the commands.

Alternatively, only a first-arrived communication frame or only a later-arrived communication frame may be selected and transferred to the communication frame disassembling unit 157. The communication frame disassembling unit 157 or the data storage unit 152 may perform the combination (a logical sum or selection of a communication frame) for each datagram.

### (Path Redundancy: Path Control)

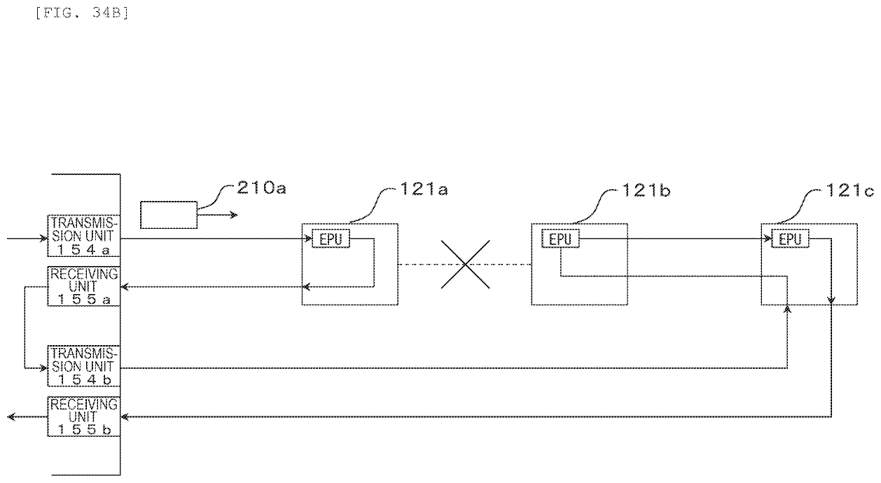

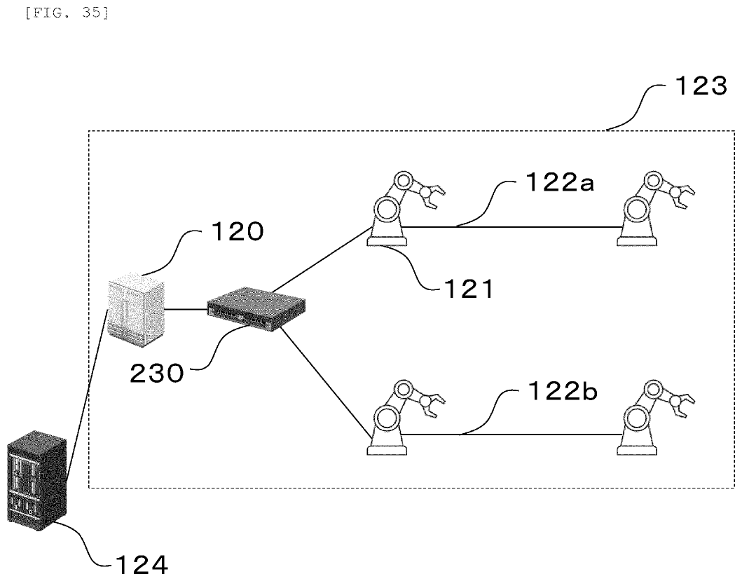

FIGS. 34A and 34B are diagrams showing operation examples different from those in FIGS. 33A and 33B. In FIGS. 34A and 34B, a communication frame transferred from the communication frame generating unit 153 is transmitted from the transmission unit 154a, and the path redundancy communication control unit 220 switches a transfer destination of the communication frame at the time of reception according to a state of a path.

When a path is normal as shown in FIG. 34A, a communication frame transmitted from the transmission unit 154a is received by the receiving unit 155b. Thereafter, the communication frame is transmitted from the transmission unit 154b and received by the receiving unit 155a. The communication frame received by the receiving unit 155a is transferred to the communication frame disassembling unit 157. When the communication frame is received by the receiving unit 155b, since the communication frame passes through EPUs of all of the control target devices 121, the communication frame may be transferred to the communication frame disassembling unit 157 without being transferred to the transmission unit 154a. When a path is abnormal as shown in FIG. 34B, a communication frame transmitted from the transmission unit 154a is received by the receiving unit 155a. Thereafter, the communication frame is transferred and transmitted to the transmission unit 154b and received 155b. The communication frame by the receiving unit 1 received by the receiving unit 155b is transferred to the communication frame disassembling unit 157.

The path redundancy communication control unit 220 stores information for identifying a communication frame, and it is possible to determine processing to be executed when the communication frame is received by performing the storage together with processing (transmission by the transmission units 154a and 154b, reception by the receiving units 155a and 155b, and transfer to the transmission unit 154b) executed on the communication frame. Examples of the information for identifying the communication frame include one or more of information on the communication frame (a size, the number of datagrams, a parameter such as a command of each datagram, and the like), a time when the path redundancy communication control unit 220 transfers the communication frame from the communication frame generating unit 153, a time when the path redundancy communication control unit 220 transmits the communication frame from the transmission units 154a and 154b, and a time when the receiving units 155a and 155b receive the communication frame.

For example, in a case where a communication frame is received by the receiving unit 155a, when information indicating that the communication frame is transmitted from the transmission unit 154a, received by the receiving unit 155b, and transmitted from the transmission unit 154b is stored, it can be determined that processing is executed in a normal path shown in FIG. 34A. Alternatively, in a case where a communication frame is received by the receiving unit 155a, when only. information indicating that the communication frame is transmitted from the transmission unit 154a is stored, it can be determined that processing is executed in an abnormal path as shown in FIG. 34B. In this case, information may be transferred to the transmission unit 154b.

In a case where a communication frame is received by the receiving unit 155a, when information indicating that the communication frame is transmitted from the transmission unit 154a, received by the receiving unit 155a, and transmitted from the transmission unit 154b is stored, it can be determined that a path abnormality shown in FIG. 34B temporarily occurs. That is, when the communication frame is transmitted from the transmission unit 154b, it can be determined that a communication path is normal and the communication frame is received by the receiving unit 155a. In such a case, since it can be determined that communication with the control target devices 121b and 121c is not possible, for example, processing such as discarding the communication frame and retransmitting the communication frame is executed.

Alternatively, the processing performed on the communication frame (transmission by the transmission units 154a and 154b, reception by the receiving units 155a and 155b, and transfer to the transmission unit 154b) may be reflected on the communication frame. Specifically, for example, processing is reflected in a destination MAC address of the Ethernet header 171, or the index 180 of a start datagram. In this case, for example, the presence or absence of transmission by the transmission unit 154a, the presence or absence of reception by the receiving unit 155a, the presence or absence of transmission by the transmission unit 154b, and the presence or absence of reception by the receiving unit 155b are represented by respective bits using four bits (1 indicates the presence of an event).

For example, in a case where a communication frame is received by the receiving unit 155a, when a value of the four bits is 1011 (binary number, the value is not set to 1 immediately after reception), since it can be determined that the communication frame is transmitted from the transmission unit 154a, received by the receiving unit 155b, and transmitted from the transmission unit 154b, it can be determined that processing is executed in the normal path shown in FIG. 34A. Alternatively, in a case where a communication frame is received by the receiving unit 155a, when the value of the four bits is 1000 (binary number), since it can be determined that the communication frame is transmitted from the transmission unit 154a, it can be determined that processing is executed in the abnormal path shown in FIG. 34B. In this case, the path redundancy communication control unit 220 changes the value of the four bits on the communication frame to 1100 (binary number, reflects reception by the receiving unit 155a), and then the communication frame is transferred to the transmission unit 154b, and the communication frame is transmitted from the transmission unit 154b.

In a case where a communication frame is received by the receiving unit 155a, when a value of the four bits is 1110 (binary number), since it can be determined that the communication frame is transmitted from the transmission unit 154a, received by the receiving unit 155a, and transmitted from the transmission unit 154b, it can be determined that a path abnormality shown in FIG. 34B temporarily occurs. That is, when the communication frame is transmitted from the transmission unit 154b, it can be determined that a communication path is normal and the communication frame is received by the receiving unit 155a. In such a case, since it can be determined that communication with the control target devices 121b and 121c is not possible, for example, processing such as discarding the communication frame and retransmitting the communication frame is executed.

Examples of the four bits include upper four bits of a start byte of the destination MAC address of the Ethernet header 171 or upper four bits of the index 180 of a start datagram. Alternatively, as described above, since the transmission of the transmission unit 154a is basically 1, the transmission may be represented by three bits of the presence or absence of reception by the receiving unit 155a, the presence or absence of transmission by the transmission unit 154b, and the presence or absence of reception by the receiving unit 155b.

By using the above-described method, even when a path abnormality temporarily occurs, it is possible to prevent a communication frame from overflowing on a network (occurrence of flooding), and it is possible to stably operate the control system 123.

### (Combination of FIGS. 33A and 33B and FIGS. 34A and 34B)

Path redundancy by the duplicate transmission shown in FIGS. 33A and 33B and path redundancy by the transfer control of a communication frame shown in FIGS. 34A and 34B may be configured with either method or be statically or dynamically changeable for each combination of the communication units 156 that constitute a path to be made redundant.

(Mixing with Single Line)

A case where a redundant path is implemented by two communication units 156 as shown in FIG. 32 and a case where two communication units 156 are divided to implement two communication paths that are not redundant may be switchable. This switching may be statically or dynamically changeable.

### (Effects)

With the above configuration, the following effects can be obtained in addition to the various effects described in the first embodiment or the second embodiment. That is, a communication path to the control target device 121 can be made redundant while shortening a communication time for the control target device 121 connected to each combination of the communication units 156, and the control system 123 that requires communication performance and reliability can be implemented.

Although the invention made by the present inventor has been specifically described based on embodiments, the invention is not limited to the embodiments, and various modifications can be made without departing from the gist of the invention. For example, the above-described embodiments have been described in detail to facilitate understanding of the invention, and the invention is not necessarily limited to those including all the configurations described above. A part of a configuration according to one embodiment can be replaced with a configuration according to another embodiment, and a configuration according to one embodiment can also be added to a configuration according to another embodiment. A part of the configuration of each embodiment may be added to, deleted from, or replaced with another configuration.

The above-described program or software may be stored in a non-transitory computer readable recording medium and then supplied to a computer. Examples of such a recording medium include a magnetic recording medium represented by a hard disc drive, an optical recording medium represented by a digital versatile disc (DVD) or a Blu-ray disc, and a semiconductor memory represented by a flash memory.

### REFERENCE SIGNS LIST

120: control apparatus
121: control target device
122: control network
123: control system
124: control system management apparatus
150: datagram generating unit
151: datagram generation information storage unit
152: data storage unit
153: communication frame generating unit
156: communication unit
157: communication frame disassembling unit
158: datagram analyzing unit
159: calculation unit
160: data access management unit
161: time measurement unit
175: datagram
196: datagram configuration information
220: path redundancy communication control unit

1. A control communication system comprising:
a control communication apparatus that includes a communication unit configured to transmit a packet including control data and in which the communication unit includes a plurality of ports; and
a plurality of device groups that are communicably connected to the plurality of communication ports and are operated according to the received packet, wherein
the control data is generated toward a target communication port among the plurality of communication ports, the target communication port being determined based on information of a communication port that transmits the packet, and
the packet includes a packet data area in which the control data is arranged, and the packet is transmitted from the target communication port to the device group connected to the target communication port.

2. A control communication system comprising:
a control communication apparatus that includes a communication unit configured to transmit a packet including control data and in which the communication unit includes a plurality of ports; and
a plurality of device groups that are communicably connected to the plurality of communication ports and are operated according to the received packet, wherein
the control data is generated toward a target communication port among the plurality of communication ports using control data configuration information generated based on information of a device that constitutes the plurality of device groups,
the target communication port is determined based on information of the communication port that transmits the packet, the information being included in the control data configuration information, and
the packet includes a packet data area in which the control data is arranged, and the packet is transmitted from the target communication port to the device group connected to the target communication port.

3. A control communication system comprising:
a control communication apparatus that includes a communication unit configured to transmit a packet including control data and in which the communication unit includes a plurality of ports; and
a plurality of device groups that are communicably connected to the plurality of communication ports and are operated according to the received packet, wherein
the control communication apparatus includes a storage unit in which data areas in the control data are arranged and stored in a group,
the control data is generated toward a target communication port among the plurality of communication ports using positions and a quantity of the data areas in the storage unit, the positions and the quantity being included in control data configuration information generated based on information of a device that constitutes the plurality of device groups,
the target communication port is determined based on information of the communication port that transmits the packet, the information being included in the control data configuration information, and
the packet includes a packet data area in which the control data is arranged, and the packet is transmitted from the target communication port to the device group connected to the target communication port.

4. The control communication system according to claim 1, wherein
for each of the communication ports, the target communication port serving as a connection destination of a corresponding device constituting the plurality of device groups is determined while satisfying a communication requirement including one or more of a communication data amount, a communication cycle, and synchronization accuracy allowed in the device connected to the communication port, and the device is connected to the determined target communication port in a serial manner.

5. The control communication system according to claim 4, wherein
the plurality of device groups are ranked based on one or more of a device type, a communication cycle, a data amount, and for writing and/or reading purpose, and are connected to the target communication port serving as the connection destination determined in the ranked order.

6. The control communication system according to claim 1, wherein
the control data configuration information includes information of a command to the device connected to the target communication port and information of a cycle or a timing of transmitting the packet, and
the packet is generated based on the information of a cycle or a timing included in the control data configuration information.

7. The control communication system according to claim 6, wherein
in the control data configuration information, the control data configuration information of the control data transmitted from the same target communication port is grouped based on the cycle or the timing in the control data configuration information of the same target communication port and an allowable size of the packet, and the timing for each packet is determined for each group.

8. The control communication system according to claim 1, wherein
the control data configuration information includes one or more of information indicating whether the control data configuration information is enabled or disabled, a control state of the control communication system that transmits the control data specified by the control data configuration information, and information indicating whether to transmit the control data transmitted from a first communication port to a second communication port after the control data is received.

9. The control communication system according to claim 3, wherein
the control communication apparatus extracts the data area from the storage unit when the control data is for writing data to the device, and ensures, in the control data, an empty data area having the same amount as the data area included in the control data configuration information when the control data is for reading data from the device.

10. The control communication system according to claim 1, wherein
the control communication apparatus groups data areas of the device groups based on one or more of information indicating whether the control data is for writing data to the device or reading data from the device, the target communication port, a communication requirement of the device, or a device type of the device, allocates the data areas of the device groups of each group to be a series on a virtual area, and performs communication of the control data using the virtual area.

11. The control communication system according to claim 3, wherein
the control communication apparatus extracts the control data from a packet returned and received from the device groups, and updates data in the storage unit based on one or more of the received control data, the control data configuration information, and information of the communication port that receives the packet.

12. The control communication system according to claim 1, wherein
the control communication apparatus changes an operation of the device into updating of a data area of the control data or acquisition of information using device software.

13. The control communication system according to claim 1, wherein
the control communication apparatus identifies the control data included in the packet transmitted from the target communication port, measures one or more of a transmission time from the target communication port, a reception time of the target communication port, and a transfer time to a different communication port, and executes one or more of transmission by the target communication port, recording of a reception operation, and transfer to the different communication port.

14. The control communication system according to claim 13, wherein
the control communication apparatus sets one or both of a delay and a time difference held by the device based on the measured transmission time, reception time, and transfer time to the different communication port.

15. The control communication system according to claim 13, wherein
the control communication apparatus reflects, in the control data, one or more of transmission from a first communication port, reception by the first communication port, transfer to a second communication port, transmission from the second communication port, and reception by the second communication port.

16. The control communication system according to claim 1, wherein
when a check code included in the received packet or the control data does not match an expected value of the check code, or when a reply from the device is not received within a predetermined time after the packet is transmitted from the target communication port, the control communication apparatus determines a communication abnormality and retransmits the packet from the target communication port or stores information of the target communication port.

17. The control communication system according to claim 1, wherein
the control data configuration information is divided into a plurality of pieces when an amount of a data area of the control data is larger than an amount allowed by the control data.

18. The control communication system according to claim 1, wherein
each device constituting the plurality of device groups is operated based on the control data corresponding to the device included in a data area of the received packet.

19. A plasma processing apparatus comprising:
a processing chamber that is located in a vacuum container and in which pressure is reduced and plasma is formed;
a stage that is located in the processing chamber and has an upper surface on which a wafer to be processed using the plasma is located;
a radio frequency power supply configured to supply radio frequency power to an electrode that forms the plasma during processing of the wafer;
a heater power supply configured to supply power to a heater that adjusts a temperature of the wafer;
a flow rate adjuster configured to adjust a flow rate of a processing gas supplied to the processing chamber to form the plasma; and
a valve configured to adjust an exhaust amount of the gas in the processing chamber through an exhaust port located below the stage, wherein
respective controllers of the radio frequency power supply, the heater power supply, the flow rate adjuster, and the valve constitute the plurality of device groups according to claim 1.
